(19) United States
(12) Patent Application Publication
(10) Pub. No.: US 2014/0084271 A1
(43) Pub. Date: Mar. 27, 2014

(54) NOVEL ORGANIC ELECTROLUMINESCENT COMPOUNDS AND ORGANIC ELECTROLUMINESCENT DEVICE USING THE SAME

(71) Applicants: Su Hyun Lee, Jangan-gu (KR); Soo-Jin Hwang, Seongbuk-gu (KR); Seon-Woo Lee, Osan-si (KR); Doo-Hyeon Moon, Hwaseong-si (KR); Hyo Jung Lee, Hwaseong-si (KR); Soo Jin Yang, Hwaseong-si (KR); Kyoung-Jin Park, Seongnam-si (KR); Chi Sik Kim, Hwaseong-si (KR); Young Jun Cho, Seongnam-si (KR); Hyuck Joo Kwon, Gangnam-gu (KR); Kyung Joo Lee, Dchwa-don (KR); Bong Ok Kim, Gangnam-gu (KR)

(72) Inventors: Su Hyun Lee, Jangan-gu (KR); Soo-Jin Hwang, Seongbuk-gu (KR); Seon-Woo Lee, Osan-si (KR); Doo-Hyeon Moon, Hwaseong-si (KR); Hyo Jung Lee, Hwaseong-si (KR); Soo Jin Yang, Hwaseong-si (KR); Kyoung-Jin Park, Seongnam-si (KR); Chi Sik Kim, Hwaseong-si (KR); Young Jun Cho, Seongnam-si (KR); Hyuck Joo Kwon, Gangnam-gu (KR); Kyung Joo Lee, Dchwa-don (KR); Bong Ok Kim, Gangnam-gu (KR)

(73) Assignee: ROHM AND HAAS ELECTRONIC MATERIALS KOREA LTD., Cheonan-si, Chungcheongnam-do (KR)

(21) Appl. No.: 13/996,975

(22) PCT Filed: Dec. 21, 2011
(86) PCT No.: PCT/KR2011/009896

§ 371 Date: Dec. 9, 2013

(30) Foreign Application Priority Data
Dec. 21, 2010 (KR) 10-2010-0131734
Dec. 15, 2011 (KR) 10-2011-0135025

(51) Int. Cl. H01L 51/00

(52) U.S. Cl. CPC H01L 51/0067; H01L 51/0072; H01L 51/0074
USPC 257/40; 544/331

(57) ABSTRACT

Provided are novel organic electroluminescent compounds and organic electroluminescent devices using the same. Since the organic electroluminescent compound exhibits good luminous efficiency and excellent life property, it may be used to manufacture OLED devices having superior operation life and consuming less power due to improved power efficiency.

### FIELD OF THE INVENTION

The present invention relates to novel organic electroluminescent compounds and an organic electroluminescent device using the same.

### BACKGROUND OF THE INVENTION

Among display devices, electroluminescent (EL) devices are advantageous in that they provide wide view angle, superior contrast and fast response rate as self-emissive display devices. In 1987, Eastman Kodak first developed an organic EL device using a low-molecular-weight aromatic diamine and aluminum complex as a substance for forming an electroluminescent layer [Appl. Phys. Lett. 51, 913, 1987].

The most important factor to determine luminous efficiency in an organic light-emitting diode (OLED) is electroluminescent material. Though fluorescent materials have been widely used as electroluminescent material up to the present, development of phosphorescent materials is one of the best ways to improve the luminous efficiency theoretically up to four (4) times, in view of electroluminescent mechanism. Up to now, iridium (III) complexes have been widely known as a phosphorescent material, including (acac)Ir(btp)₂(bis(2-(2′-benzothienyl)-pyridinato-N,C-3′)iridium-(acetylacetonate)), Ir(ppy)₃(tris(2-phenylpyridine)iridium) and Firpic (Bis(4,6-difluorophenylpyridinato-N,C2)picolinatoiridium), as the red, green and blue one (RGB), respectively. In particular, a lot of phosphorescent materials have been recently investigated in Japan, Europe and America.

At present, 4,4′-N,N′-dicarbazole-biphenyl (CBP) is most widely known as a host material for a phosphorescent material. High-efficiency OLEDs using a hole blocking layer comprising Bathocuproine (BCP), aluminum(III)bis(2-methyl-8-quinolinato)(4-phenylphenolate)) (BAlq), etc. are reported. High-performance OLEDs using BAlq derivatives as a host were reported by Pioneer (Japan) and others.

Although these materials provide good electroluminescence characteristics, they are disadvantageous in that degradation may occur during the high-temperature deposition process in vacuum because of low glass transition temperature and poor thermal stability. Since the power efficiency of an OLED is given by (π/voltage)×current efficiency, the power efficiency is inversely proportional to the voltage. High power efficiency is required to reduce the power consumption of an OLED. Actually, OLEDs using phosphorescent materials provide much better current efficiency (cd/A) than those using fluorescent materials. However, when the existing materials such as BAlq, CBP, etc. are used as a host of the phosphorescent material, there is no significant advantage in power efficiency (Im/W) over the OLEDs using fluorescent materials because of high driving voltage. Further, the OLED devices do not have satisfactory operation life. Therefore, development of more stable, higher-performance host materials is required.

### TECHNICAL PROBLEM

Accordingly, one aspect of the present invention is to provide an organic electroluminescent compound having luminescence efficiency and device operation life improved over existing materials and having superior backbone with appropriate color coordinates in order to solve the aforesaid problems. Another aspect of the present invention is to provide a highly efficient organic electroluminescent device having a long operation life by employing the organic electroluminescent compound as an electroluminescent material.

### TECHNICAL SOLUTION

Provided are an organic electroluminescent compound represented by Chemical Formula 1 and an organic electroluminescent device using the same. With superior luminescence efficiency and excellent life property, the organic electroluminescent compound according to the present invention may be used to manufacture an OLED device having superior operation life and consuming reduced power by improved power efficiency.

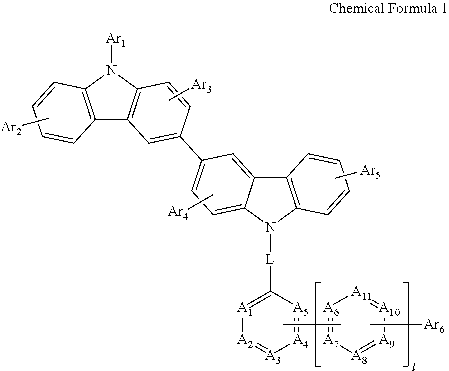

Wherein the I represents an integer of 0 to 2; the L represents (C6-C30)arylene or (C3-C30)heteroarylene; the A₁ to A₁₁ independently represent CR7 or N; the R7 and Ar₁ to Ar₆ independently represent any one selected from the group consisting of hydrogen, deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl and tri(C6-C30)arylsilyl; each of alkyl, cycloalkyl, heterocycloalkyl, alkenyl, alkynyl, aryl, heteroaryl, arylene, and heteroarylene of the R7, and Ar₁ to Ar₆ is further substituted with one or more selected from the group consisting of deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl, (C1-C30)alkyldi(C6-C30)arylsilyl and tri(C6-C30)arylsilyl; carbon atoms of the A₁ to A₁₁ and carbon atoms of Ar₆ are linked through a chemical bond, or independently linked via any one selected from the group consisting of —CR₈R₉—, —O—, —NR₁₀— and —S— to form a fused ring; and definition on the R₈, R₉, R₁₀ and substituents thereof are the same as that of the R₇.

Also, the present invention includes the organic electroluminescent compounds represented by following Chemical Formulas 2 to 5 but is not limited thereto.

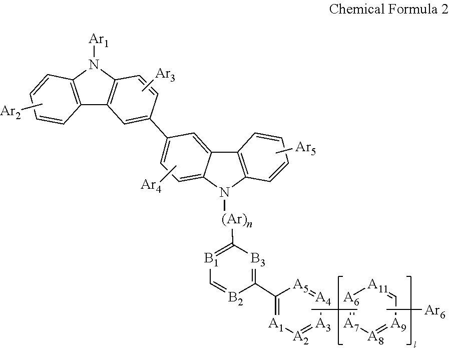

Wherein the I represents an integer of 1 to 2; the Ar represents (C6-C30)arylene, n represents an integer of 1 to 2; the A₁ to A₁₁ independently represent CR7 or N; the R7 and Ar₁ to Ar₆ independently represent any one selected from the group consisting of hydrogen, deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl and tri(C6-C30)arylsilyl; the B₁, B₂ and B₃ independently represent CH or N, but they do not represent CH at the same time; each of alkyl, cycloalkyl, heterocycloalkyl, alkenyl, alkynyl, aryl and heteroaryl of the R7, Ar₁ to Ar₆ is further substituted with one or more selected from the group consisting of deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl, (C1-C30)alkyldi(C6-C30)arylsilyl and tri(C6-C30)arylsilyl; carbon atoms of the A₁ to A₁₁ and carbon atoms of Ar₆ are linked through a chemical bond, or independently linked via any one selected from the group consisting of —CR₈R₉—, —O—, —NR₁₀— and —S— to form a fused ring; and definition on the R₈, R₉, R₁₀ and substituents thereof is the same as that of the R₇.

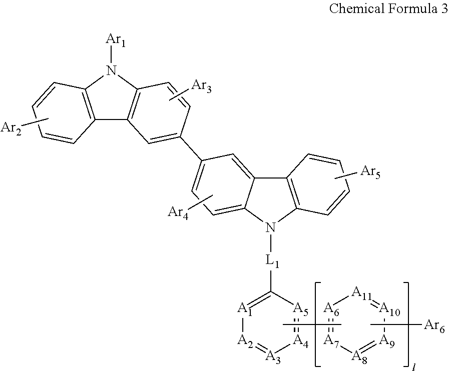

Wherein the L₁ represents (C3-C30)heteroarylene; definition on Ar₁ to Ar₆ and substituents of Ar₁ to Ar₆ is the same as that of Ar₁ to Ar₆ in Chemical Formula 1, and definition on A₁ to A₁₁ is the same as that of A₁ to A₁₁ in Chemical Formula 1; and the 1 is an integer of 1 to 2.

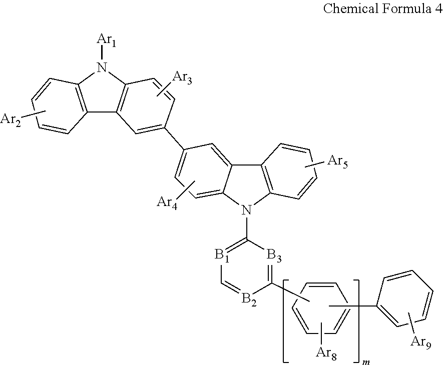

Wherein definition on Ar₁ to Ar₅, Ar₅ to Ar_{g} and substituents thereof is the same as that of Ar₁ to Ar₆ in Chemical Formula 1; and the m represents an integer of 1 to 2, and the B₁, B₂ and B₃ independently represent CH or N, but they are not CH at the same time.

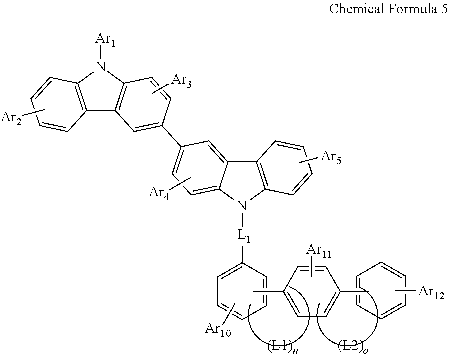

Wherein L₁ represents (C3-C30)heteroarylene; definition on Ar₁ to Ar₅, Ar₁₀ to Ar₁₂ and substituents thereof is the same as that of Ar₁ to Ar₆ in Chemical Formula 1;

the L1 to L2 independently represent any one selected from the group consisting of —CR₈O₉—, —O—, —NR₁₀— and —S—; definition on the R₈, R₉, R₁₀ and substituents thereof is the same as that of R7 in Chemical Formula 1; and the n and independently represent an integer of 0 to 1, and n+o=1.

In the present invention, “alkyl”, “alkoxy” and other substituents containing “alkyl” moiety include both linear and branched species. In the present invention, the “cycloalkyl” includes polycyclic hydrocarbon rings such as substituted or unsubstituted adamantyl or substituted or unsubstituted (C7-C30)bicycloalkyl as well as a monocyclic ring.

In the present invention, “aryl” means an organic radical derived from an aromatic hydrocarbon by the removal of one hydrogen atom, and may include a 4- to 7-membered, particularly 5- or 6-membered, single ring or fused ring, including a plurality of aryl groups having single bond(s) therebetween. Specific examples include phenyl, naphthyl, biphenyl, anthryl, indenyl, fluorenyl, phenanthryl, triphenylenyl, pyrenyl, perylenyl, chrysenyl, naphthacenyl, fluoranthenyl, etc., but are not limited thereto. The naphthyl includes 1-naphthyl and 2-naphthyl. The anthryl includes 1-anthryl, 2-anthryl and 9-anthryl, and the fluorenyl includes 1-fluorenyl, 2-fluorenyl, 3-fluorenyl, 4-fluorenyl and 9-fluorenyl. In the present invention, “heteroaryl” means an aryl group containing 1 to 4 heteroatom(s) selected from B, N, O, S, P(═O), Si and P as aromatic ring backbone atom(s), other remaining aromatic ring backbone atoms being carbon. It may be 5- or 6-membered monocyclic heteroaryl or polycyclic heteroaryl resulting from condensation with a benzene ring, and may be partially saturated. The heteroaryl also includes one or more heteroaryl groups having single bond(s) therebetween.

The heteroaryl includes a divalent aryl group wherein the heteroatom(s) in the ring may be oxidized or quaternized to form, for example, an N-oxide or a quaternary salt. Specific examples include monocyclic heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., polycyclic heteroaryl such as benzofuranyl, benzothiophenyl, isobenzofuranyl, dibenzocyphenyl, dibenzofuranyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenanthridinyl, benzodioxolyl, etc., an N-oxide thereof (e.g., pyridyl N-oxide, quinolyl N-oxide, etc.), a quaternary salt thereof, etc., but are not limited thereto.

The “(C1-C30)alkyl” groups described herein may include (C1-C20)alkyl or (C1-C10)alkyl and the “(C6-C30)aryl” groups include (C6-C20)aryl or (C6-C12)aryl. The “(C3-C30)heteroaryl” groups include (C3-C20)heteroaryl or (C3-C12)heteroaryl and the “(C3-C30)cycloalkyl” groups include (C3-C20)cycloalkyl or (C3-C7)cycloalkyl. The “(C2-C30)alkenyl or alkynyl” group include (C2-C20)alkenyl or alkynyl, (C2-C10)alkenyl or alkynyl.

The organic electroluminescent compounds according to the present invention will be specifically exemplified as following compounds but are not limited thereto.

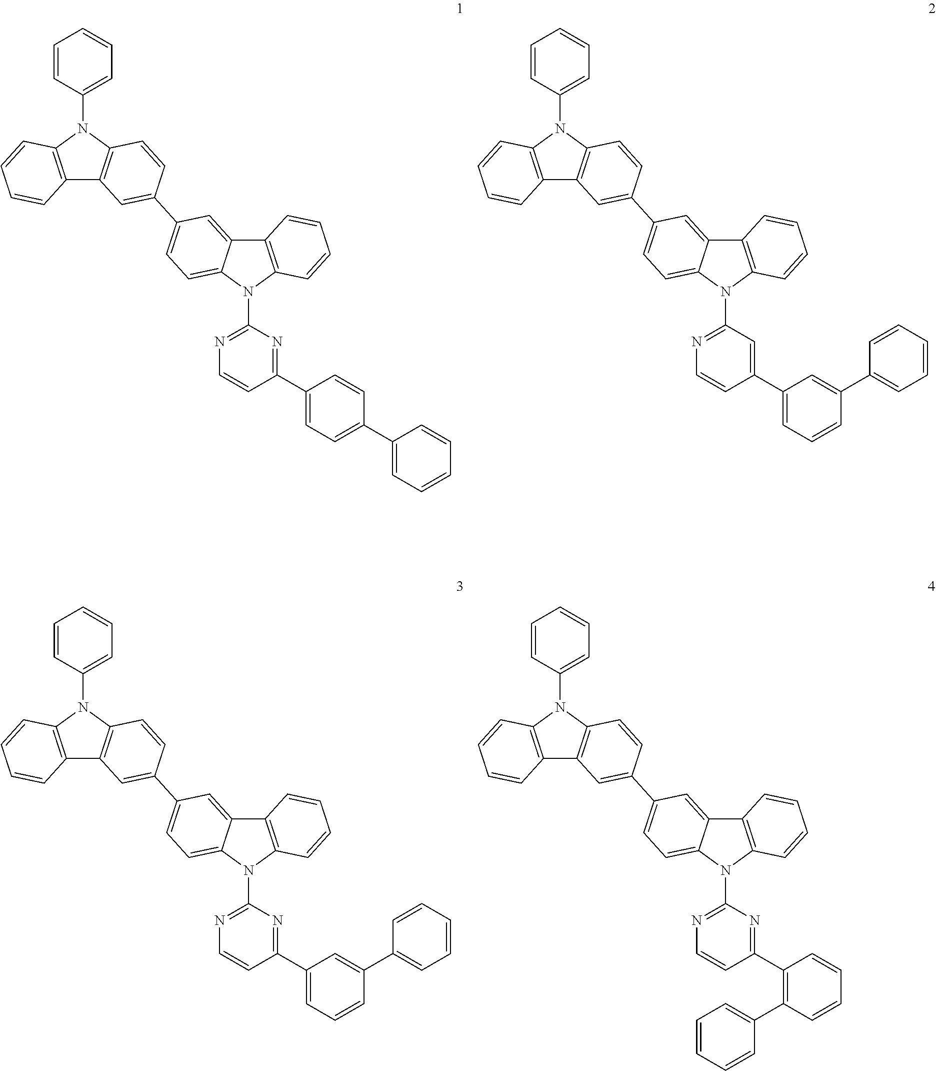 [SMILES: c1ccc(-c2ccc(-c3ccnc(-n4c5ccccc5c5cc(-c6ccc7c(c6)c6ccccc6n7-c6ccccc6)ccc54)n3)cc2)cc1 ; c1ccc(-c2cccc(-c3ccnc(-n4c5ccccc5c5cc(-c6ccc7c(c6)c6ccccc6n7-c6ccccc6)ccc54)c3)c2)cc1 ; c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccccc2-c2ccnc(-n3c4ccccc4c4cc(-c5ccc6c(c5)c5ccccc5n6-c5ccccc5)ccc43)n2)cc1]

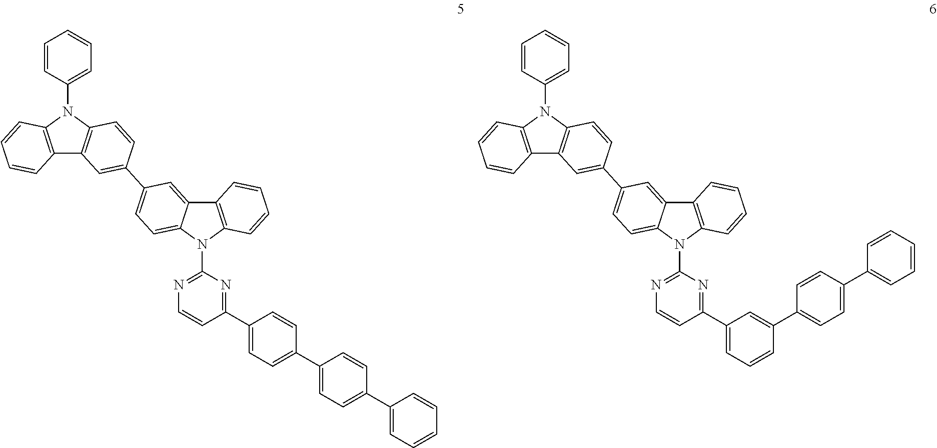 [SMILES: c1ccc(-c2ccc(-c3ccc(-c4ccnc(-n5c6ccccc6c6cc(-c7ccc8c(c7)c7ccccc7n8-c7ccccc7)ccc65)n4)cc3)cc2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

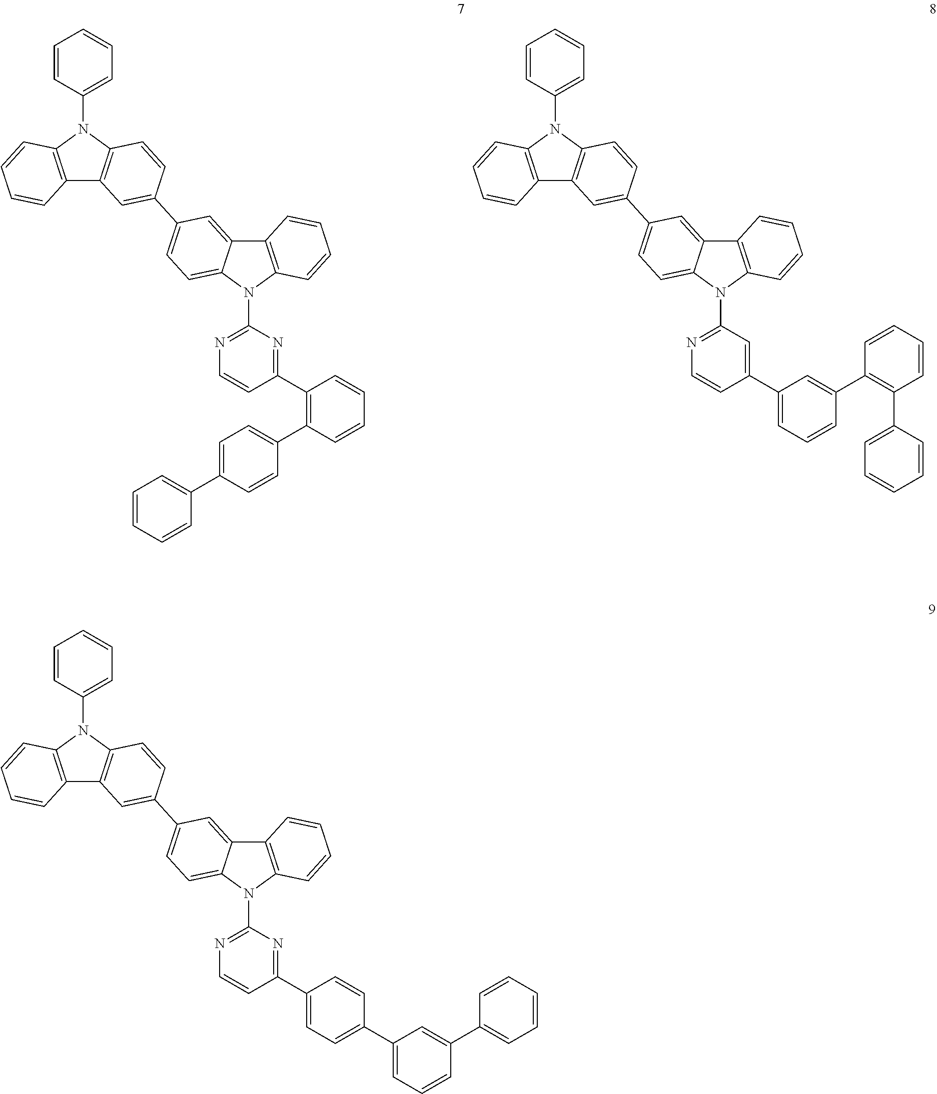 [SMILES: c1ccc(-c2ccc(-c3ccccc3-c3ccnc(-n4c5ccccc5c5cc(-c6ccc7c(c6)c6ccccc6n7-c6ccccc6)ccc54)n3)cc2)cc1 ; c1ccc(-c2ccccc2-c2cccc(-c3ccnc(-n4c5ccccc5c5cc(-c6ccc7c(c6)c6ccccc6n7-c6ccccc6)ccc54)c3)c2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1]

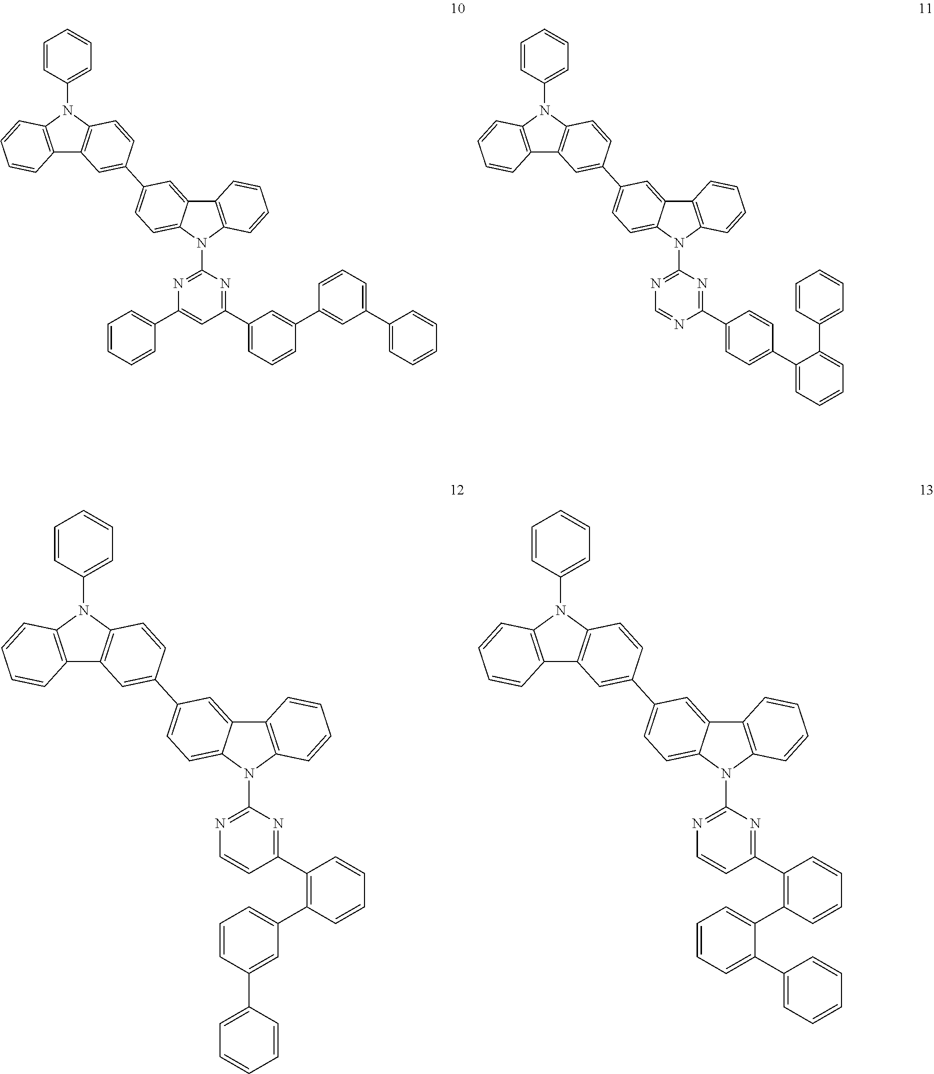 [SMILES: c1ccc(-c2cccc(-c3cccc(-c4cc(-c5ccccc5)nc(-n5c6ccccc6c6cc(-c7ccc8c(c7)c7ccccc7n8-c7ccccc7)ccc65)n4)c3)c2)cc1 ; c1ccc(-c2ccccc2-c2ccc(-c3ncnc(-n4c5ccccc5c5cc(-c6ccc7c(c6)c6ccccc6n7-c6ccccc6)ccc54)n3)cc2)cc1 ; c1ccc(-c2cccc(-c3ccccc3-c3ccnc(-n4c5ccccc5c5cc(-c6ccc7c(c6)c6ccccc6n7-c6ccccc6)ccc54)n3)c2)cc1 ; c1ccc(-c2ccccc2-c2ccccc2-c2ccnc(-n3c4ccccc4c4cc(-c5ccc6c(c5)c5ccccc5n6-c5ccccc5)ccc43)n2)cc1]

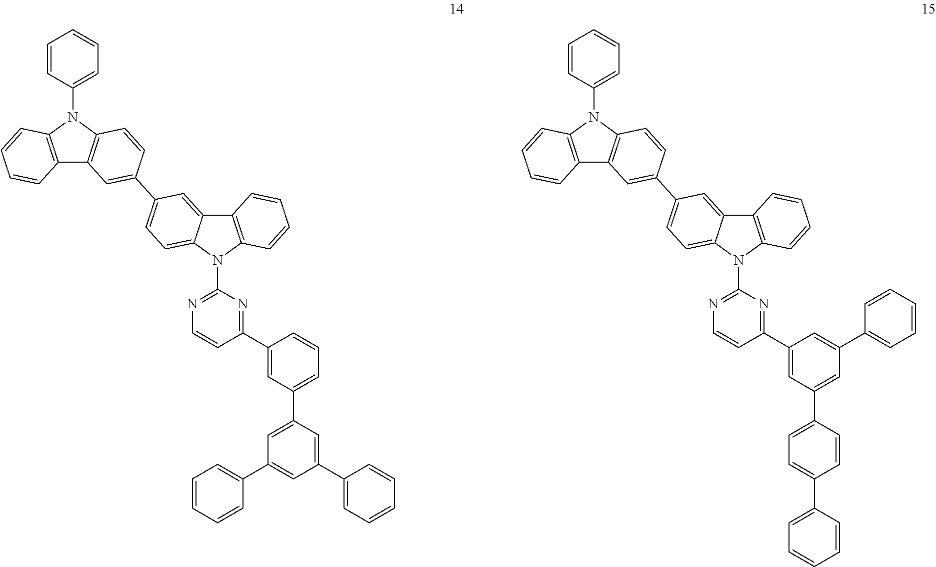 [SMILES: c1ccc(-c2cc(-c3ccccc3)cc(-c3cccc(-c4ccnc(-n5c6ccccc6c6cc(-c7ccc8c(c7)c7ccccc7n8-c7ccccc7)ccc65)n4)c3)c2)cc1 ; c1ccc(-c2ccc(-c3cc(-c4ccccc4)cc(-c4ccnc(-n5c6ccccc6c6cc(-c7ccc8c(c7)c7ccccc7n8-c7ccccc7)ccc65)n4)c3)cc2)cc1]

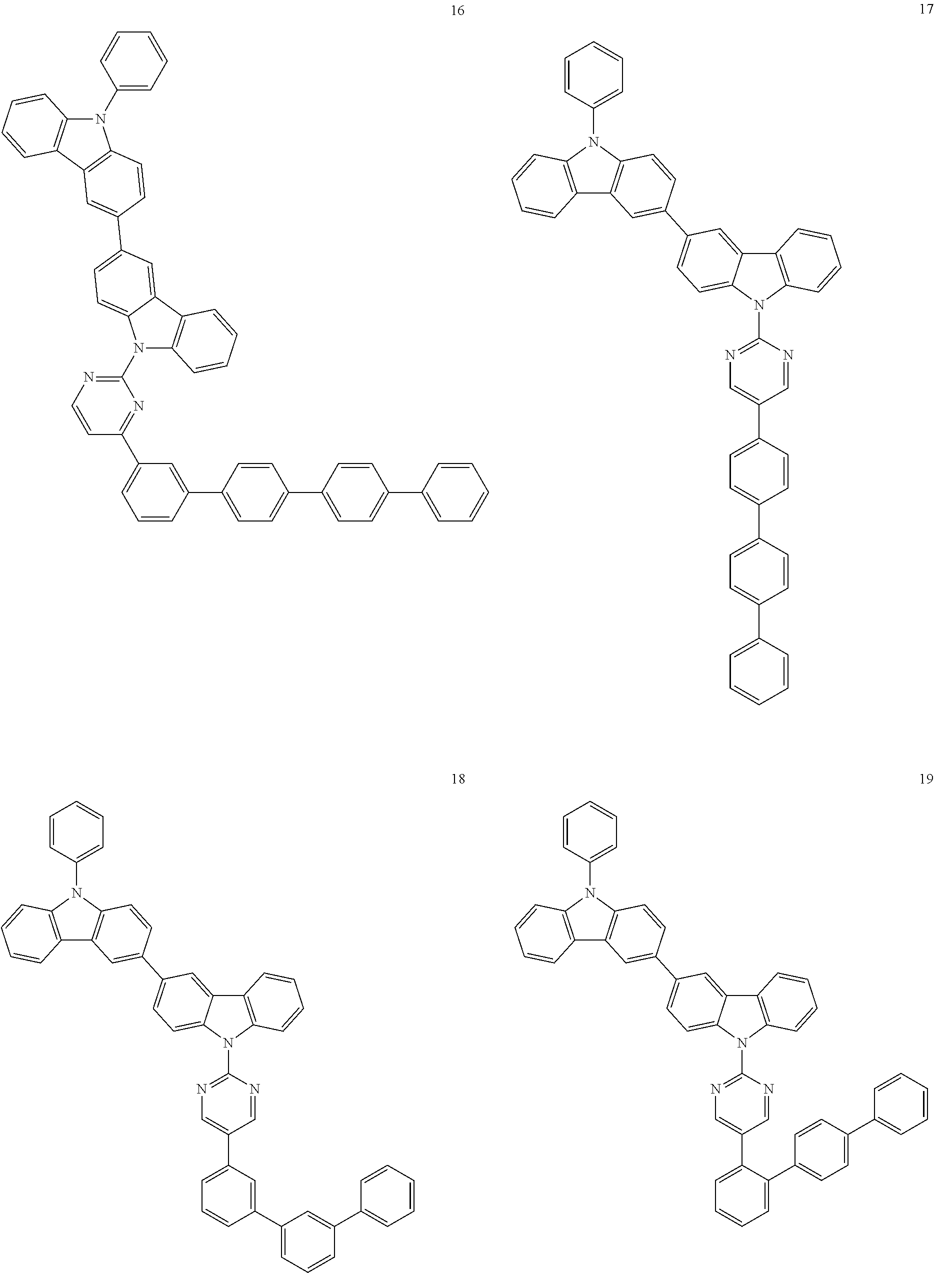 [SMILES: c1ccc(-c2ccc(-c3ccc(-c4cccc(-c5ccnc(-n6c7ccccc7c7cc(-c8ccc9c(c8)c8ccccc8n9-c8ccccc8)ccc76)n5)c4)cc3)cc2)cc1 ; c1ccc(-c2ccc(-c3ccc(-c4cnc(-n5c6ccccc6c6cc(-c7ccc8c(c7)c7ccccc7n8-c7ccccc7)ccc65)nc4)cc3)cc2)cc1 ; c1ccc(-c2cccc(-c3cccc(-c4cnc(-n5c6ccccc6c6cc(-c7ccc8c(c7)c7ccccc7n8-c7ccccc7)ccc65)nc4)c3)c2)cc1 ; c1ccc(-c2ccc(-c3ccccc3-c3cnc(-n4c5ccccc5c5cc(-c6ccc7c(c6)c6ccccc6n7-c6ccccc6)ccc54)nc3)cc2)cc1]

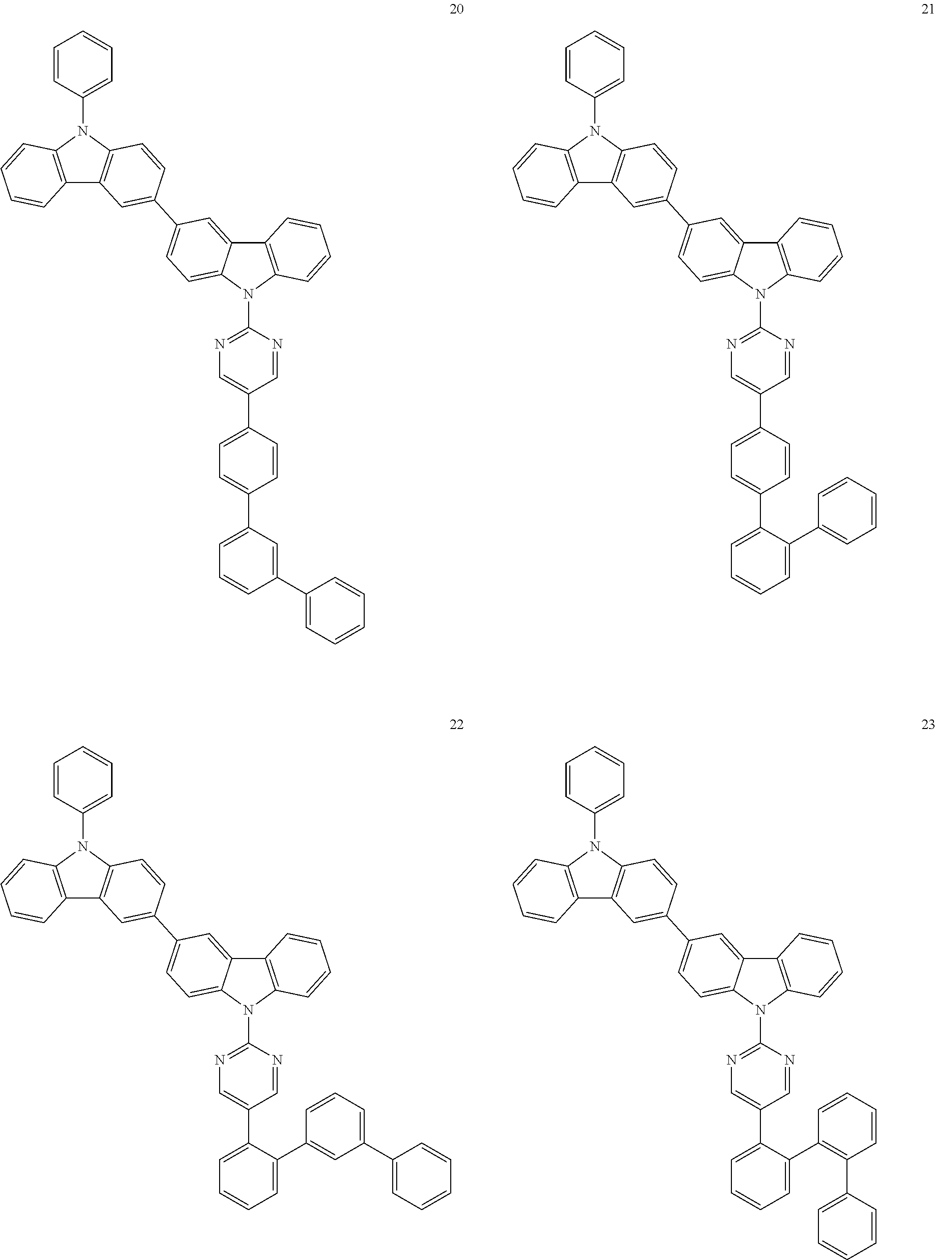 [SMILES: c1ccc(-c2cccc(-c3ccc(-c4cnc(-n5c6ccccc6c6cc(-c7ccc8c(c7)c7ccccc7n8-c7ccccc7)ccc65)nc4)cc3)c2)cc1 ; c1ccc(-c2ccccc2-c2ccc(-c3cnc(-n4c5ccccc5c5cc(-c6ccc7c(c6)c6ccccc6n7-c6ccccc6)ccc54)nc3)cc2)cc1 ; c1ccc(-c2cccc(-c3ccccc3-c3cnc(-n4c5ccccc5c5cc(-c6ccc7c(c6)c6ccccc6n7-c6ccccc6)ccc54)nc3)c2)cc1 ; c1ccc(-c2ccccc2-c2ccccc2-c2cnc(-n3c4ccccc4c4cc(-c5ccc6c(c5)c5ccccc5n6-c5ccccc5)ccc43)nc2)cc1]

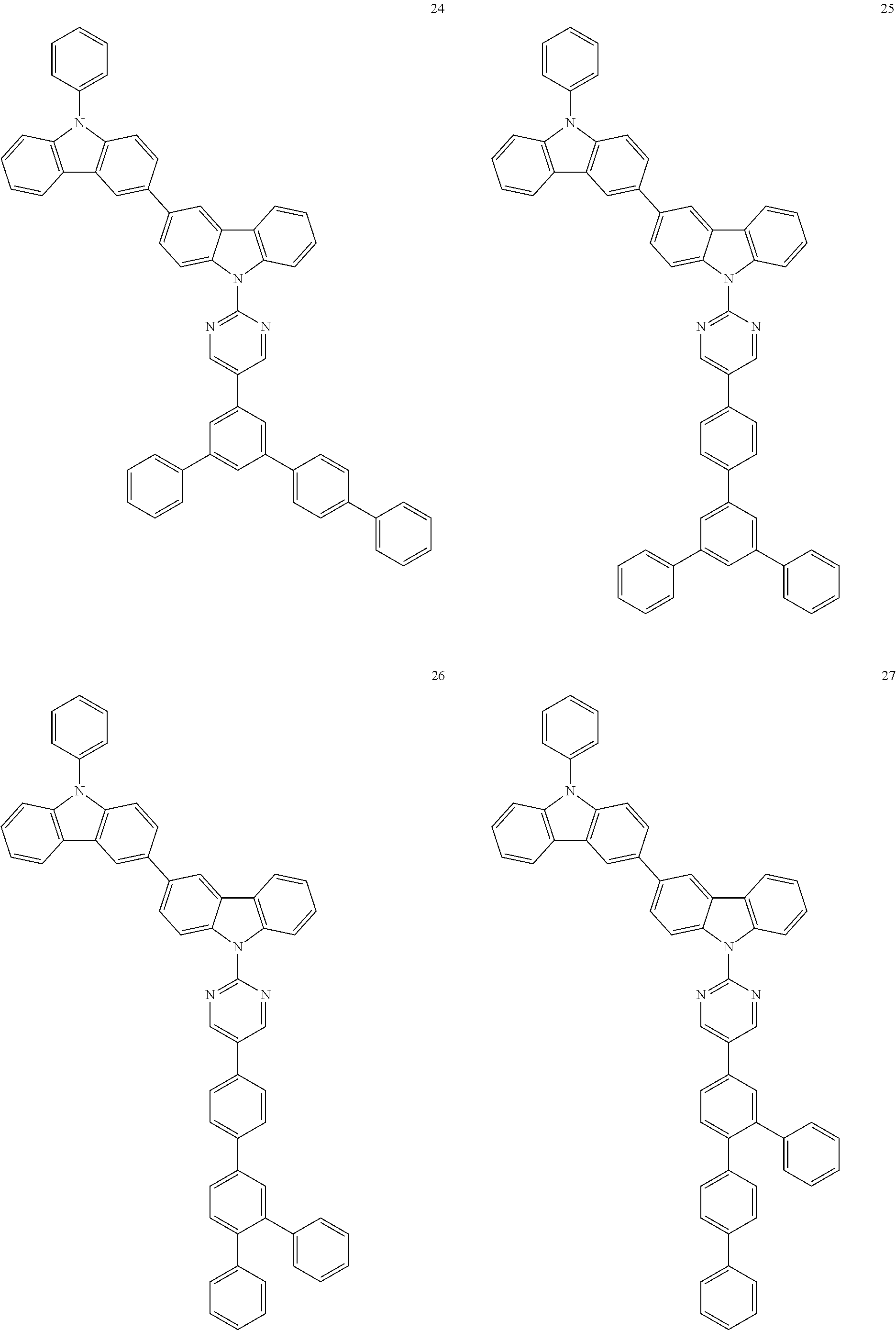 [SMILES: c1ccc(-c2ccc(-c3cc(-c4ccccc4)cc(-c4cnc(-n5c6ccccc6c6cc(-c7ccc8c(c7)c7ccccc7n8-c7ccccc7)ccc65)nc4)c3)cc2)cc1 ; c1ccc(-c2cc(-c3ccccc3)cc(-c3ccc(-c4cnc(-n5c6ccccc6c6cc(-c7ccc8c(c7)c7ccccc7n8-c7ccccc7)ccc65)nc4)cc3)c2)cc1 ; c1ccc(-c2ccc(-c3ccc(-c4cnc(-n5c6ccccc6c6cc(-c7ccc8c(c7)c7ccccc7n8-c7ccccc7)ccc65)nc4)cc3)cc2-c2ccccc2)cc1 ; c1ccc(-c2ccc(-c3ccc(-c4cnc(-n5c6ccccc6c6cc(-c7ccc8c(c7)c7ccccc7n8-c7ccccc7)ccc65)nc4)cc3-c3ccccc3)cc2)cc1]

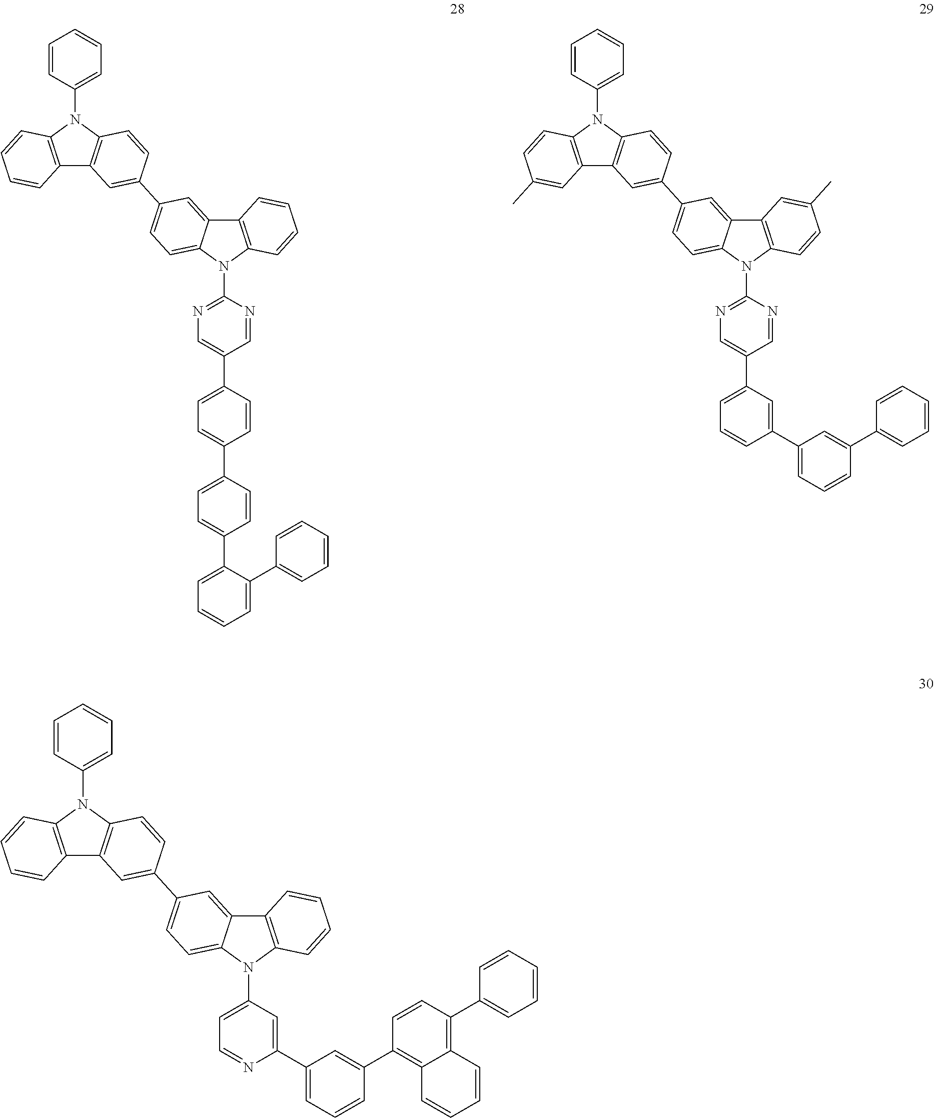 [SMILES: c1ccc(-c2ccccc2-c2ccc(-c3ccc(-c4cnc(-n5c6ccccc6c6cc(-c7ccc8c(c7)c7ccccc7n8-c7ccccc7)ccc65)nc4)cc3)cc2)cc1 ; Cc1ccc2c(c1)c1cc(-c3ccc4c(c3)c3cc(C)ccc3n4-c3ncc(-c4cccc(-c5cccc(-c6ccccc6)c5)c4)cn3)ccc1n2-c1ccccc1 ; c1ccc(-c2ccc(-c3cccc(-c4cc(-n5c6ccccc6c6cc(-c7ccc8c(c7)c7ccccc7n8-c7ccccc7)ccc65)ccn4)c3)c3ccccc23)cc1]

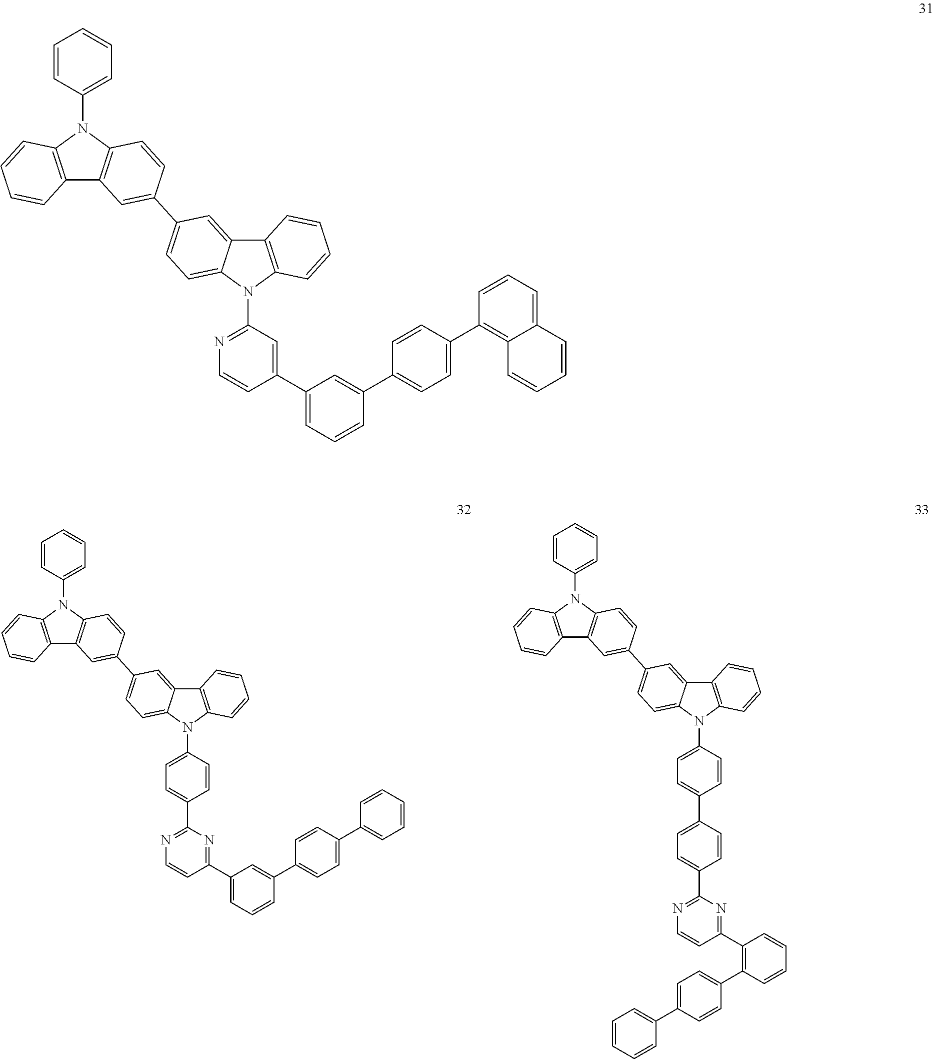 [SMILES: c1ccc(-n2c3ccccc3c3cc(-c4ccc5c(c4)c4ccccc4n5-c4cc(-c5cccc(-c6ccc(-c7cccc8ccccc78)cc6)c5)ccn4)ccc32)cc1 ; c1ccc(-c2ccc(-c3cccc(-c4ccnc(-c5ccc(-n6c7ccccc7c7cc(-c8ccc9c(c8)c8ccccc8n9-c8ccccc8)ccc76)cc5)n4)c3)cc2)cc1 ; c1ccc(-c2ccc(-c3ccccc3-c3ccnc(-c4ccc(-c5ccc(-n6c7ccccc7c7cc(-c8ccc9c(c8)c8ccccc8n9-c8ccccc8)ccc76)cc5)cc4)n3)cc2)cc1]

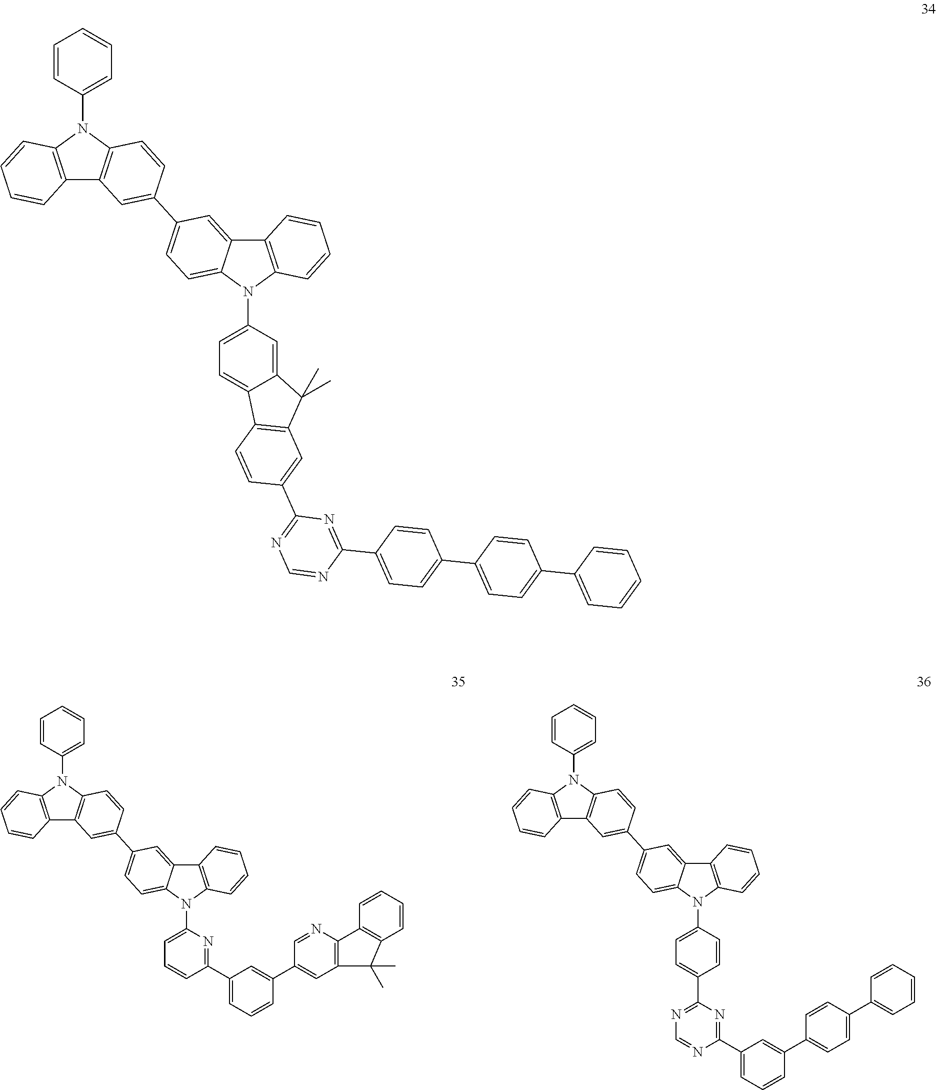 [SMILES: CC1(C)c2cc(-c3ncnc(-c4ccc(-c5ccc(-c6ccccc6)cc5)cc4)n3)ccc2-c2ccc(-n3c4ccccc4c4cc(-c5ccc6c(c5)c5ccccc5n6-c5ccccc5)ccc43)cc21 ; CC1(C)c2ccccc2-c2ncc(-c3cccc(-c4cccc(-n5c6ccccc6c6cc(-c7ccc8c(c7)c7ccccc7n8-c7ccccc7)ccc65)n4)c3)cc21 ; c1ccc(-c2ccc(-c3cccc(-c4ncnc(-c5ccc(-n6c7ccccc7c7cc(-c8ccc9c(c8)c8ccccc8n9-c8ccccc8)ccc76)cc5)n4)c3)cc2)cc1]

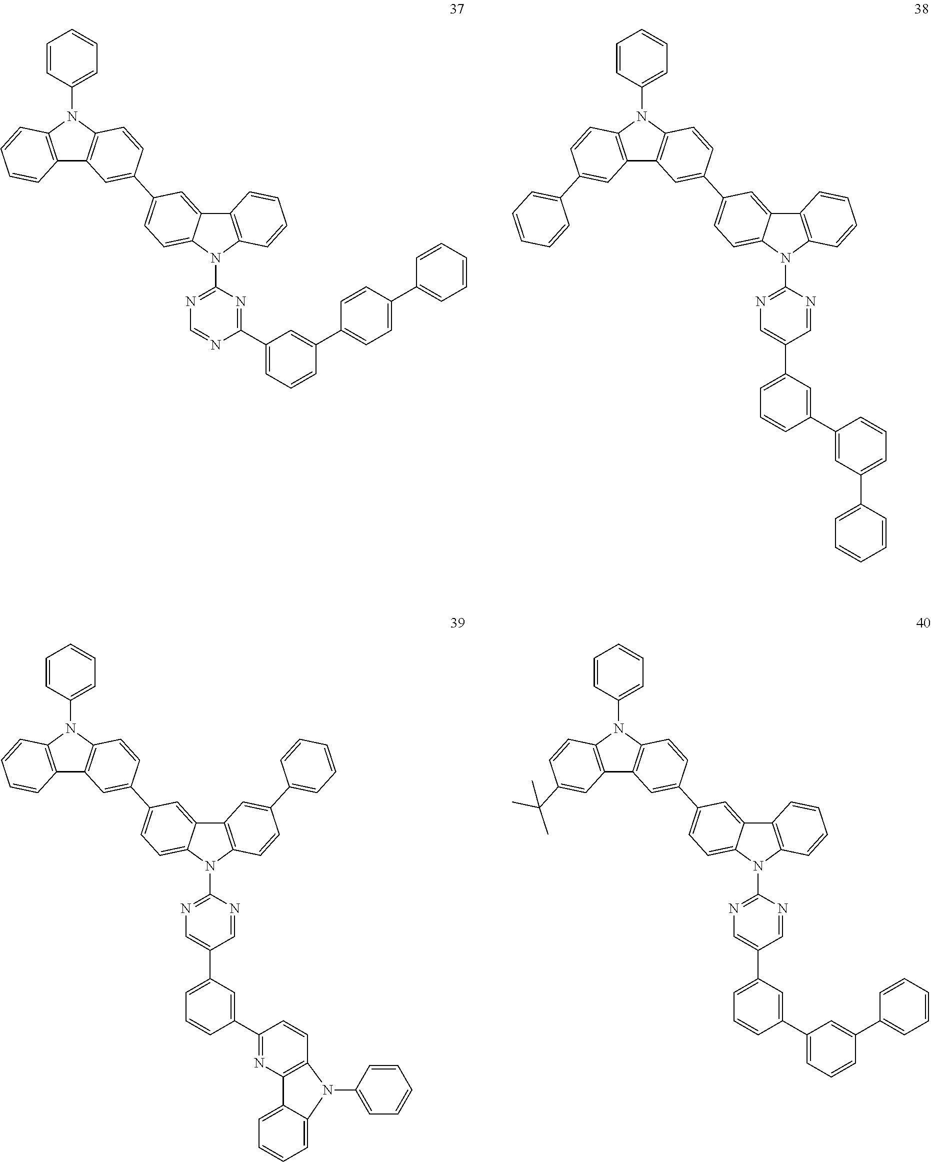 [SMILES: c1ccc(-c2ccc(-c3cccc(-c4ncnc(-n5c6ccccc6c6cc(-c7ccc8c(c7)c7ccccc7n8-c7ccccc7)ccc65)n4)c3)cc2)cc1 ; c1ccc(-c2cccc(-c3cccc(-c4cnc(-n5c6ccccc6c6cc(-c7ccc8c(c7)c7cc(-c9ccccc9)ccc7n8-c7ccccc7)ccc65)nc4)c3)c2)cc1 ; c1ccc(-c2ccc3c(c2)c2cc(-c4ccc5c(c4)c4ccccc4n5-c4ccccc4)ccc2n3-c2ncc(-c3cccc(-c4ccc5c(n4)c4ccccc4n5-c4ccccc4)c3)cn2)cc1 ; CC(C)(C)c1ccc2c(c1)c1cc(-c3ccc4c(c3)c3ccccc3n4-c3ncc(-c4cccc(-c5cccc(-c6ccccc6)c5)c4)cn3)ccc1n2-c1ccccc1]

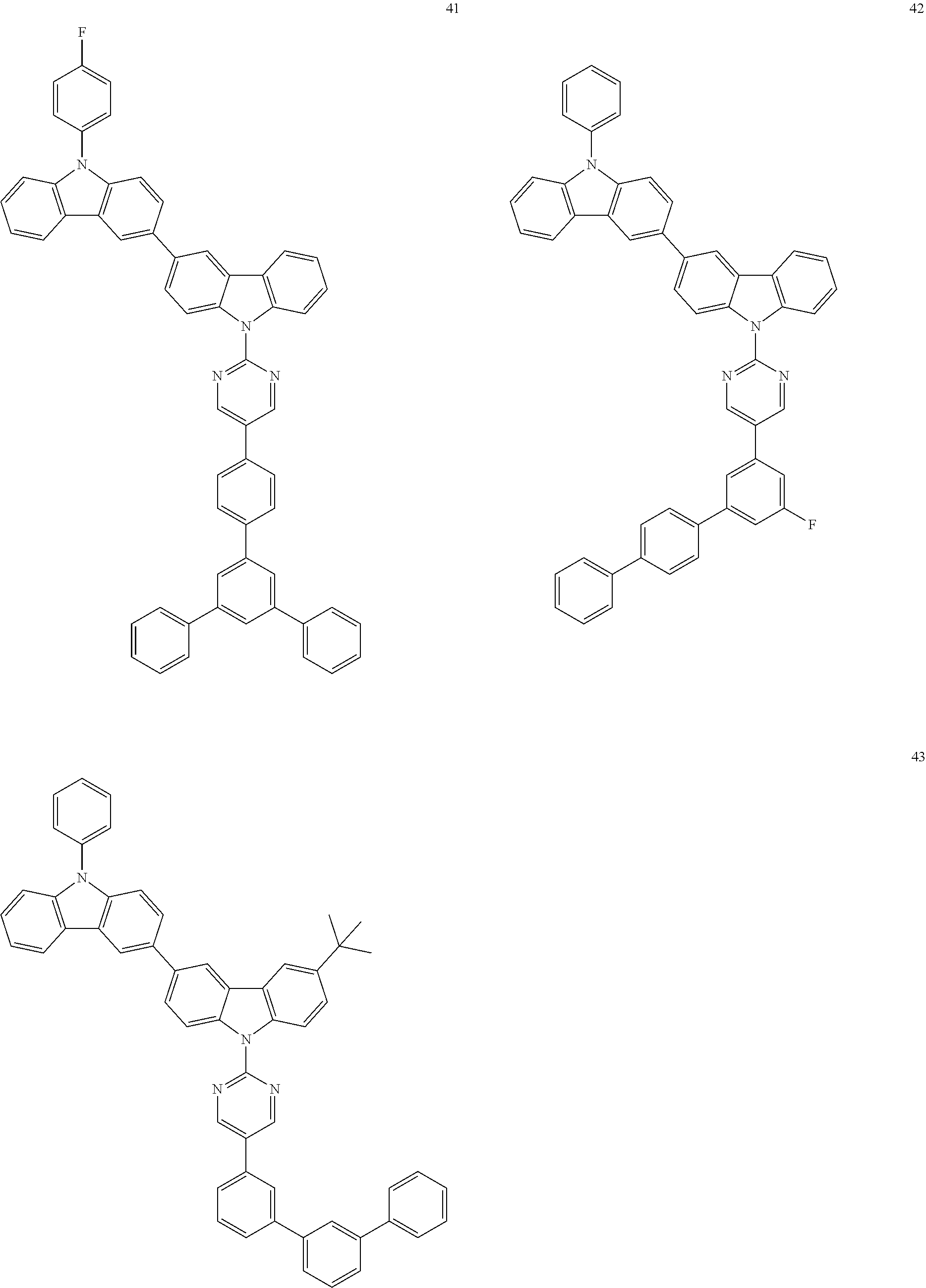 [SMILES: Fc1ccc(-n2c3ccccc3c3cc(-c4ccc5c(c4)c4ccccc4n5-c4ncc(-c5ccc(-c6cc(-c7ccccc7)cc(-c7ccccc7)c6)cc5)cn4)ccc32)cc1 ; Fc1cc(-c2ccc(-c3ccccc3)cc2)cc(-c2cnc(-n3c4ccccc4c4cc(-c5ccc6c(c5)c5ccccc5n6-c5ccccc5)ccc43)nc2)c1 ; CC(C)(C)c1ccc2c(c1)c1cc(-c3ccc4c(c3)c3ccccc3n4-c3ccccc3)ccc1n2-c1ncc(-c2cccc(-c3cccc(-c4ccccc4)c3)c2)cn1]

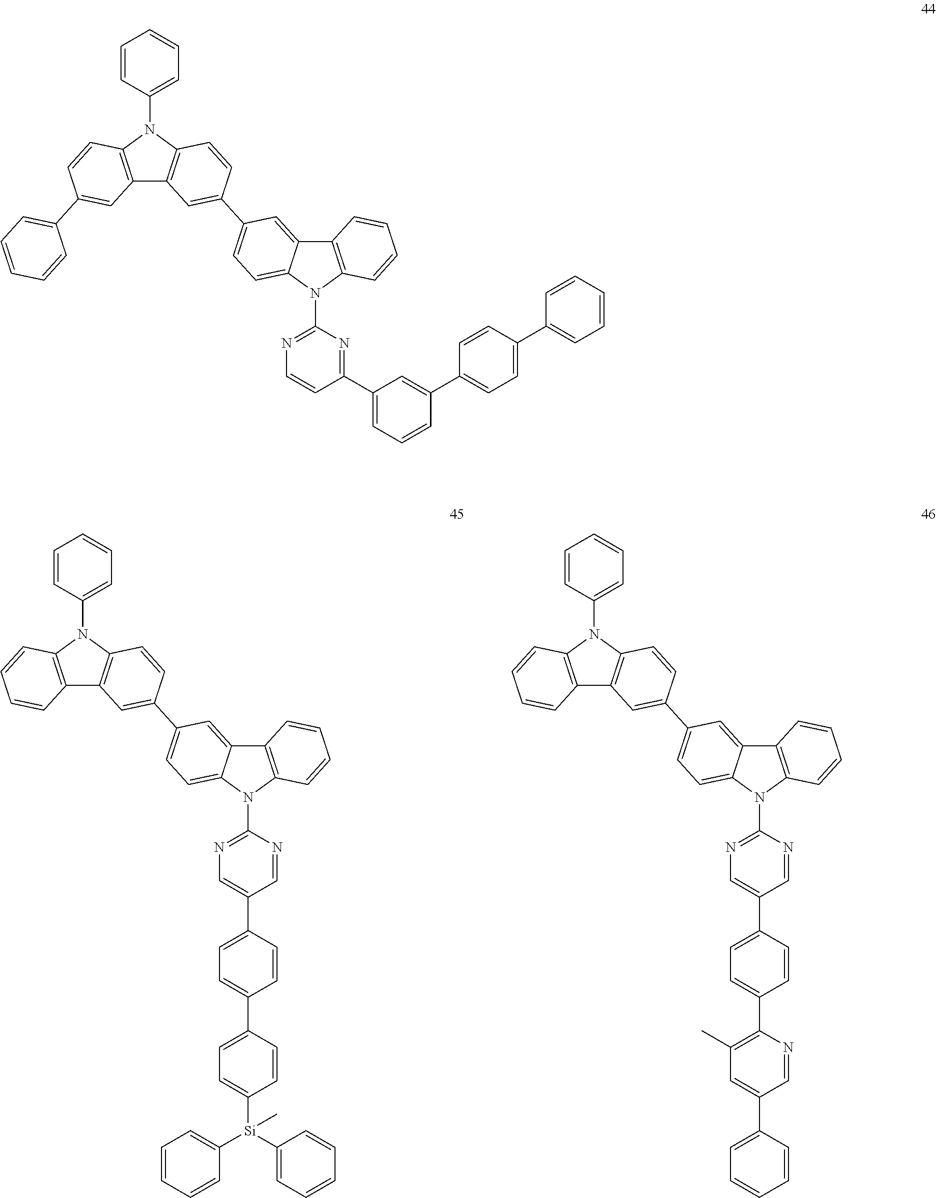 [SMILES: c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1 ; C[Si](c1ccccc1)(c1ccccc1)c1ccc(-c2ccc(-c3cnc(-n4c5ccccc5c5cc(-c6ccc7c(c6)c6ccccc6n7-c6ccccc6)ccc54)nc3)cc2)cc1 ; Cc1cc(-c2ccccc2)cnc1-c1ccc(-c2cnc(-n3c4ccccc4c4cc(-c5ccc6c(c5)c5ccccc5n6-c5ccccc5)ccc43)nc2)cc1]

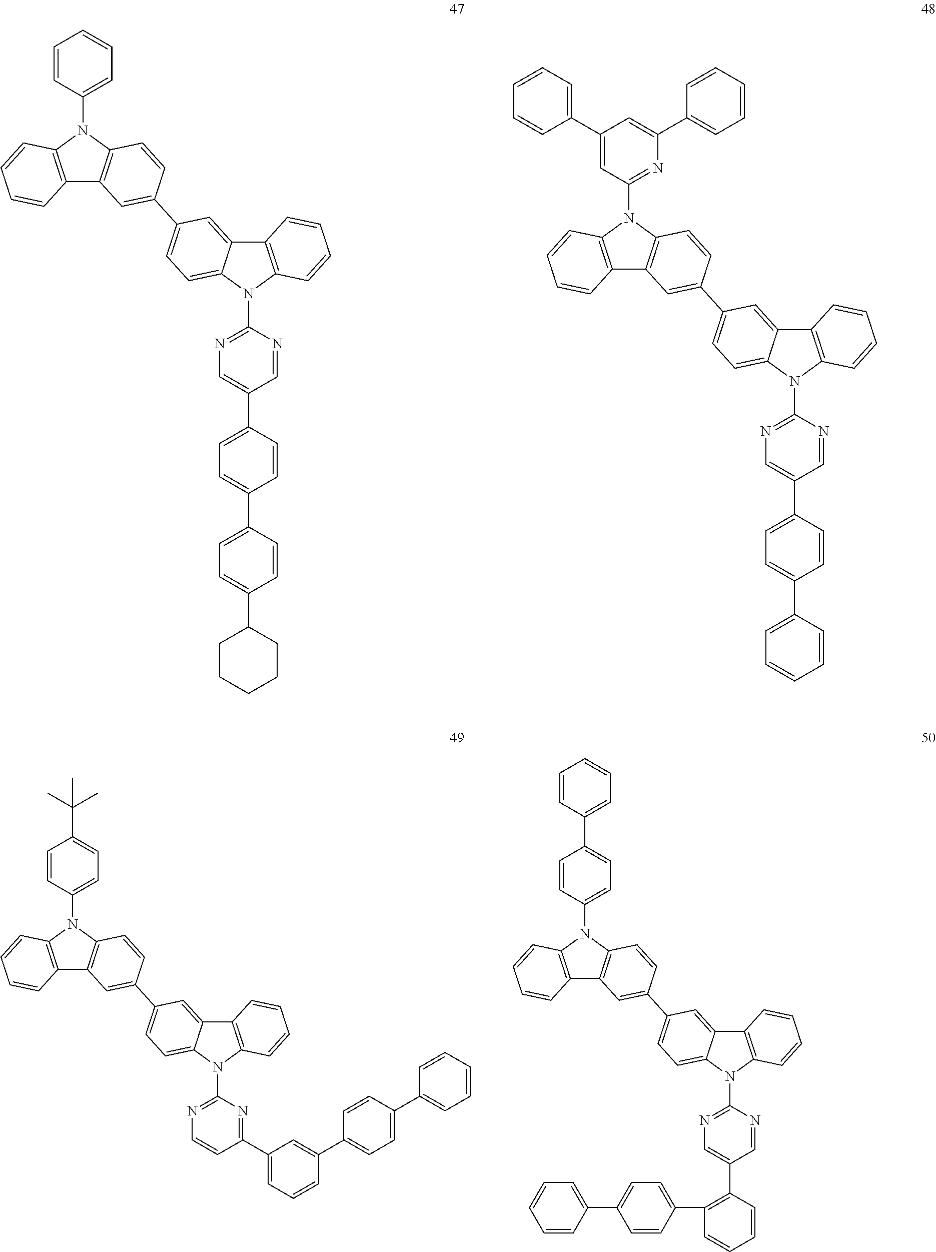 [SMILES: c1ccc(-n2c3ccccc3c3cc(-c4ccc5c(c4)c4ccccc4n5-c4ncc(-c5ccc(-c6ccc(C7CCCCC7)cc6)cc5)cn4)ccc32)cc1 ; c1ccc(-c2ccc(-c3cnc(-n4c5ccccc5c5cc(-c6ccc7c(c6)c6ccccc6n7-c6cc(-c7ccccc7)cc(-c7ccccc7)n6)ccc54)nc3)cc2)cc1 ; CC(C)(C)c1ccc(-n2c3ccccc3c3cc(-c4ccc5c(c4)c4ccccc4n5-c4nccc(-c5cccc(-c6ccc(-c7ccccc7)cc6)c5)n4)ccc32)cc1 ; c1ccc(-c2ccc(-c3ccccc3-c3cnc(-n4c5ccccc5c5cc(-c6ccc7c(c6)c6ccccc6n7-c6ccc(-c7ccccc7)cc6)ccc54)nc3)cc2)cc1]

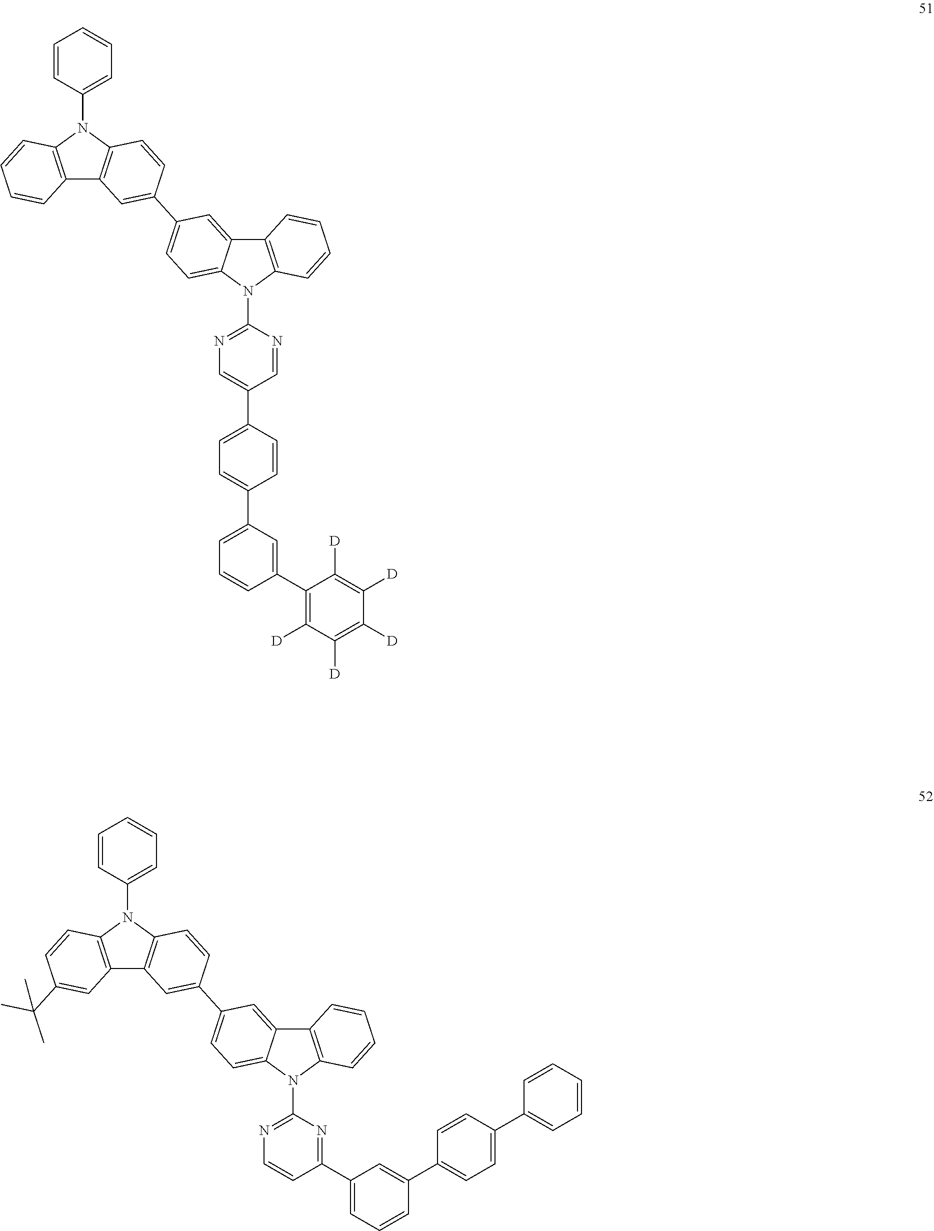 [SMILES: [2H]c1c([2H])c([2H])c(-c2cccc(-c3ccc(-c4cnc(-n5c6ccccc6c6cc(-c7ccc8c(c7)c7ccccc7n8-c7ccccc7)ccc65)nc4)cc3)c2)c([2H])c1[2H] ; CC(C)(C)c1ccc2c(c1)c1cc(-c3ccc4c(c3)c3ccccc3n4-c3nccc(-c4cccc(-c5ccc(-c6ccccc6)cc5)c4)n3)ccc1n2-c1ccccc1]

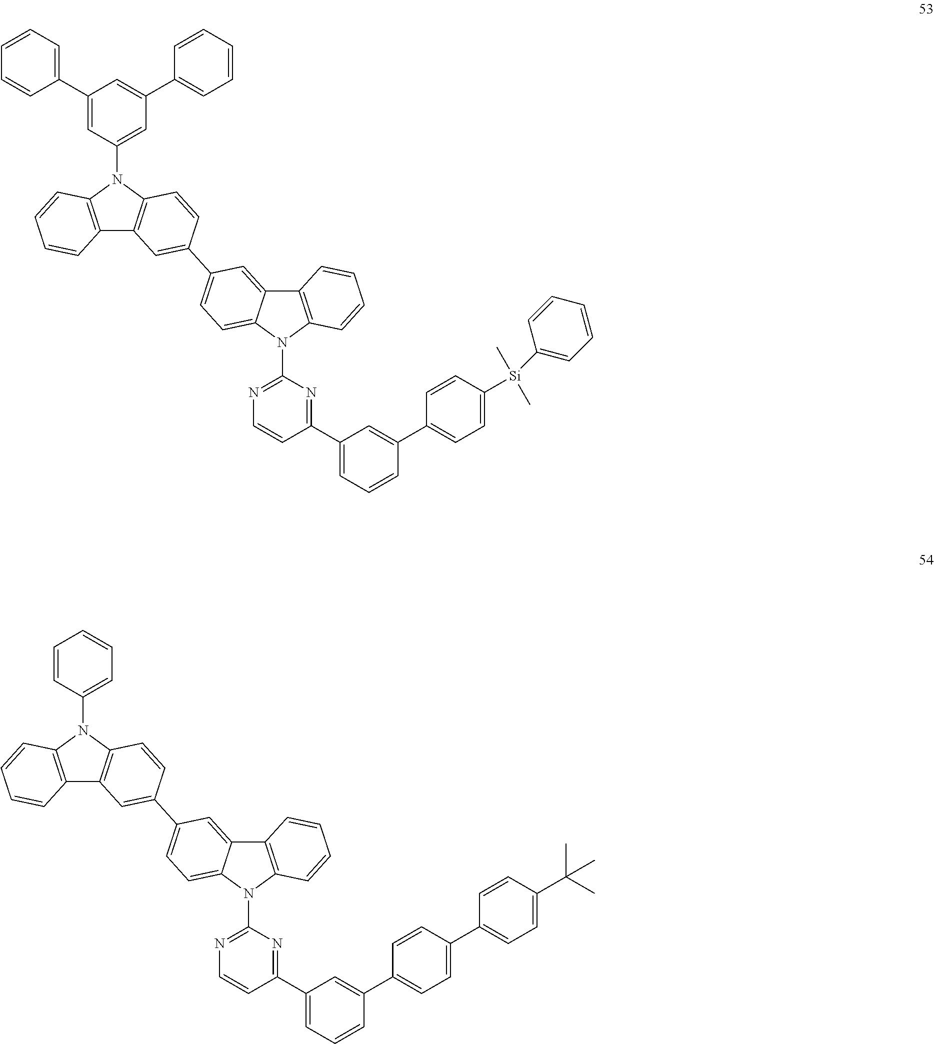 [SMILES: C[Si](C)(c1ccccc1)c1ccc(-c2cccc(-c3ccnc(-n4c5ccccc5c5cc(-c6ccc7c(c6)c6ccccc6n7-c6cc(-c7ccccc7)cc(-c7ccccc7)c6)ccc54)n3)c2)cc1 ; CC(C)(C)c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

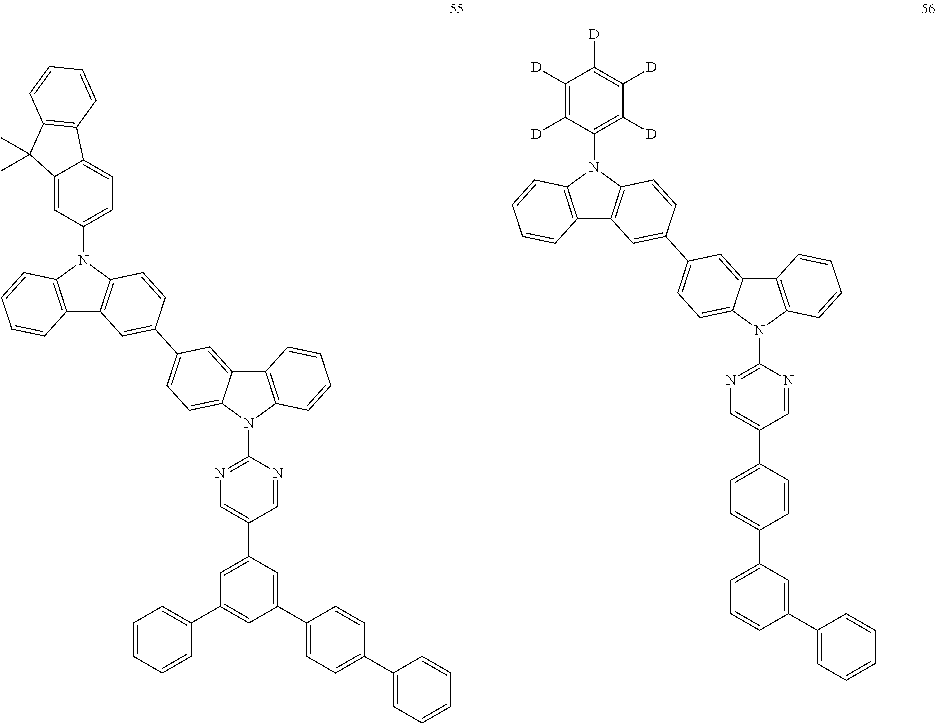 [SMILES: CC1(C)c2ccccc2-c2ccc(-n3c4ccccc4c4cc(-c5ccc6c(c5)c5ccccc5n6-c5ncc(-c6cc(-c7ccccc7)cc(-c7ccc(-c8ccccc8)cc7)c6)cn5)ccc43)cc21 ; [2H]c1c([2H])c([2H])c(-n2c3ccccc3c3cc(-c4ccc5c(c4)c4ccccc4n5-c4ncc(-c5ccc(-c6cccc(-c7ccccc7)c6)cc5)cn4)ccc32)c([2H])c1[2H]]

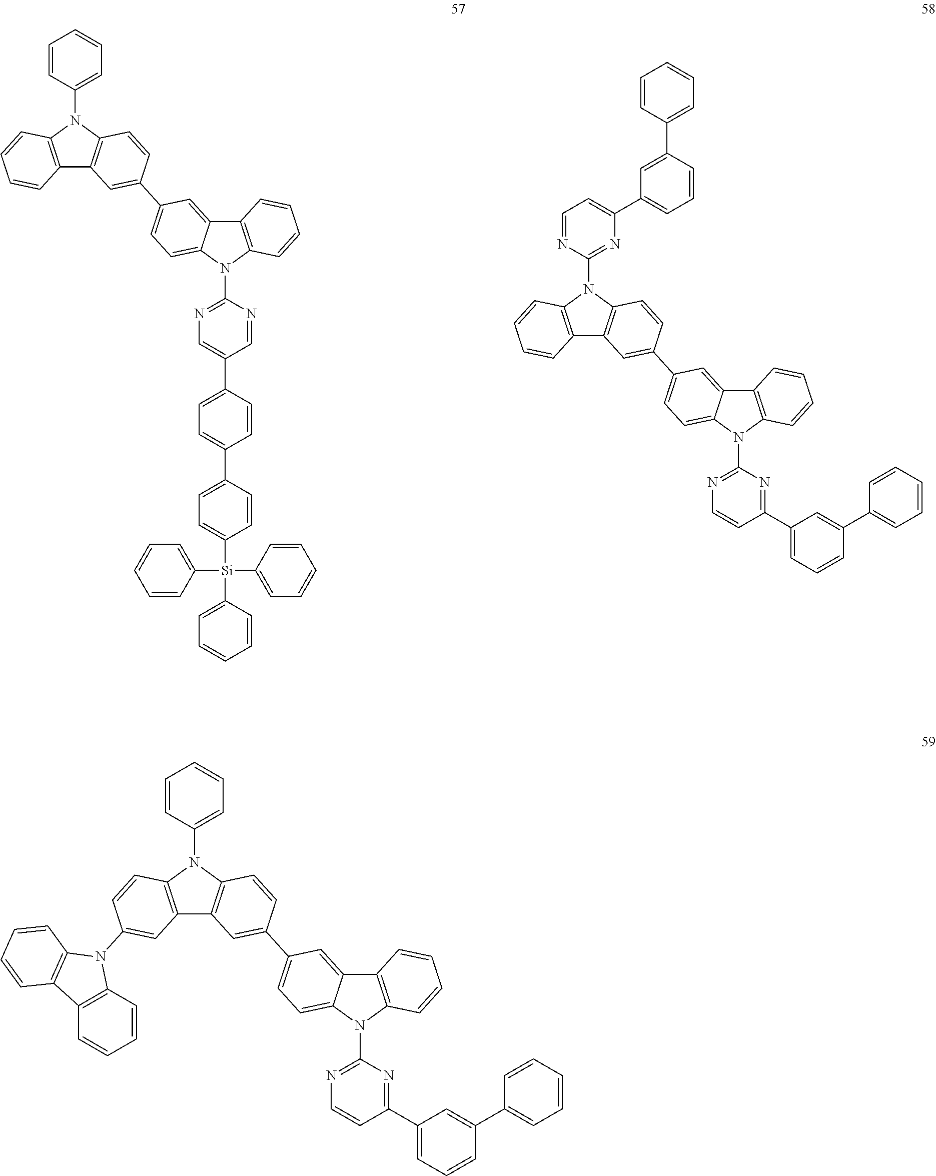 [SMILES: c1ccc(-n2c3ccccc3c3cc(-c4ccc5c(c4)c4ccccc4n5-c4ncc(-c5ccc(-c6ccc([Si](c7ccccc7)(c7ccccc7)c7ccccc7)cc6)cc5)cn4)ccc32)cc1 ; c1ccc(-c2cccc(-c3ccnc(-n4c5ccccc5c5cc(-c6ccc7c(c6)c6ccccc6n7-c6nccc(-c7cccc(-c8ccccc8)c7)n6)ccc54)n3)c2)cc1 ; c1ccc(-c2cccc(-c3ccnc(-n4c5ccccc5c5cc(-c6ccc7c(c6)c6cc(-n8c9ccccc9c9ccccc98)ccc6n7-c6ccccc6)ccc54)n3)c2)cc1]

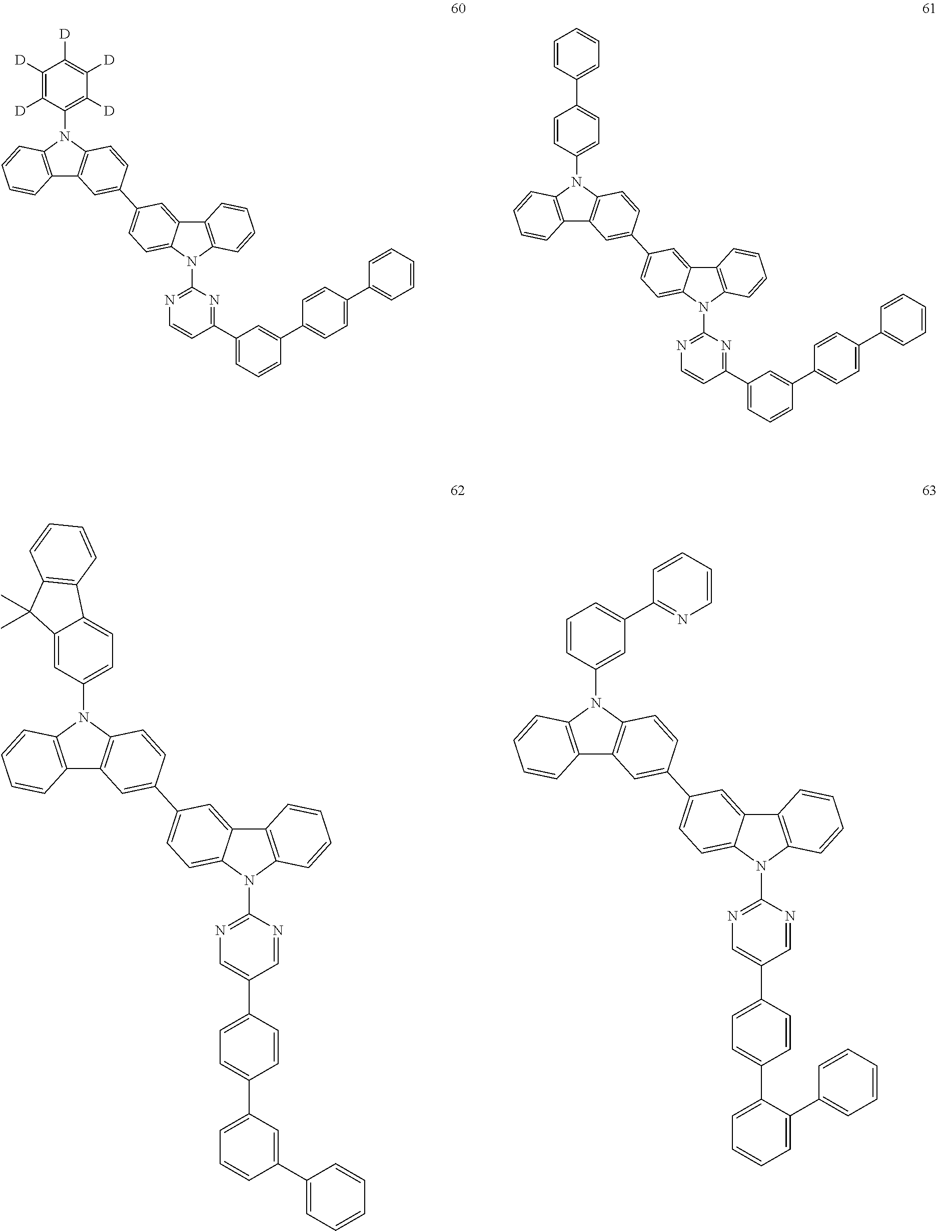 [SMILES: [2H]c1c([2H])c([2H])c(-n2c3ccccc3c3cc(-c4ccc5c(c4)c4ccccc4n5-c4nccc(-c5cccc(-c6ccc(-c7ccccc7)cc6)c5)n4)ccc32)c([2H])c1[2H] ; c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1 ; CC1(C)c2ccccc2-c2ccc(-n3c4ccccc4c4cc(-c5ccc6c(c5)c5ccccc5n6-c5ncc(-c6ccc(-c7cccc(-c8ccccc8)c7)cc6)cn5)ccc43)cc21 ; c1ccc(-c2ccccc2-c2ccc(-c3cnc(-n4c5ccccc5c5cc(-c6ccc7c(c6)c6ccccc6n7-c6cccc(-c7ccccn7)c6)ccc54)nc3)cc2)cc1]

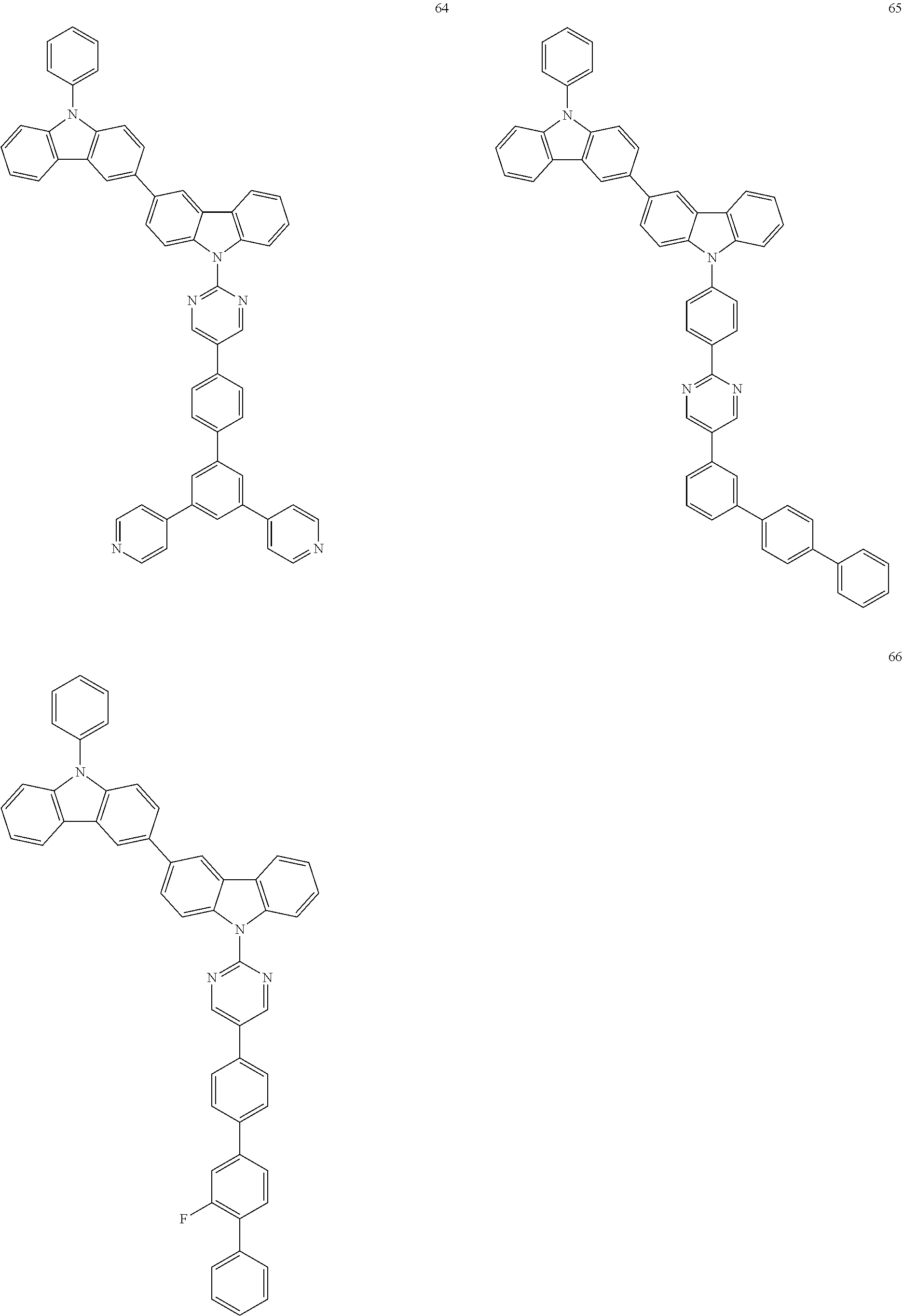 [SMILES: c1ccc(-n2c3ccccc3c3cc(-c4ccc5c(c4)c4ccccc4n5-c4ncc(-c5ccc(-c6cc(-c7ccncc7)cc(-c7ccncc7)c6)cc5)cn4)ccc32)cc1 ; c1ccc(-c2ccc(-c3cccc(-c4cnc(-c5ccc(-n6c7ccccc7c7cc(-c8ccc9c(c8)c8ccccc8n9-c8ccccc8)ccc76)cc5)nc4)c3)cc2)cc1 ; Fc1cc(-c2ccc(-c3cnc(-n4c5ccccc5c5cc(-c6ccc7c(c6)c6ccccc6n7-c6ccccc6)ccc54)nc3)cc2)ccc1-c1ccccc1]

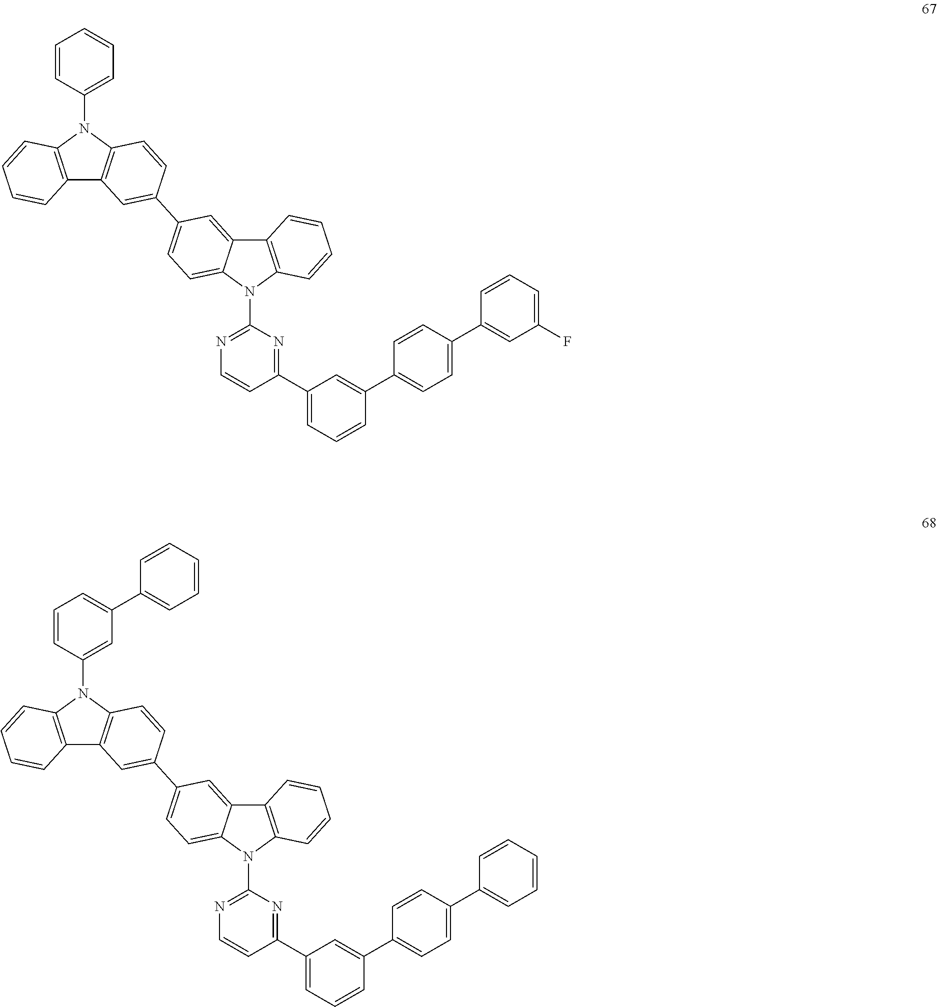 [SMILES: Fc1cccc(-c2ccc(-c3cccc(-c4ccnc(-n5c6ccccc6c6cc(-c7ccc8c(c7)c7ccccc7n8-c7ccccc7)ccc65)n4)c3)cc2)c1 ; c1ccc(-c2ccc(-c3cccc(-c4ccnc(-n5c6ccccc6c6cc(-c7ccc8c(c7)c7ccccc7n8-c7cccc(-c8ccccc8)c7)ccc65)n4)c3)cc2)cc1]

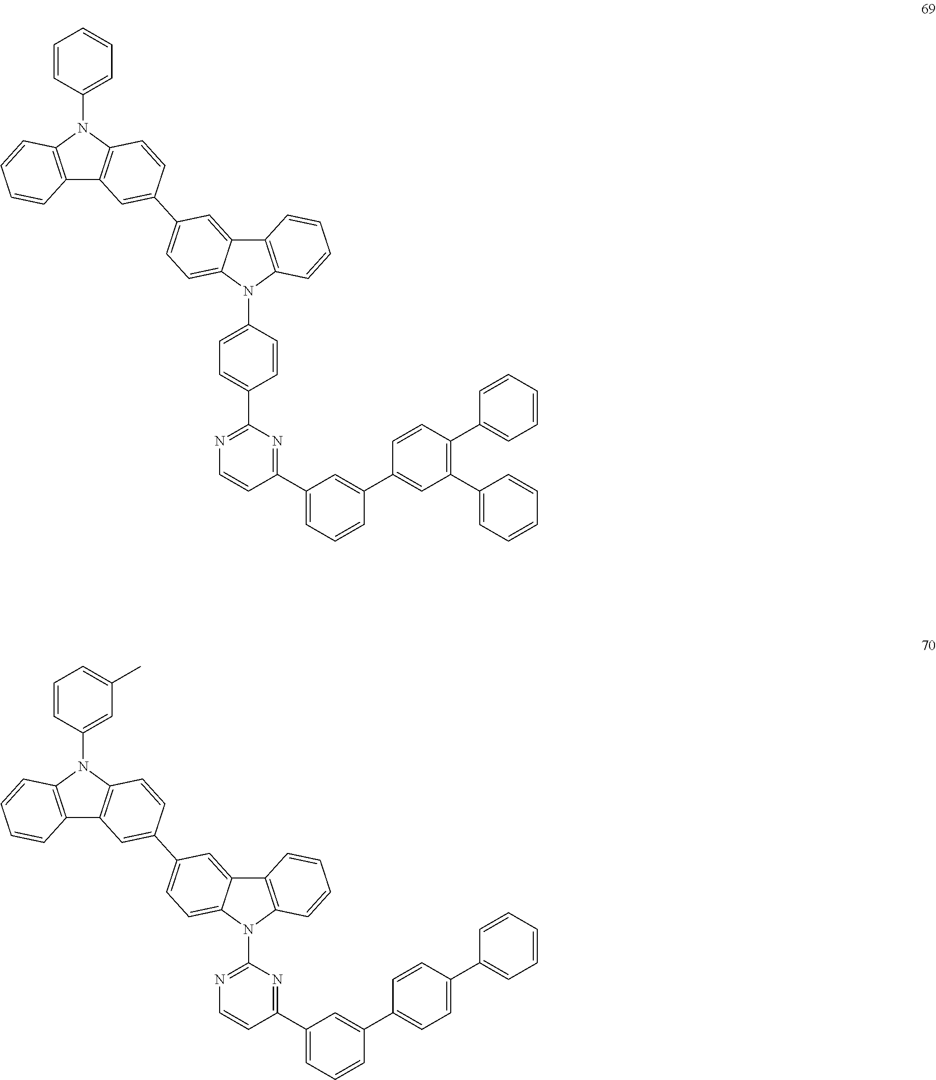 [SMILES: c1ccc(-c2ccc(-c3cccc(-c4ccnc(-c5ccc(-n6c7ccccc7c7cc(-c8ccc9c(c8)c8ccccc8n9-c8ccccc8)ccc76)cc5)n4)c3)cc2-c2ccccc2)cc1 ; Cc1cccc(-n2c3ccccc3c3cc(-c4ccc5c(c4)c4ccccc4n5-c4nccc(-c5cccc(-c6ccc(-c7ccccc7)cc6)c5)n4)ccc32)c1]

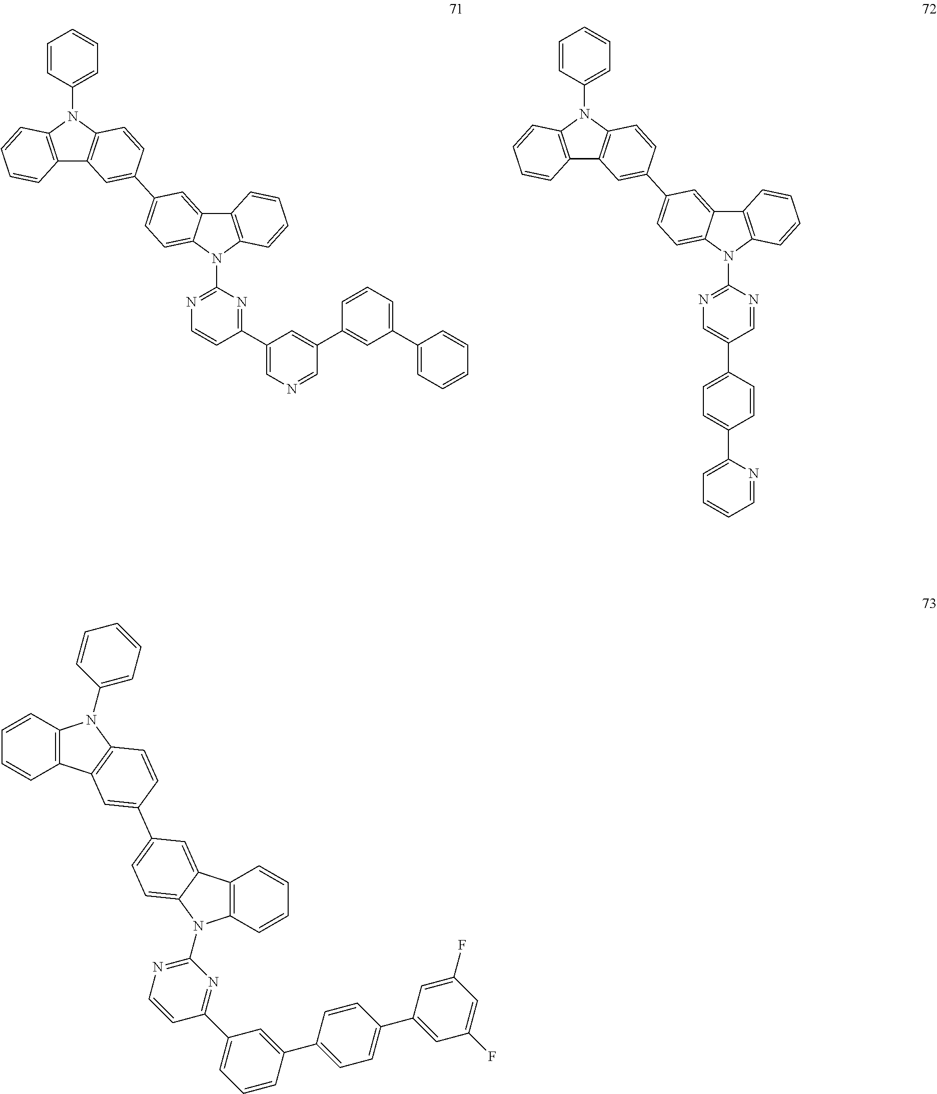 [SMILES: c1ccc(-c2cccc(-c3cncc(-c4ccnc(-n5c6ccccc6c6cc(-c7ccc8c(c7)c7ccccc7n8-c7ccccc7)ccc65)n4)c3)c2)cc1 ; c1ccc(-n2c3ccccc3c3cc(-c4ccc5c(c4)c4ccccc4n5-c4ncc(-c5ccc(-c6ccccn6)cc5)cn4)ccc32)cc1 ; Fc1cc(F)cc(-c2ccc(-c3cccc(-c4ccnc(-n5c6ccccc6c6cc(-c7ccc8c(c7)c7ccccc7n8-c7ccccc7)ccc65)n4)c3)cc2)c1]

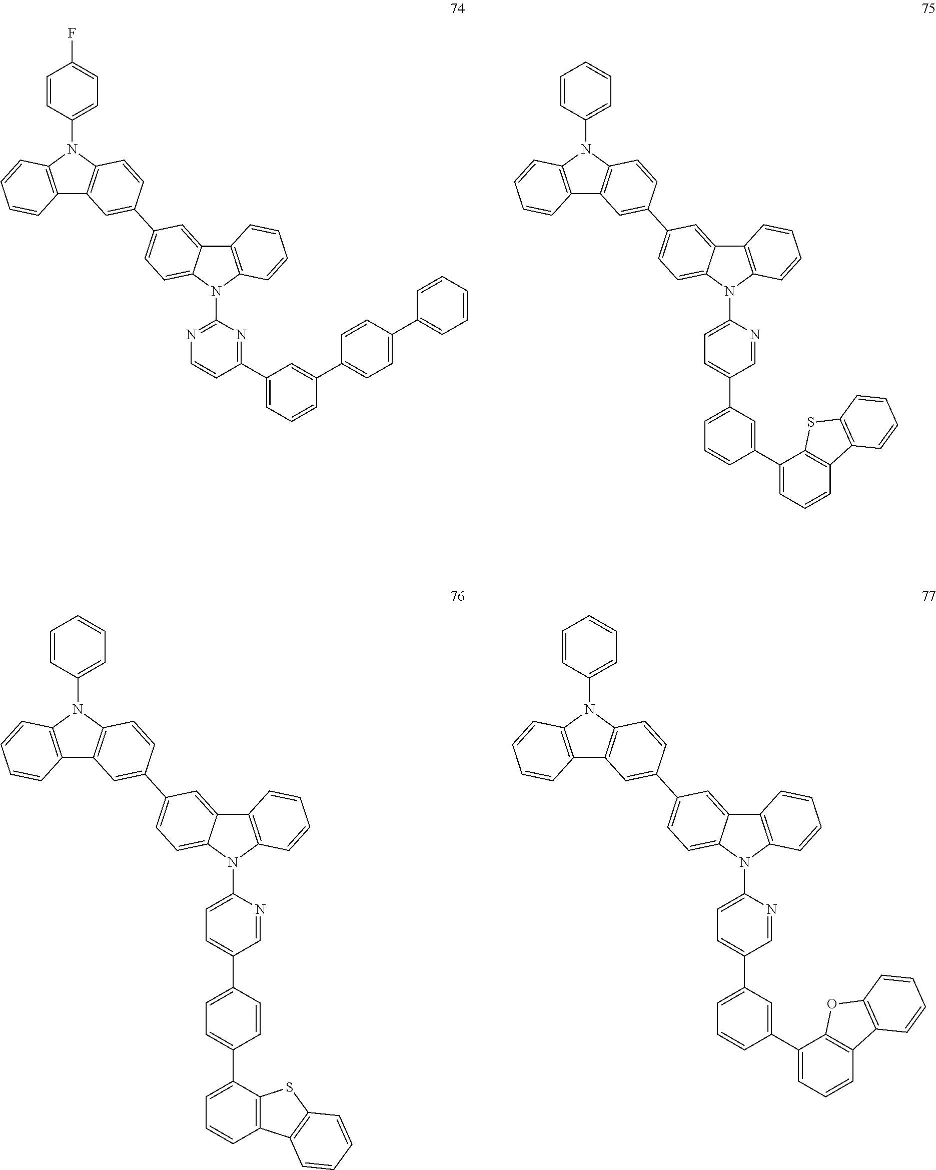 [SMILES: Fc1ccc(-n2c3ccccc3c3cc(-c4ccc5c(c4)c4ccccc4n5-c4nccc(-c5cccc(-c6ccc(-c7ccccc7)cc6)c5)n4)ccc32)cc1 ; c1ccc(-n2c3ccccc3c3cc(-c4ccc5c(c4)c4ccccc4n5-c4ccc(-c5cccc(-c6cccc7c6sc6ccccc67)c5)cn4)ccc32)cc1 ; c1ccc(-n2c3ccccc3c3cc(-c4ccc5c(c4)c4ccccc4n5-c4ccc(-c5ccc(-c6cccc7c6sc6ccccc67)cc5)cn4)ccc32)cc1 ; c1ccc(-n2c3ccccc3c3cc(-c4ccc5c(c4)c4ccccc4n5-c4ccc(-c5cccc(-c6cccc7c6oc6ccccc67)c5)cn4)ccc32)cc1]

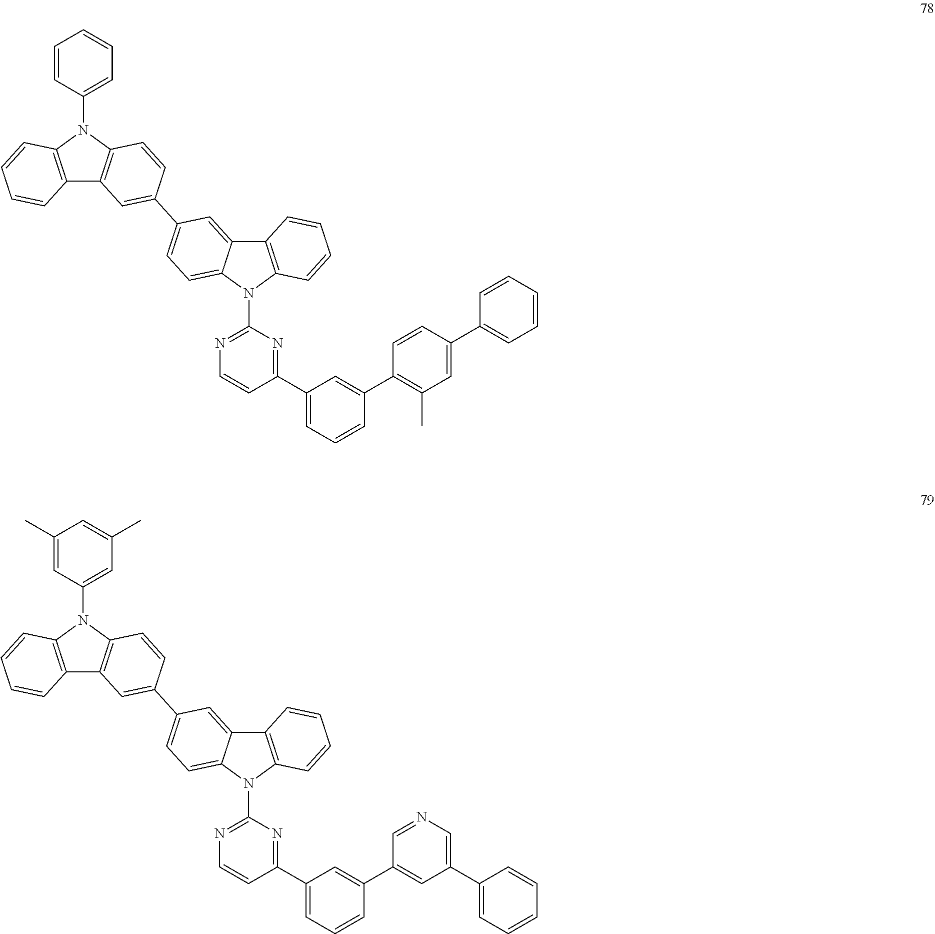 [SMILES: Cc1cc(-c2ccccc2)ccc1-c1cccc(-c2ccnc(-n3c4ccccc4c4cc(-c5ccc6c(c5)c5ccccc5n6-c5ccccc5)ccc43)n2)c1 ; Cc1cc(C)cc(-n2c3ccccc3c3cc(-c4ccc5c(c4)c4ccccc4n5-c4nccc(-c5cccc(-c6cncc(-c7ccccc7)c6)c5)n4)ccc32)c1]

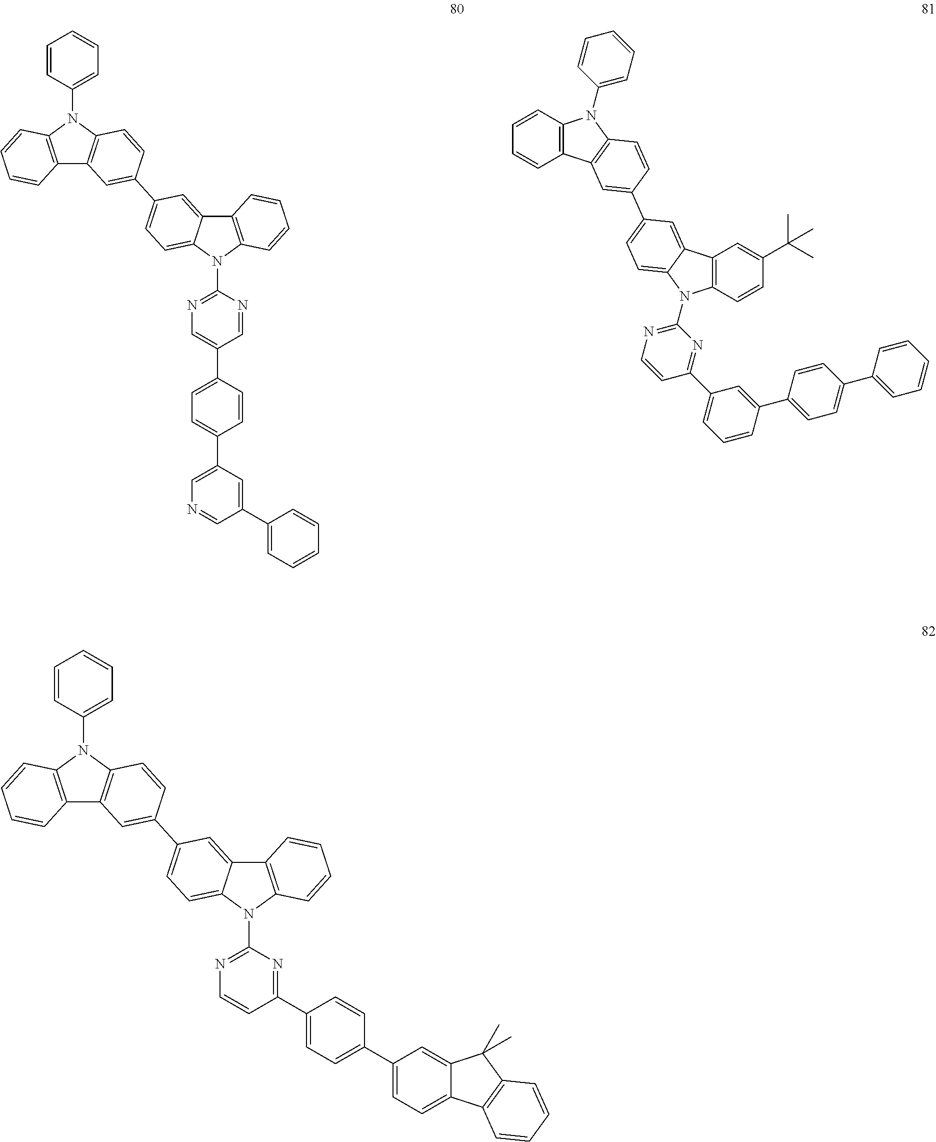 [SMILES: c1ccc(-c2cncc(-c3ccc(-c4cnc(-n5c6ccccc6c6cc(-c7ccc8c(c7)c7ccccc7n8-c7ccccc7)ccc65)nc4)cc3)c2)cc1 ; CC(C)(C)c1ccc2c(c1)c1cc(-c3ccc4c(c3)c3ccccc3n4-c3ccccc3)ccc1n2-c1nccc(-c2cccc(-c3ccc(-c4ccccc4)cc3)c2)n1 ; CC1(C)c2ccccc2-c2ccc(-c3ccc(-c4ccnc(-n5c6ccccc6c6cc(-c7ccc8c(c7)c7ccccc7n8-c7ccccc7)ccc65)n4)cc3)cc21]

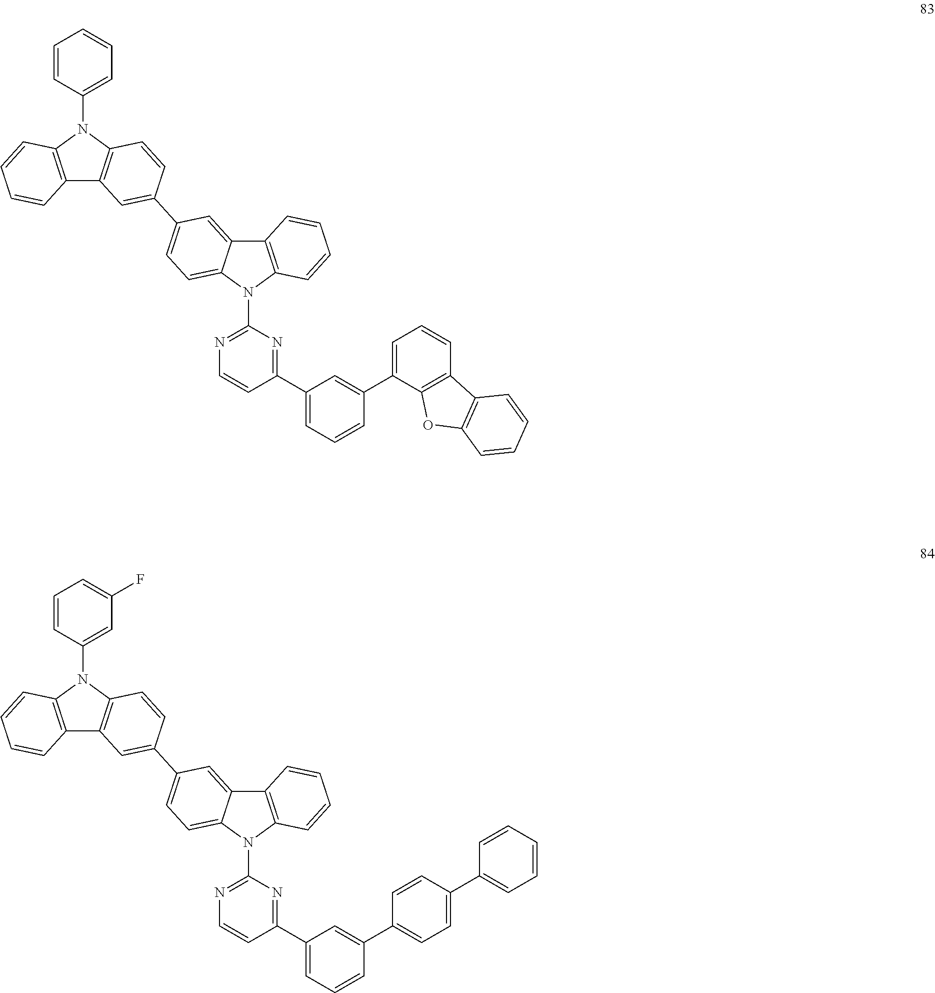 [SMILES: c1ccc(-n2c3ccccc3c3cc(-c4ccc5c(c4)c4ccccc4n5-c4nccc(-c5cccc(-c6cccc7c6oc6ccccc67)c5)n4)ccc32)cc1 ; Fc1cccc(-n2c3ccccc3c3cc(-c4ccc5c(c4)c4ccccc4n5-c4nccc(-c5cccc(-c6ccc(-c7ccccc7)cc6)c5)n4)ccc32)c1]

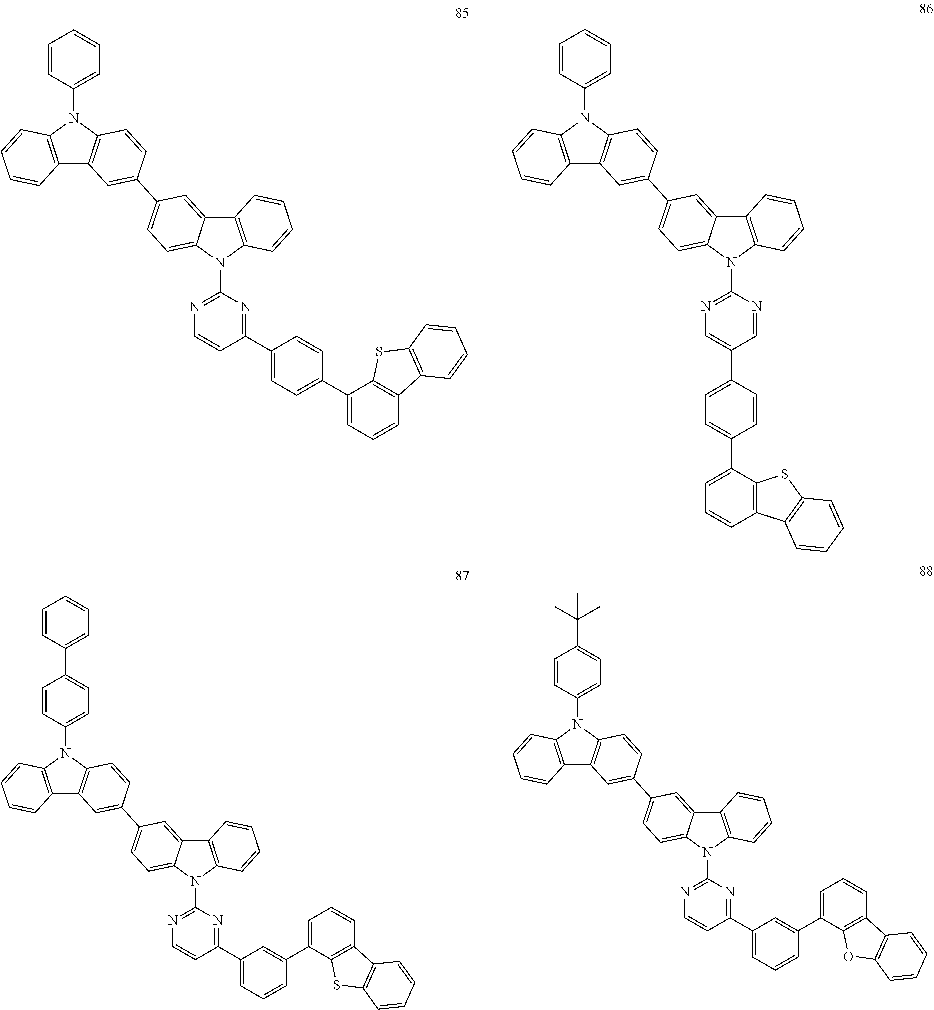 [SMILES: c1ccc(-n2c3ccccc3c3cc(-c4ccc5c(c4)c4ccccc4n5-c4nccc(-c5ccc(-c6cccc7c6sc6ccccc67)cc5)n4)ccc32)cc1 ; c1ccc(-n2c3ccccc3c3cc(-c4ccc5c(c4)c4ccccc4n5-c4ncc(-c5ccc(-c6cccc7c6sc6ccccc67)cc5)cn4)ccc32)cc1 ; c1ccc(-c2ccc(-n3c4ccccc4c4cc(-c5ccc6c(c5)c5ccccc5n6-c5nccc(-c6cccc(-c7cccc8c7sc7ccccc78)c6)n5)ccc43)cc2)cc1 ; CC(C)(C)c1ccc(-n2c3ccccc3c3cc(-c4ccc5c(c4)c4ccccc4n5-c4nccc(-c5cccc(-c6cccc7c6oc6ccccc67)c5)n4)ccc32)cc1]

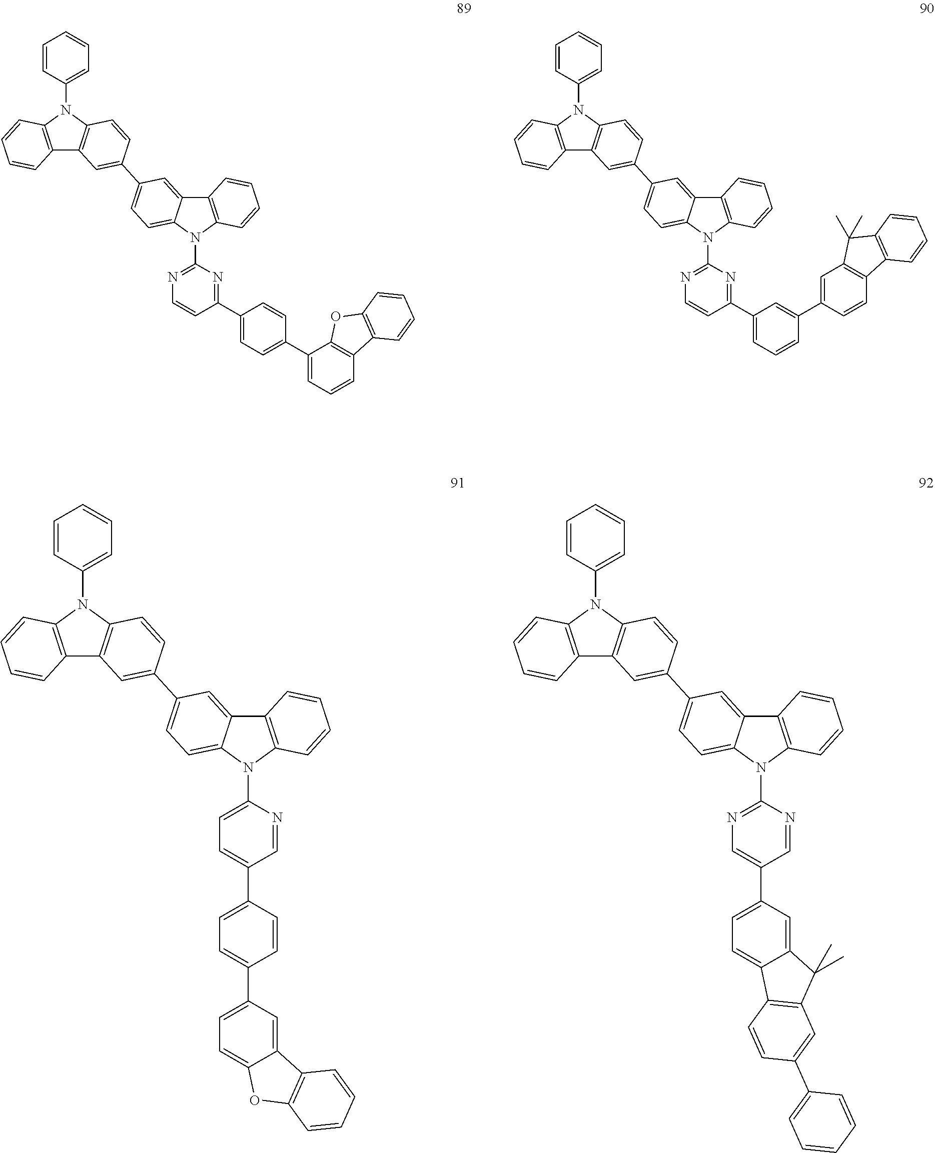 [SMILES: c1ccc(-n2c3ccccc3c3cc(-c4ccc5c(c4)c4ccccc4n5-c4nccc(-c5ccc(-c6cccc7c6oc6ccccc67)cc5)n4)ccc32)cc1 ; CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21 ; c1ccc(-n2c3ccccc3c3cc(-c4ccc5c(c4)c4ccccc4n5-c4ccc(-c5ccc(-c6ccc7oc8ccccc8c7c6)cc5)cn4)ccc32)cc1 ; CC1(C)c2cc(-c3ccccc3)ccc2-c2ccc(-c3cnc(-n4c5ccccc5c5cc(-c6ccc7c(c6)c6ccccc6n7-c6ccccc6)ccc54)nc3)cc21]

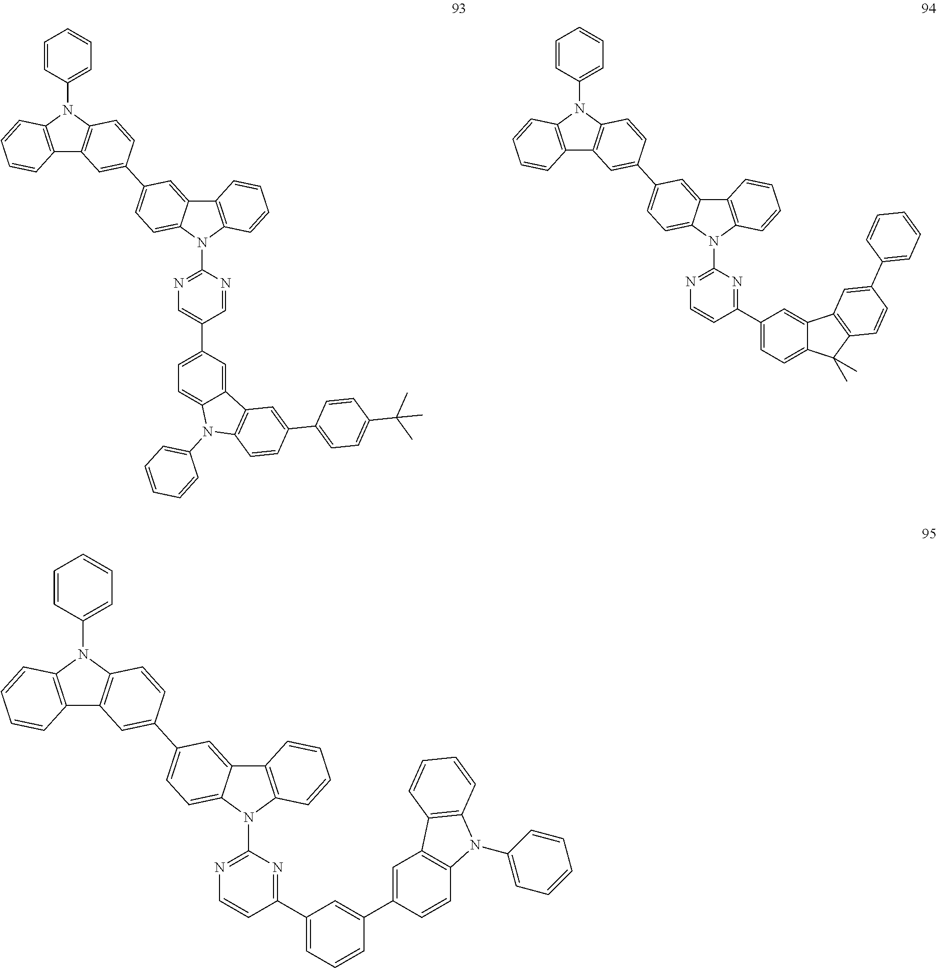 [SMILES: CC(C)(C)c1ccc(-c2ccc3c(c2)c2cc(-c4cnc(-n5c6ccccc6c6cc(-c7ccc8c(c7)c7ccccc7n8-c7ccccc7)ccc65)nc4)ccc2n3-c2ccccc2)cc1 ; CC1(C)c2ccc(-c3ccccc3)cc2-c2cc(-c3ccnc(-n4c5ccccc5c5cc(-c6ccc7c(c6)c6ccccc6n7-c6ccccc6)ccc54)n3)ccc21 ; c1ccc(-n2c3ccccc3c3cc(-c4cccc(-c5ccnc(-n6c7ccccc7c7cc(-c8ccc9c(c8)c8ccccc8n9-c8ccccc8)ccc76)n5)c4)ccc32)cc1]

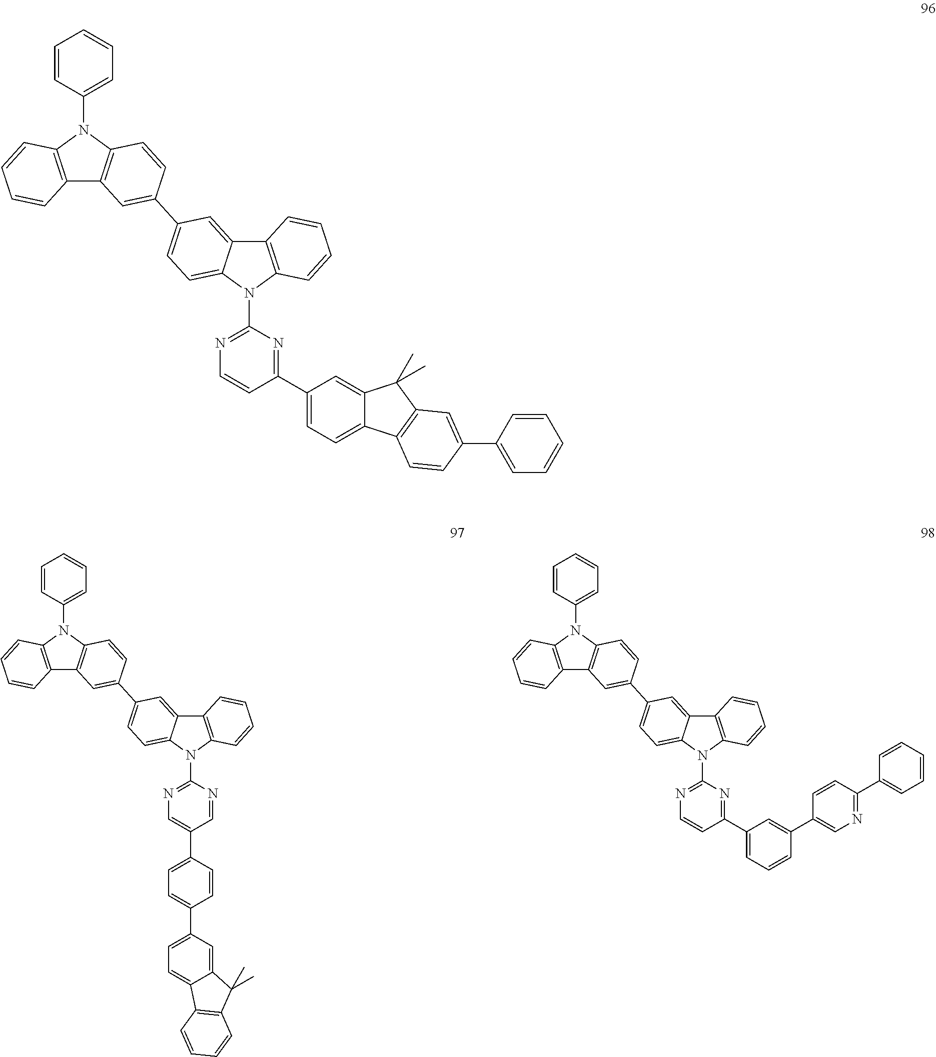 [SMILES: CC1(C)c2cc(-c3ccccc3)ccc2-c2ccc(-c3ccnc(-n4c5ccccc5c5cc(-c6ccc7c(c6)c6ccccc6n7-c6ccccc6)ccc54)n3)cc21 ; CC1(C)c2ccccc2-c2ccc(-c3ccc(-c4cnc(-n5c6ccccc6c6cc(-c7ccc8c(c7)c7ccccc7n8-c7ccccc7)ccc65)nc4)cc3)cc21 ; c1ccc(-c2ccc(-c3cccc(-c4ccnc(-n5c6ccccc6c6cc(-c7ccc8c(c7)c7ccccc7n8-c7ccccc7)ccc65)n4)c3)cn2)cc1]

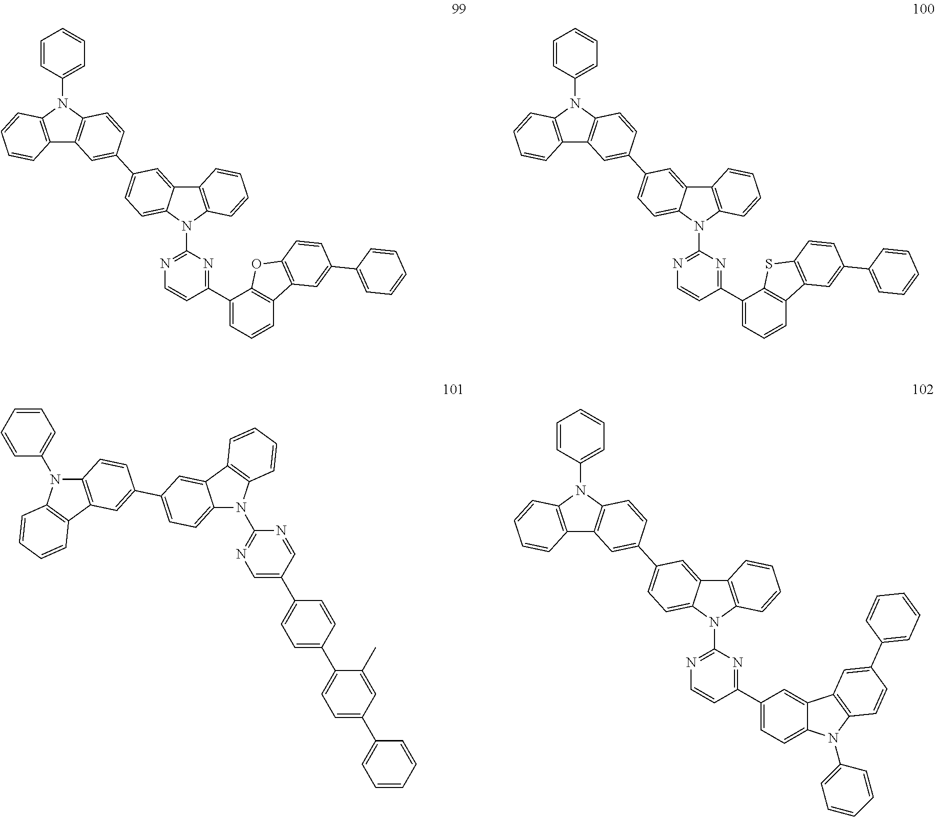 [SMILES: c1ccc(-c2ccc3oc4c(-c5ccnc(-n6c7ccccc7c7cc(-c8ccc9c(c8)c8ccccc8n9-c8ccccc8)ccc76)n5)cccc4c3c2)cc1 ; c1ccc(-c2ccc3sc4c(-c5ccnc(-n6c7ccccc7c7cc(-c8ccc9c(c8)c8ccccc8n9-c8ccccc8)ccc76)n5)cccc4c3c2)cc1 ; Cc1cc(-c2ccccc2)ccc1-c1ccc(-c2cnc(-n3c4ccccc4c4cc(-c5ccc6c(c5)c5ccccc5n6-c5ccccc5)ccc43)nc2)cc1 ; c1ccc(-c2ccc3c(c2)c2cc(-c4ccnc(-n5c6ccccc6c6cc(-c7ccc8c(c7)c7ccccc7n8-c7ccccc7)ccc65)n4)ccc2n3-c2ccccc2)cc1]

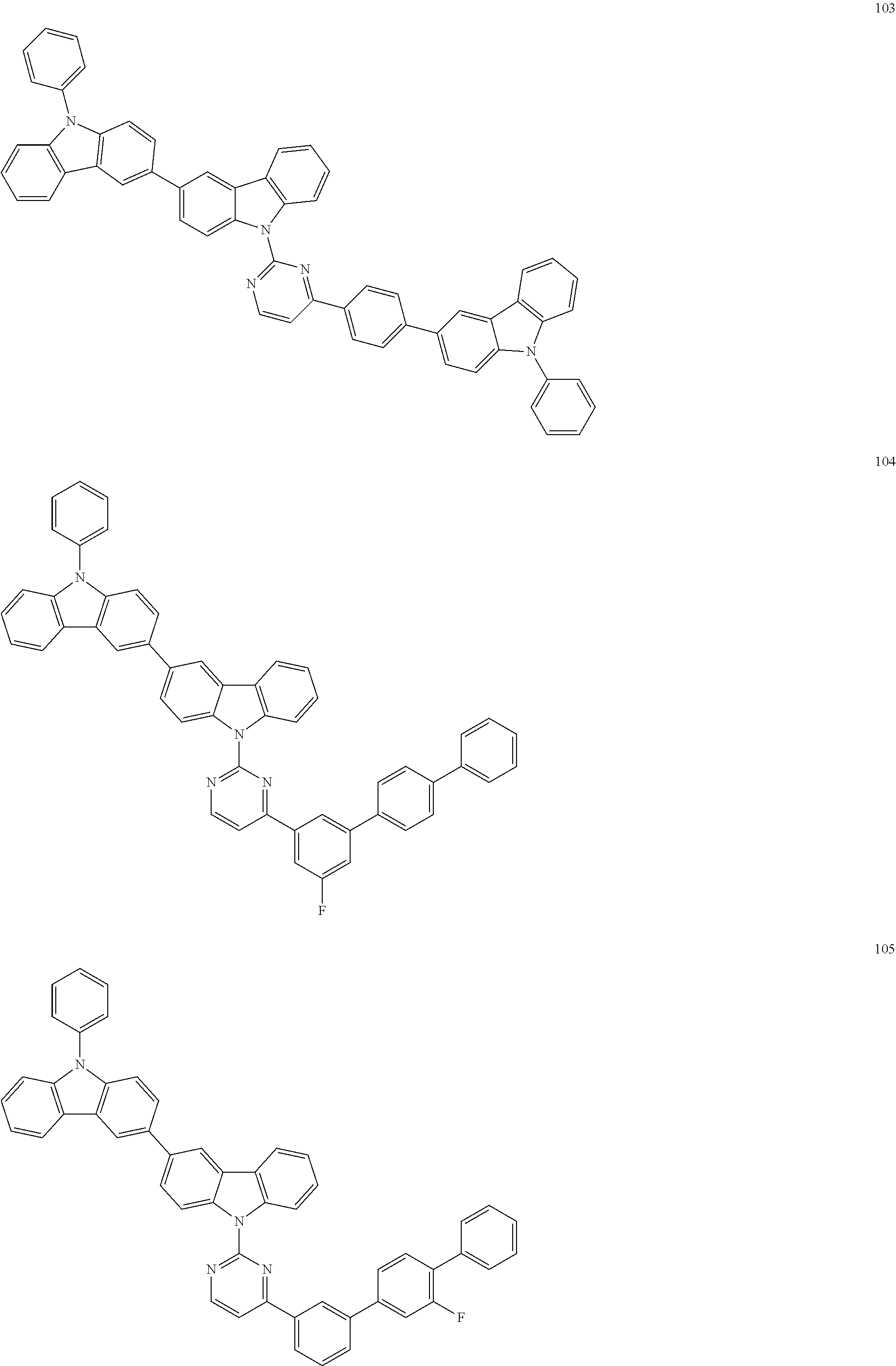 [SMILES: c1ccc(-n2c3ccccc3c3cc(-c4ccc(-c5ccnc(-n6c7ccccc7c7cc(-c8ccc9c(c8)c8ccccc8n9-c8ccccc8)ccc76)n5)cc4)ccc32)cc1 ; Fc1cc(-c2ccc(-c3ccccc3)cc2)cc(-c2ccnc(-n3c4ccccc4c4cc(-c5ccc6c(c5)c5ccccc5n6-c5ccccc5)ccc43)n2)c1 ; Fc1cc(-c2cccc(-c3ccnc(-n4c5ccccc5c5cc(-c6ccc7c(c6)c6ccccc6n7-c6ccccc6)ccc54)n3)c2)ccc1-c1ccccc1]

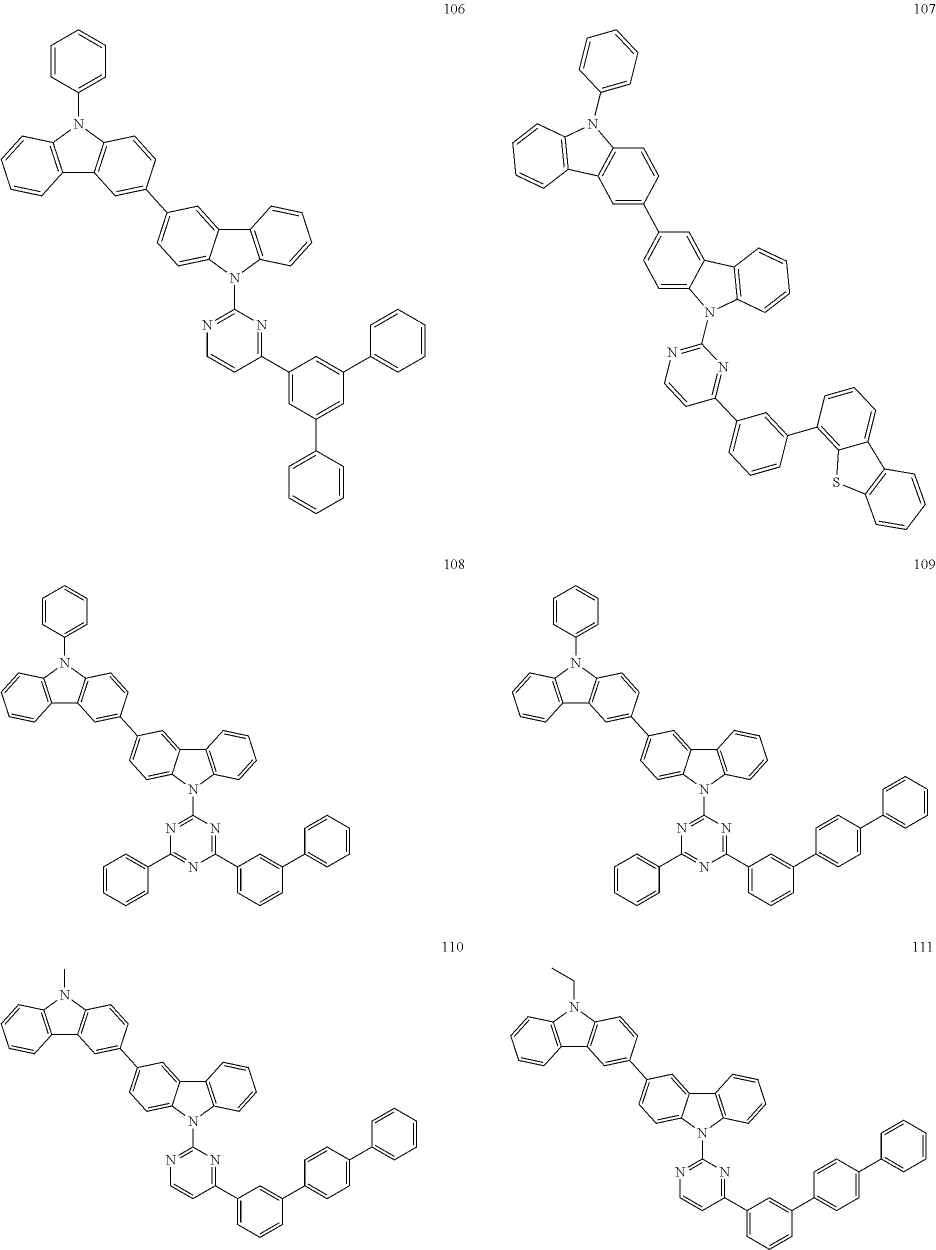

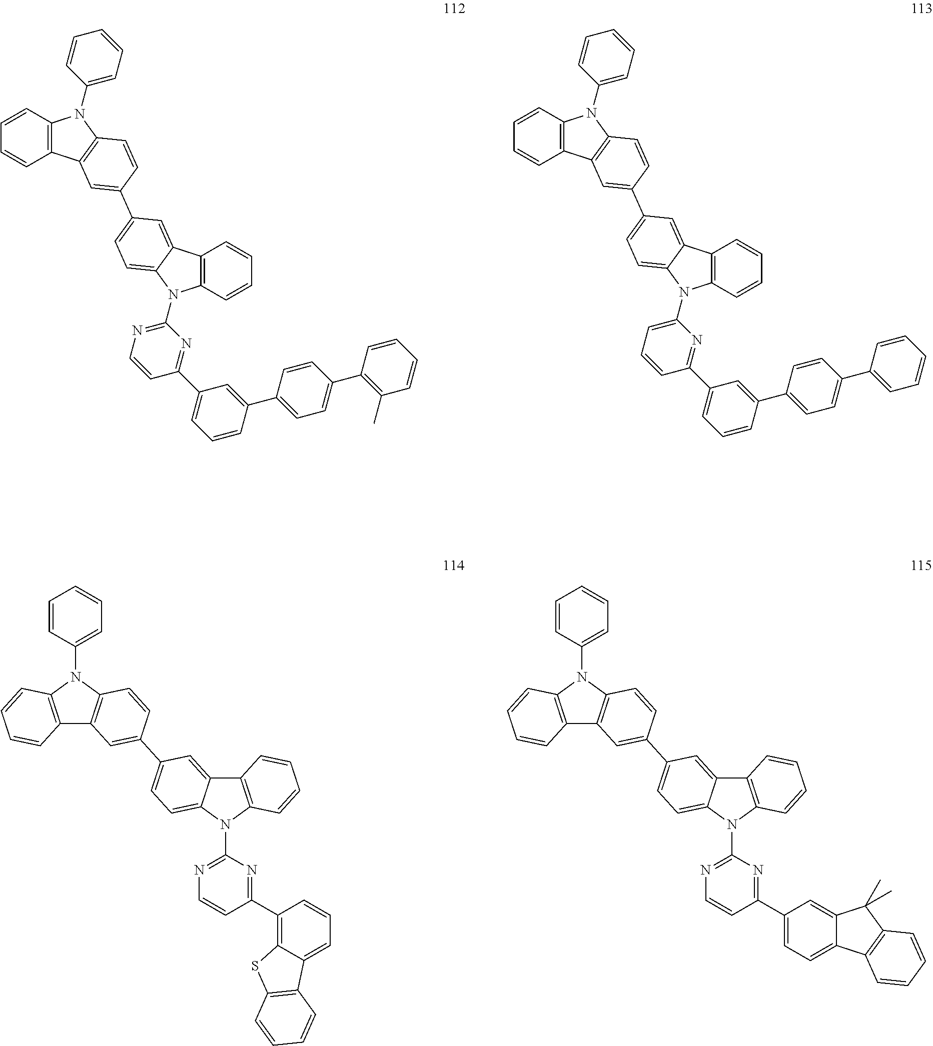 [SMILES: Cc1ccccc1-c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4cccc(-n5c6ccccc6c6cc(-c7ccc8c(c7)c7ccccc7n8-c7ccccc7)ccc65)n4)c3)cc2)cc1 ; c1ccc(-n2c3ccccc3c3cc(-c4ccc5c(c4)c4ccccc4n5-c4nccc(-c5cccc6c5sc5ccccc56)n4)ccc32)cc1 ; CC1(C)c2ccccc2-c2ccc(-c3ccnc(-n4c5ccccc5c5cc(-c6ccc7c(c6)c6ccccc6n7-c6ccccc6)ccc54)n3)cc21]

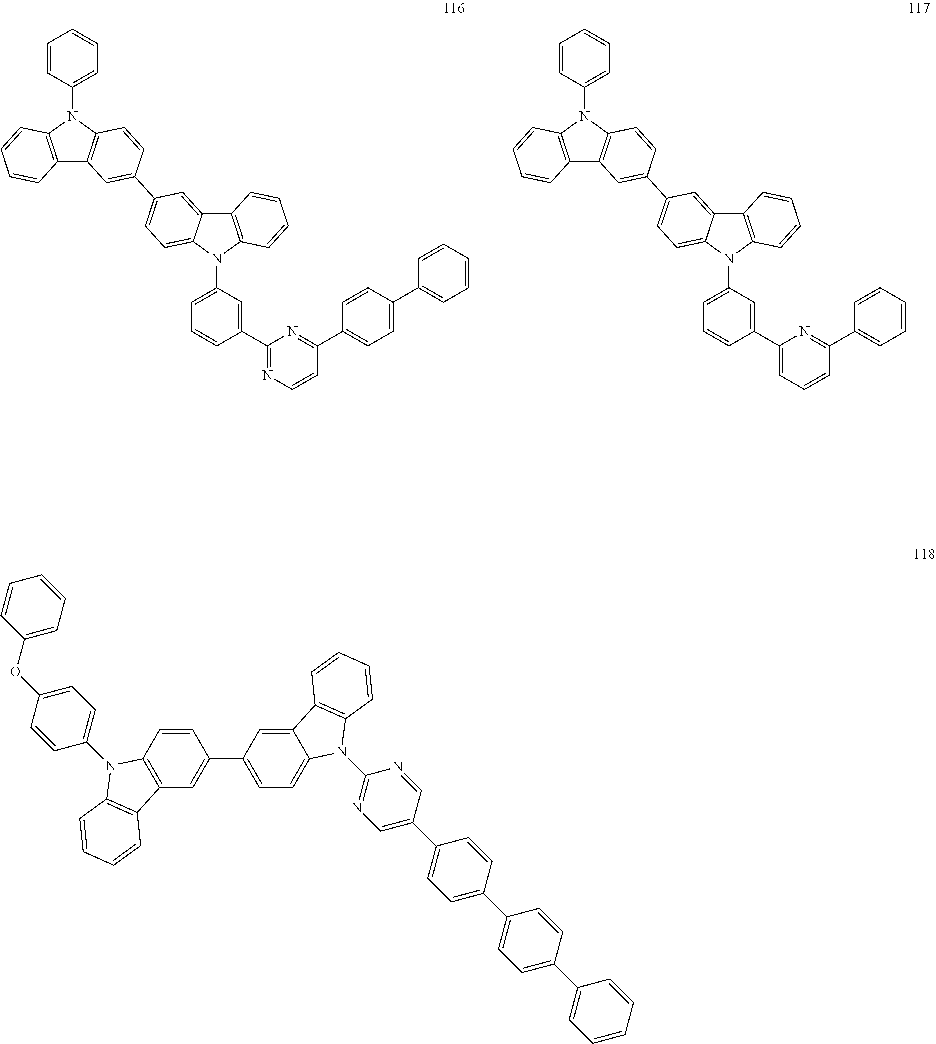 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2cccc(-c3cccc(-n4c5ccccc5c5cc(-c6ccc7c(c6)c6ccccc6n7-c6ccccc6)ccc54)c3)n2)cc1 ; c1ccc(Oc2ccc(-n3c4ccccc4c4cc(-c5ccc6c(c5)c5ccccc5n6-c5ncc(-c6ccc(-c7ccc(-c8ccccc8)cc7)cc6)cn5)ccc43)cc2)cc1]

The general scheme of the organic electroluminescent compound according to the present invention is shown below and the organic electroluminescent compound may be prepared through an organic reaction, which is similar to the scheme or well known already.

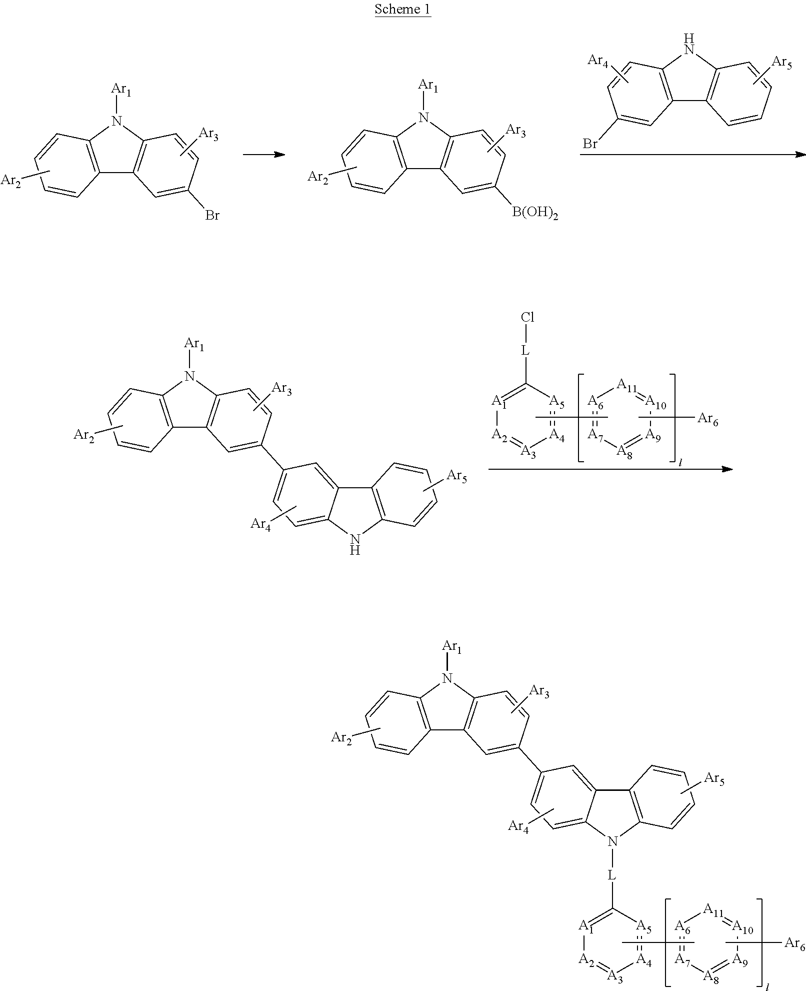

Provided is an organic electroluminescent device, which comprises a first electrode; a second electrode; and one or more organic layer(s) interposed between the first electrode and the second electrode, wherein the organic layer comprises one or more organic electroluminescent compound(s) represented by Chemical Formula 1. The organic layer comprises an electroluminescent layer, in which the organic electroluminescent compounds of Chemical Formula 1 are used as a host material.

When the organic electroluminescent compounds of Chemical Formula 1 are used as a host in the electroluminescent layer, one or more phosphorant dopant(s) are included. The phosphorant dopant applied to the organic electroluminescent device according to the present invention is not specifically limited but may be selected from Ir, Pt and Cu as a metal included in the phosphorant dopant.

To be specific, the compounds having following structures may be used as the phosphorantdopant compound.

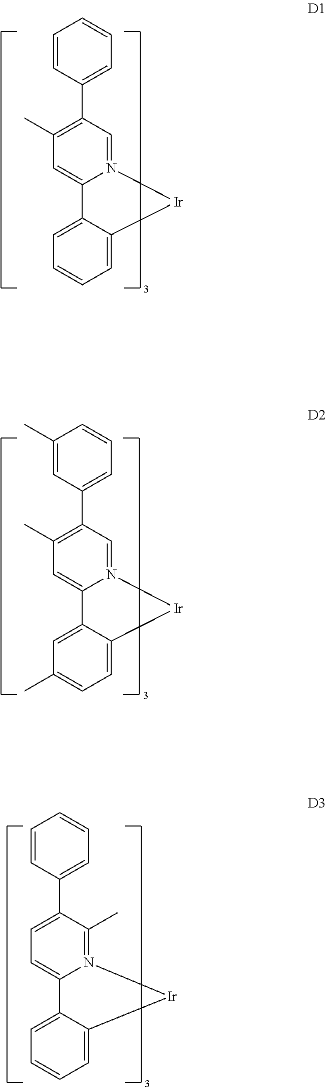

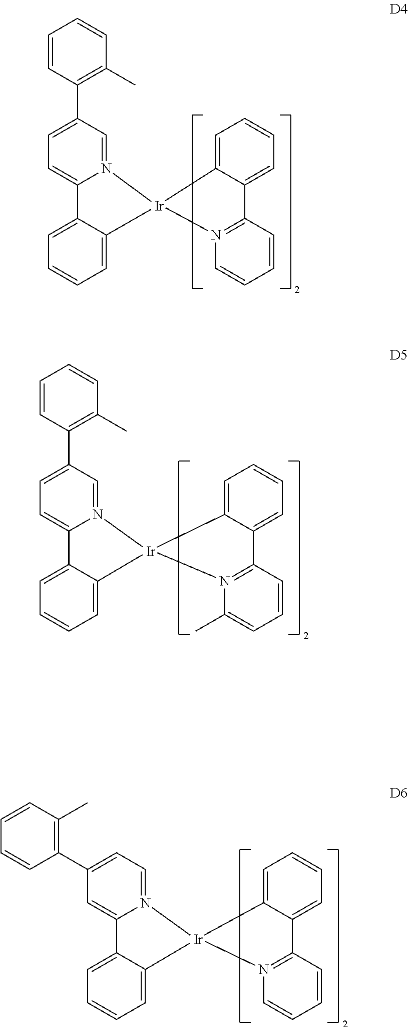

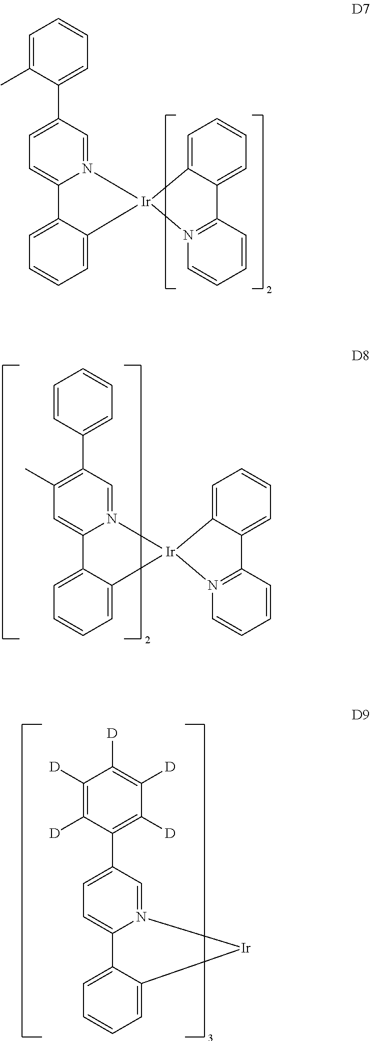

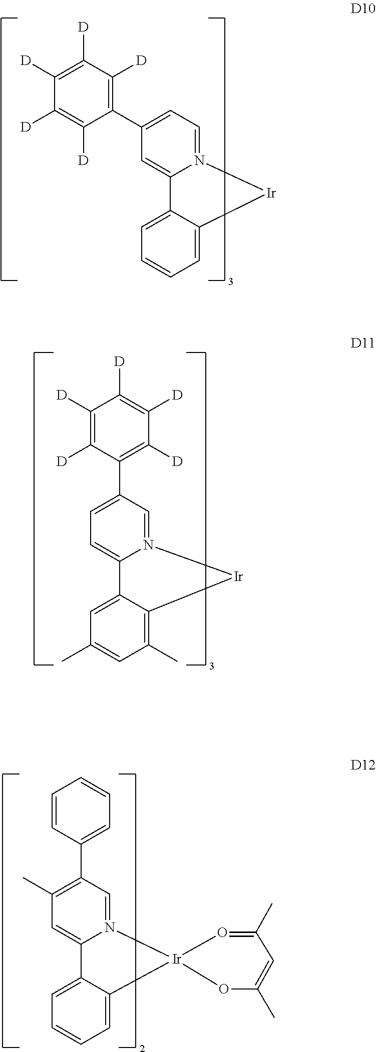

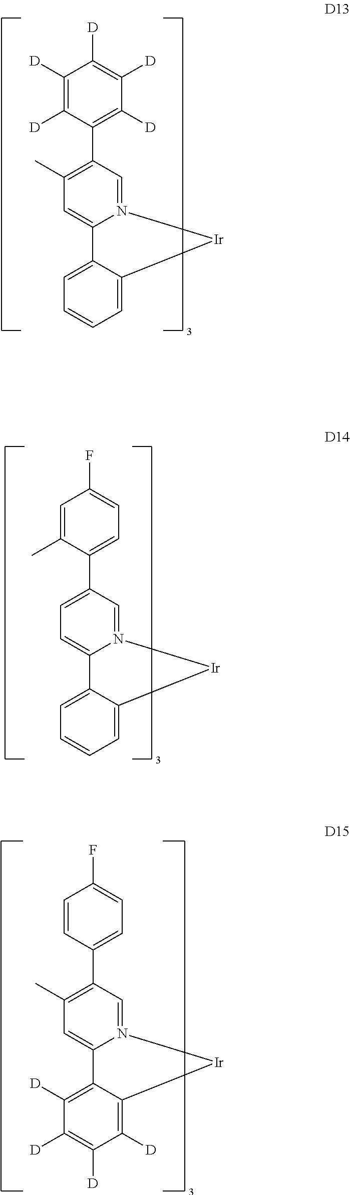

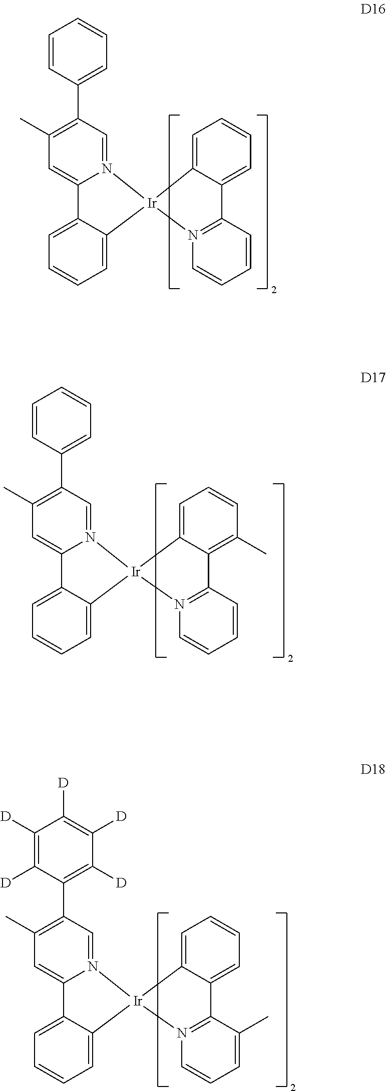

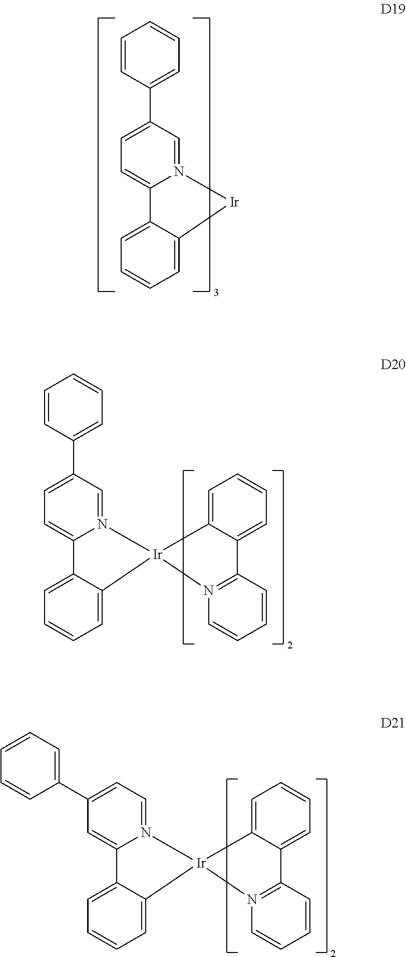

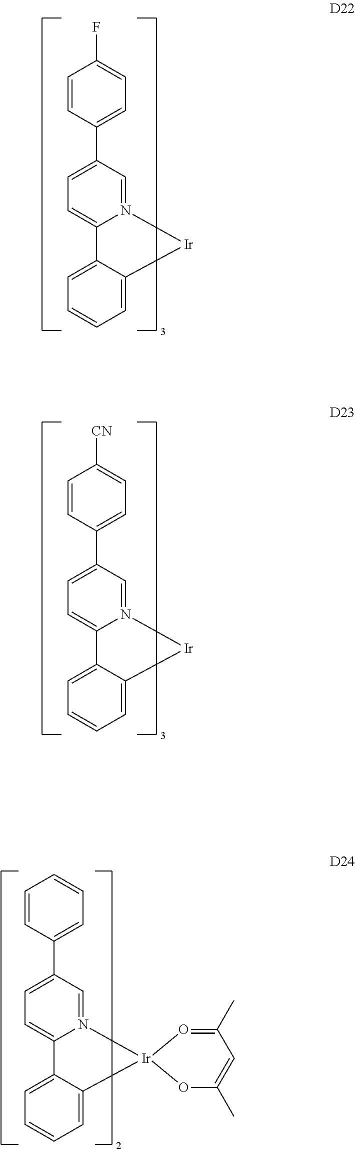

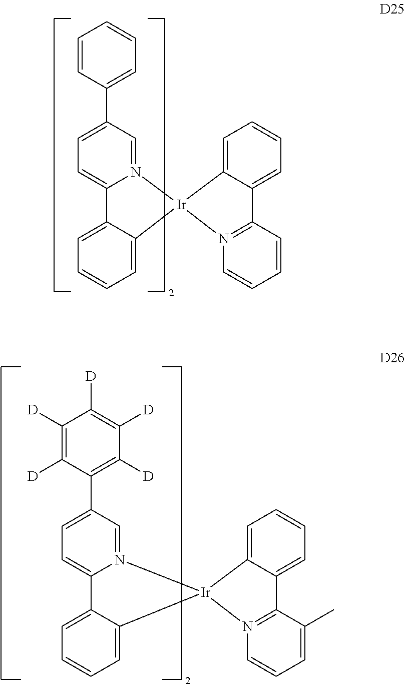

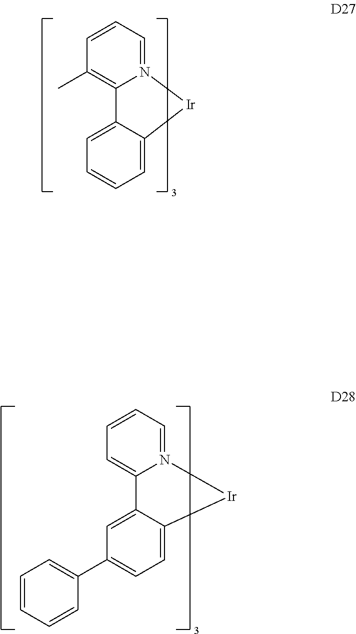

The organic electroluminescent device according to the present invention includes the organic electroluminescent compound of Chemical Formula 1 and includes one or more compound(s) selected from the group consisting of arylamine compound or styrylarylamine compound at the same time. The arylamine compounds or styrylarylamine compounds are exemplified in Korean Patent Application No. 10-2008-0123276, 10-2008-0107606 or 10-2008-0118428, but are not limited thereto.

Further, in the organic electroluminescent device of the present invention, the organic layer may further include, in addition to the organic electroluminescent compound represented by Chemical Formula 1, one or more metal(s) selected from the group consisting of organic metals of Group 1, Group 2, 4th period and 5th period transition metals, lanthanide metals and d-transition elements or complex compound(s). The organic layer may include an electroluminescent layer and a charge generating layer.

Further, the organic layer may include, in addition to the organic electroluminescent compound of Chemical Formula 1, one or more organic electroluminescent layer(s) emitting blue, red or green light at the same time in order to embody a white-emitting organic electroluminescent device. The compounds emitting blue, green or red light may be exemplified by the compounds described in Korean Patent Application No. 10-2008-0123276, 10-2008-0107606 or 10-2008-0118428, but are not limited thereto.

In the organic electroluminescent device of the present invention, a layer (hereinafter referred to as surface layer) selected from a chalcogenide layer, a metal halide layer and a metal oxide layer may be placed on the inner surface of one or both electrode(s) among the pair of electrodes. More specifically, a metal chalcogenide (including oxide) layer of silicon or aluminum may be placed on the anode surface of the electroluminescent medium layer, and a metal halide layer or metal oxide layer may be placed on the cathode surface of the electroluminescent medium layer. Operation stability may be attained therefrom. The chalcogenide may be, for example, SiOₓ (1≦x≦2), AlOₓ (1≦x≦1.5), SiON, SiAlON, etc. The metal halide may be, for example, LiF, MgF₂, CaF₂, a rare earth metal fluoride, etc. The metal oxide may be, for example, Cs₂O, Li₂O, MgO, SrO, BaO, CaO, etc.

In the organic electroluminescent device according to the present invention, it is also preferable to arrange on at least one surface of the pair of electrodes thus manufactured a mixed region of an electron transport compound and a reductive dopant, or a mixed region of a hole transport compound and an oxidative dopant. In that case, since the electron transport compound is reduced to an anion, injection and transport of electrons from the mixed region to an electroluminescent medium are facilitated. In addition, since the hole transport compound is oxidized to a cation, injection and transport of holes from the mixed region to an electroluminescent medium are facilitated. Preferable oxidative dopants include various Lewis acids and acceptor compounds. Preferable reductive dopants include alkali metals, alkali metal compounds, alkaline earth metals, rare-earth metals, and mixtures thereof. Further, a white-emitting electroluminescent device having two or more electroluminescent layers may be manufactured by employing a reductive dopant layer as a charge generating layer.

### ADVANTAGEOUS EFFECTS

Since the organic electroluminescent compound according to the present invention exhibits good luminous efficiency and excellent life property, it may be used to manufacture OLED devices having very superior operation life.

### MODE OF THE INVENTION

The present invention is further described with respect to organic electroluminescent compounds according to the present invention, processes for preparing the same, and luminescence properties of devices employing the same. However, the following examples are provided for illustrative purposes only and they are not intended to limit the scope of the present invention.

### Preparation Example 1

### Preparation of Compound 6

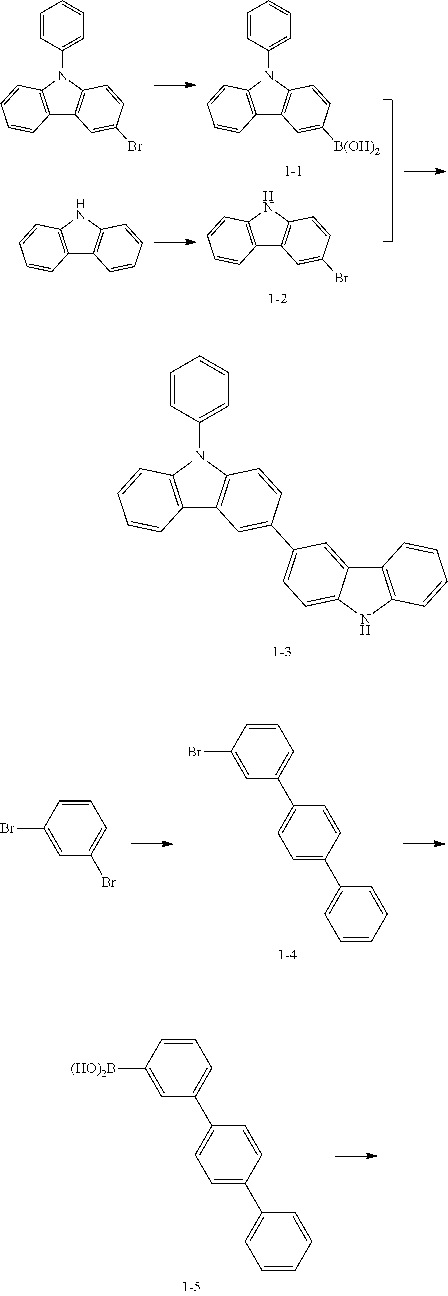

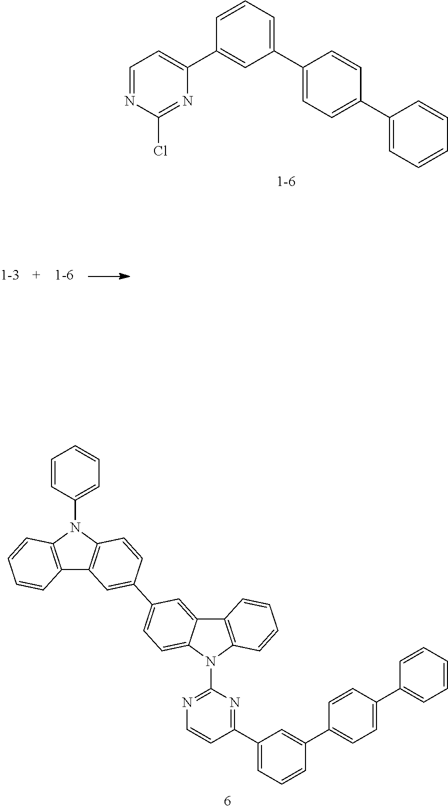 [SMILES: Clc1nccc(-c2cccc(-c3ccc(-c4ccccc4)cc3)c2)n1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

3-Bromo-N-phenylcarbazole 20 g (62.07 mmol) was dissolved in THF 200 ml and n-buLi 29 ml (74.48 mmol, 2.5M in Hexane) was slowly added thereto at −78° C. One hour later, triisopropylborate 19.9 ml (86.90 mmol) was added to the mixture. The mixture was stirred at room temperature for 12 hours and distilled water was added thereto. After extracting with EA, drying with magnesium sulfate, and distilling under reduced pressure, Compound 1-1 12 g (41.79 mmol, 67.33%) was obtained through recystallization with EA and Hexane.

Carbazole 20 g (119.6 mmol) was dissolved in DMF 200 ml and NBS 21.2 g (119.6 mmol) was added there to at 0° C. After stirring for 12 hours, distilled water was added and a produced solid was filtered under reduced pressure. The obtained solid was added to methanol, and the mixture was stirred and filtered under reduced pressure. The obtained solid was added to EA and methanol, stirred and filtered under reduced pressure to obtain Compound 1-2 17 g (69.07 mmol, 58.04%).

Compound 1-1 12 g (41.79 mmol), Compound 1-2 11.3 g (45.97 mmol), Pd(PPh₃)₄ 1.4 g (1.25 mmol), 2M K₂CO₃ 52 ml, toluene 150 ml, and ethanol 30 ml were stirred under reflux. 5 hours later, the mixture was cooled to room temperature and distilled water was added thereto. After extracting with EA, drying with magnesium sulfate, and distilling under reduced pressure, Compound 1-3 10 g (24.48 mmol, 58.57%) was obtained through recystallization with EA and Hexane.

1,3-dibromobenzene 36.5 ml (302.98 mmol), 4-biphenylboronic acid 40 g (201.98 mmol), Pd(PPh₃)₄ 4.25 g (6.05 mmol), 2M Na₂CO₃ 250 ml, toluene 400 ml, and ethanol 100 ml were added and stirred under reflux. 12 hours later, the mixture was cooled to room temperature and distilled water was added thereto. After extracting with EA, drying with magnesium sulfate, and distilling under reduced pressure, Compound 1-4 25 g (80.85 mmol, 40.12%) was obtained via column separation.

Compound 1-4 25 g (80.85 mmol) was dissolved in THF and n-buLi 42 ml (105.10 mmol, 2.5M in Hexane) was slowly added thereto at −78° C. one hour later, trimethylborate 14.42 ml (129.3 mmol) was added to the mixture. The mixture was stirred for 12 hours at room temperature and distilled water was added thereto. After extracting with EA, drying with magnesium sulfate, and distilling under reduced pressure, Compound 1-5 20 g (72.96 mmol, 90.24%) was obtained through recystallization with MC and Hexane.

Compound 1-5 20 g (72.96 mmol), 2,4-dichloropyrimidine 9.8 g (80.25 mmol), Pd(PPh₃)₄ 2.28 g (2.18 mmol), 2M Na₂CO₃ 80 ml, toluene 150 ml, and ethanol 50 ml were added and stirred under reflux for 5 hours. The mixture was cooled to room temperature and distilled water was added thereto. After extracting with EA, drying with magnesium sulfate, and distilling under reduced pressure, Compound 1-6 11 g (32.08 mmol, 43.97%) was obtained through recystallization with EA and Methanol.

Compound 1-3 5.2 g (12.83 mmol), and Compound 1-6 4 g (11.66 mmol) were dissolved in DMF 150 ml and NaH 0.7 g (17.50 mmol, 60% in mineral oil) was added thereto. The mixture was stirred for 12 hours at room temperature and methanol and distilled water were added thereto. A produced solid was filtered under reduced pressure to obtain Compound 6 5 g (6.99 mmol, 59.98%) via column separation.

### Preparation Example 2

### Preparation of Compound 90

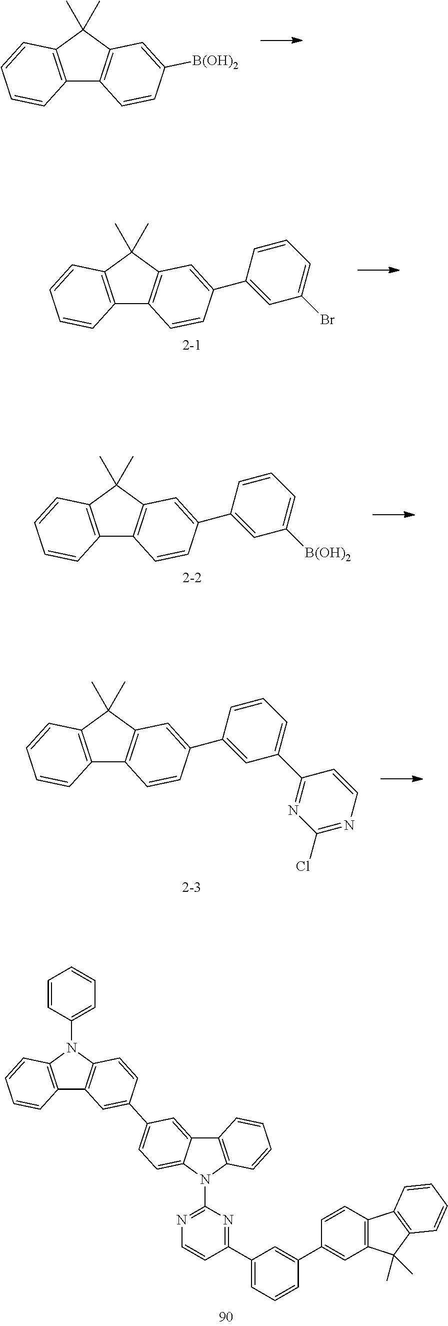 [SMILES: CC1(C)c2ccccc2-c2ccc(B(O)O)cc21 ; CC1(C)c2ccccc2-c2ccc(-c3cccc(Br)c3)cc21 ; CC1(C)c2ccccc2-c2ccc(-c3cccc(B(O)O)c3)cc21 ; CC1(C)c2ccccc2-c2ccc(-c3cccc(-c4ccnc(Cl)n4)c3)cc21 ; CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21]

9,9-dimethyl-2-fluoreneboronic acid 30 g (126 mmol), 1,3-dibromobenzene 30.45 mmol (252 mmol), PdCl₂(PPh₃)₂ 2.6 g (3.78 mmol), 2M Na₂CO₃ 160 ml, and toluene 800 m were added and stirred at 100° C. for 5 hours. The mixture was cooled to room temperature, extracted with EA and washed with distilled water. After drying with magnesium sulfate and distilling under reduced pressure, Compound 2-1 30 g (85.89 mmol, 67.46%) was obtained via column separation.

Compound 2-2, Compound 2-3 and Compound 90 were respectivelyreacted by using Compound 2-1 in the same manner as Compound 1-5, Compound 1-6, and Compound 6.

### Preparation Example 3

### Preparation of Compound 44

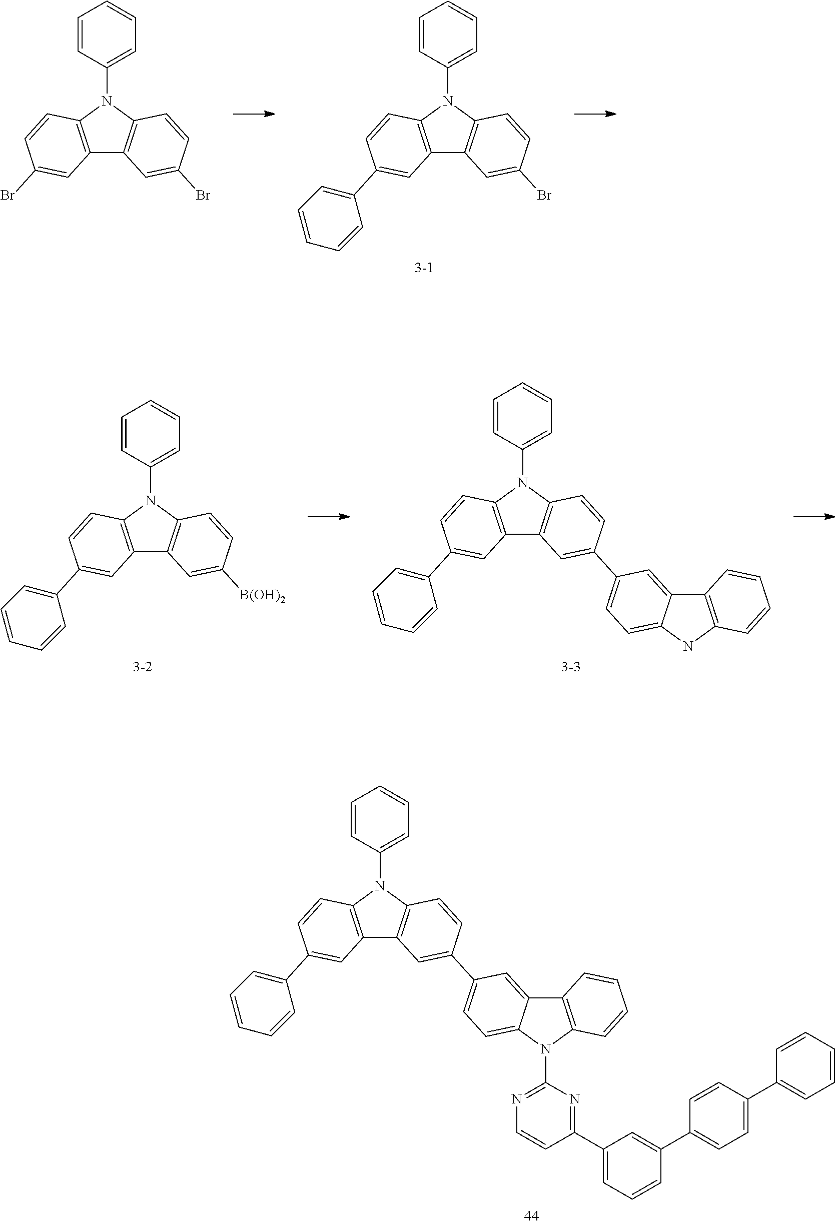 [SMILES: Brc1ccc2c(c1)c1cc(Br)ccc1n2-c1ccccc1 ; Brc1ccc2c(c1)c1cc(-c3ccccc3)ccc1n2-c1ccccc1 ; OB(O)c1ccc2c(c1)c1cc(-c3ccccc3)ccc1n2-c1ccccc1 ; c1ccc(-c2ccc3c(c2)c2cc(-c4ccc5[nH]c6ccccc6c5c4)ccc2n3-c2ccccc2)cc1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

Compound 3-1 was reacted in the same manner as Compound 2-1 by using 3,6-dibromo-9-phenyl-9H-carbazole and phenyl boronic acid as a starting material.

Compound 3-2, Compound 3-3, and Compound 44 were respectively reacted by using Compound 3-1 in the same manner as Compound 1-1, Compound 1-3, and Compound 6.

### Preparation Example 4

### Preparation of Compound 74

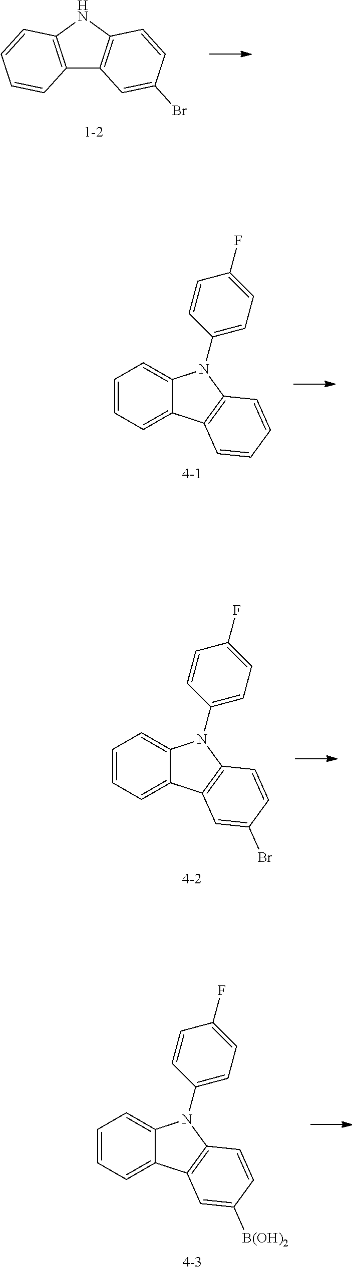 [SMILES: Brc1ccc2[nH]c3ccccc3c2c1 ; Fc1ccc(-n2c3ccccc3c3ccccc32)cc1 ; Fc1ccc(-n2c3ccccc3c3cc(Br)ccc32)cc1 ; OB(O)c1ccc2c(c1)c1ccccc1n2-c1ccc(F)cc1]

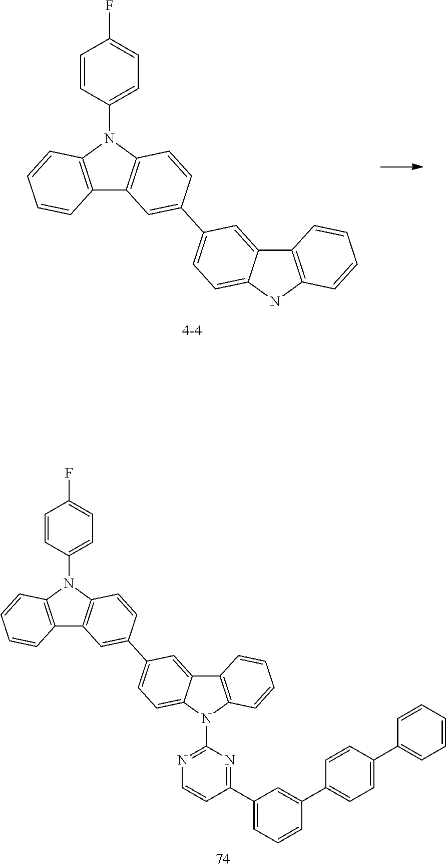 [SMILES: Fc1ccc(-n2c3ccccc3c3cc(-c4ccc5[nH]c6ccccc6c5c4)ccc32)cc1 ; Fc1ccc(-n2c3ccccc3c3cc(-c4ccc5c(c4)c4ccccc4n5-c4nccc(-c5cccc(-c6ccc(-c7ccccc7)cc6)c5)n4)ccc32)cc1]

Compound 1-2 25 g (149 mmol), 1-bromo-4-fluorobenzene 49 ml (448 mmol), CuI 23 g (120 mmol), Cs₂CO₃ 146 g (449 mmol), and EDA 12 ml (179 mmol) were added to F 750 ml, and stirred at 120° C. for 12 hours. After the reaction mixture was cooled to room temperature, and extracted with ethyl acetate 500 ml, an obtained organic layer was washed with distilled water 100 ml twice. The organic layer was drid with anhydrous magnesium sulfate and an organic solvent was removed under reduced pressure. 4-1 Compound 36 g (77%) was obtained by separation through column chromatograph using silica gel and recystallization.

After dissolving Compound 4-1 20 g (77 mmol) in DMF 200 mL, NBS 14 g (77 mmol) was added to DMF100 mL at 0° C. The mixture was stirred at room temperature for 2 hours. Upon completion of the reaction, the reaction mixture was extracted with ethyl acetate 400 mL and an obtained organic layer was washed with distilled water 100 mL several times. The organic layer was dried with anhydrousmagnesium sulfate and an organic solvent was removed under reduced pressure to obtain a solid. The obtained solid was treated by column chromatograph using silica gel and recystallization to obtain Compound 4-2 16 g (62%).

Compound 4-3, Compound 4-4, and Compound 74 were respectively reacted in the same manner as Compound 1-1, Compound 1-3, Compound 6 by using Compound 4-2.

### Preparation Example 5

### Preparation of Compound 78

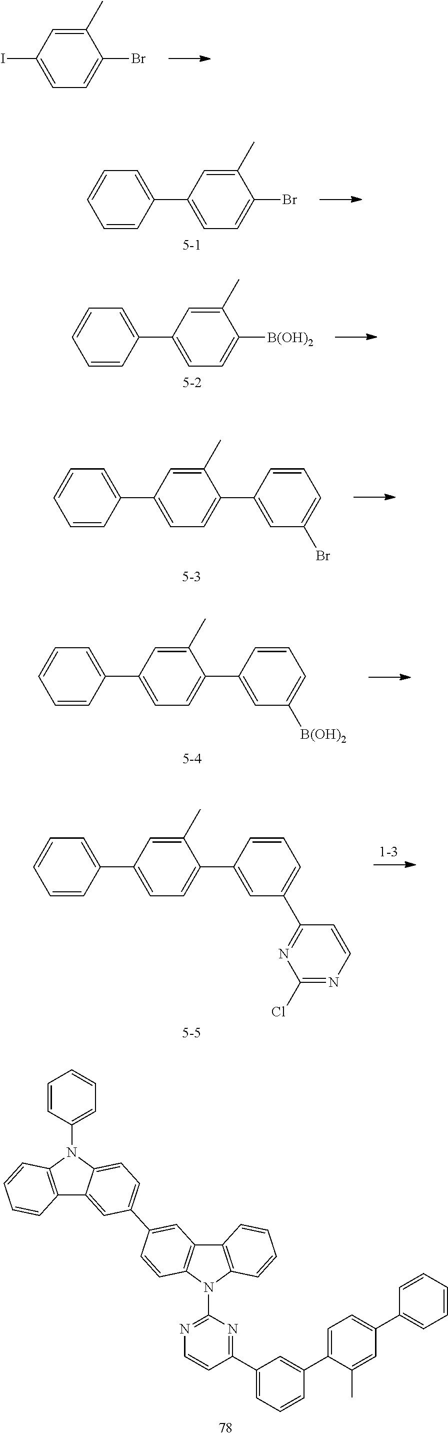

2-Bromo-5-iodotoluene (15.8 g, 53.21 mmol), phenylboronic acid (6.4 g, 53.21 mmol), PdCl(PPh₃)₂ (1.8 g, 2.66 mmol), 2M Na₂CO₃ solution 50 ml, and toluene 150 ml were added and stirred under reflux. 30 minutes later, the mixture was cooled to room temperature and an organic layer was washed with distilled water. After drying with magnesium sulfate and distilling under reduced pressure, Compound 5-1 (12 g, 92%) was obtained via column separation.

Compound 78 was reacted in the same manner as Compound 6 by using Compound 5-1.

### Preparation Example 6

### Preparation of Compound 104

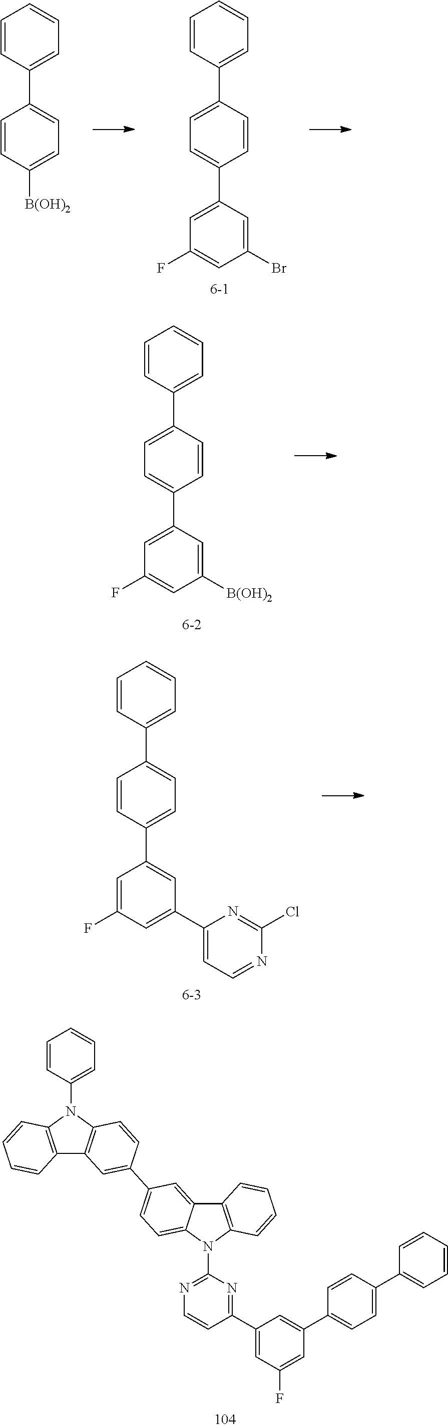 [SMILES: OB(O)c1ccc(-c2ccccc2)cc1 ; Fc1cc(Br)cc(-c2ccc(-c3ccccc3)cc2)c1 ; OB(O)c1cc(F)cc(-c2ccc(-c3ccccc3)cc2)c1 ; Fc1cc(-c2ccc(-c3ccccc3)cc2)cc(-c2ccnc(Cl)n2)c1 ; Fc1cc(-c2ccc(-c3ccccc3)cc2)cc(-c2ccnc(-n3c4ccccc4c4cc(-c5ccc6c(c5)c5ccccc5n6-c5ccccc5)ccc43)n2)c1]

Boronic acid Compound 48 g (0.24 mol), 1,3-dibromo-5-fluorobenzene 90 g (0.35 mol), Na₂CO₃ 64 g (0.6 mol), and PdCl₂(PPh₃)₂ 5 g (0.007 mol) were added to Toluene 600 mL, EtOH 300 mL, and purified water 300 mL. The mixture was stirred under reflux for one day and extracted with ethyl acetate 600 mL to obtain an organic layer. The organic layer was washed with distilled water 100 mL. The organic layer was dried with anhydrousmagnesium sulfate, and an organic solvent was removed under reduced pressure. The obtained solid was separated via column chromatograph using silica gel and recystallization to obtain Compound 6-1 16 g (20%).

Compound 104 was reacted by using Compound 6-1 in the same manner as Compound 6.

### Preparation Example 7

### Preparation of Compound 106

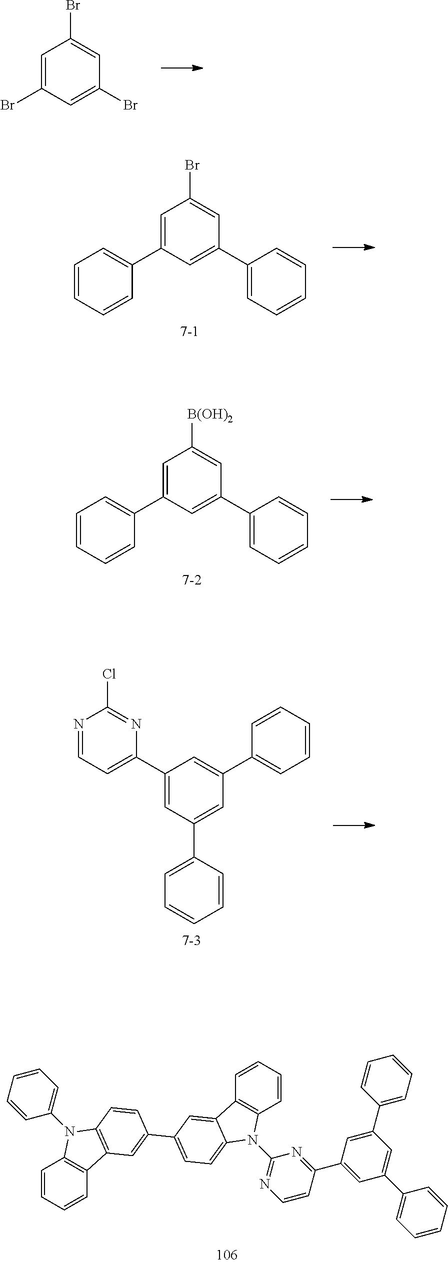 [SMILES: Brc1cc(Br)cc(Br)c1 ; Brc1cc(-c2ccccc2)cc(-c2ccccc2)c1 ; OB(O)c1cc(-c2ccccc2)cc(-c2ccccc2)c1 ; Clc1nccc(-c2cc(-c3ccccc3)cc(-c3ccccc3)c2)n1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

1,3,5-tribromobenzene 50 g (0159 mmol), Phenylboronic acid 46 g (381 mmol), Na₂CO₃ 16.8 g (1.50 mol), and Pd(PPh₃)₄ 2 g (0.01 mol) were added to Toluene 480 mL and purified water 159 mL. The mixture was stirred under reflux for one day and extracted with ethyl acetate 500 mL to obtain an organic layer. The organic layer was washed with distilled water 100 mL and dried with anhydrousmagnesium sulfate. An organic solvent was removed under reduced pressure. An obtained solid was separated via column chromatograph using silica gel and recystallization to obtain Compound 7-1 23 g (47%).

Compound 106 was reacted by using Compound 7-1 in the same manner as Compound 6.

### Preparation Example 8

### Preparation of Compound 107

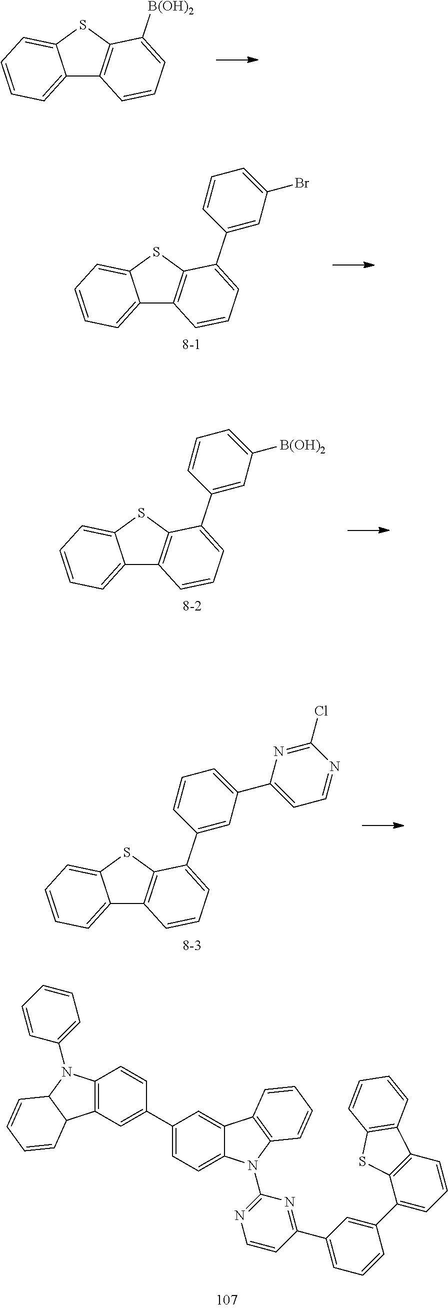 [SMILES: OB(O)c1cccc2c1sc1ccccc12 ; Brc1cccc(-c2cccc3c2sc2ccccc23)c1 ; OB(O)c1cccc(-c2cccc3c2sc2ccccc23)c1 ; Clc1nccc(-c2cccc(-c3cccc4c3sc3ccccc34)c2)n1 ; C1=CC2c3cc(-c4ccc5c(c4)c4ccccc4n5-c4nccc(-c5cccc(-c6cccc7c6sc6ccccc67)c5)n4)ccc3N(c3ccccc3)C2C=C1]

1,3-dibromobenzene (16.5 g, 0.2 mol), dibenzo[b,d]thiophen-4-ylboronic acid (15 g, 0.06 mol), Pd(PPh₃)₄ (3.8 g, 0.003 mol), Na₂CO₃ (14 g, 0.13 mol), Toluene (330 ml), and H₂O (70 ml) were added at 80° C. for 12 hours. Upon completion of the reaction, the mixture was extracted with Ethyl Acetate and an organic layer was dried with MgSO₄, and filtered. A solvent was removed under reduced pressure to obtain Compound 8-1 (8.4 g, 40%) as a white solid, via Column separation. THF (200 ml), and Compound 8-1 (8.4 g, 0.025 mol) were added and mixed under nitrogen atmosphere. n-BuLi (15 ml, 2.25M solution in hexane) was slowly added to the mixture at −78° C. After stirring the mixture at −78° C. for 1 hour, B(O-iPr)₃ (11.4 ml, 0.05 mol) was slowly added to the mixture at −78° C. The mixture was heated to room temperature and reacted for 12 hours. Upon completion of the reaction, the mixture was extracted with Ethyl Acetate and an organic layer was dried with MgSO₄, and filtered. A solvent was removed under reduced pressure to obtain Compound 8-2 (6 g, 80%) as a white solid via Column separation. 2,4-dichloropyrimidine (5.9 g, 0.04 mol), Compound 12-2 (8.3 g, 0.03 mol), Pd(PPh₃)₄ (1.7 g, 0.001 mol), Na₂CO₃ (8.1 g, to 0.07 mol), Toluene (150 ml), EtOH (40 ml), and H₂O (40 ml) were added and stirred at 80° C. for 12 hours. Upon completion of the reaction, the mixture was extracted with Ethyl Acetate and an organic layer was dried with MgSO₄, and filtered. A solvent was removed under reduced pressure to obtain Compound 8-3 (10 g, 98%) via column separation.

Compound 107 was reacted using Compound 8-3 in the same manner as Compound 6.

### Preparation Example 9

### Preparation of Compound 110

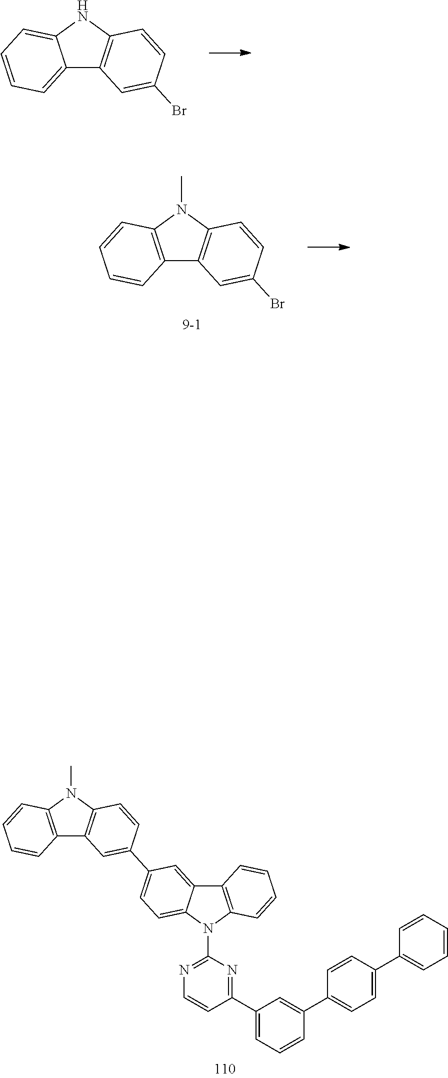 [SMILES: Brc1ccc2[nH]c3ccccc3c2c1 ; Cn1c2ccccc2c2cc(Br)ccc21 ; Cn1c2ccccc2c2cc(-c3ccc4c(c3)c3ccccc3n4-c3nccc(-c4cccc(-c5ccc(-c6ccccc6)cc5)c4)n3)ccc21]

After 3-bromo-9H-carbazole 20 g (81 mmol) was dissolved in DMF 74 mL, NaH 4.3 g (106 mmol) was slowly added thereto. After stirring the mixture for 30 minutes, CH₃Cl Compound 7 ml (114 mmol) was added to the mixture and stirred for 4 hours. The mixture was slowly added to distilled water 200 mL and stirred for 30 minutes to obtain a solid. The obtained solid was separated via column chromatograph using silica gel and recystallization to obtain Compound 9-1 17 g (81%).

Compound 110 was reacted using Compound 9-1 in the same manner as Compound 6.

Table 1 showed the result of the following Compounds reacted based on Preparation Examples 1-9

TABLE 1

| compound | [symbol] | mass | | UV | PL | mp |
|---|---|---|---|---|---|---|
| 1 | 23% | 639.25 | 638.76 | 340 nm | 482 nm | 175° C. |
| 3 | 52% | 639.25 | 638.76 | 358 nm | 482 nm | 206° C. |
| 5 | 31% | 715.28 | 714.85 | 347 nm | 492 nm | 254° C. |
| 6 | 65% | 715.28 | 714.85 | 332 nm | 478 nm | 200° C. |
| 7 | 36% | 715.28 | 714.85 | 472 nm | 308 nm | 243° C. |
| 9 | 22% | 715.28 | 714.85 | 347 nm | 488 nm | 198° C. |
| 10 | 46% | 715.28 | 714.85 | 364 nm | 474 nm | 120° C. |
| 44 | 38% | 791.31 | 790.95 | 480 nm | 308 nm | 219° C. |
| 61 | 17% | 791.31 | 790.95 | 354 nm | 480 nm | 218° C. |
| 67 | 19% | 733.27 | 732.84 | 471 nm | 304 nm | 230° C. |
| 68 | 43% | 791.31 | 790.95 | 338 nm | 485 nm | 195° C. |
| 70 | 13% | 729.3 | 728.88 | 478 nm | 304 nm | 169° C. |
| 74 | 13% | 733.27 | 732.84 | 324 nm | 475 nm | 234° C. |
| 78 | 47% | 729.3 | 728.88 | 356 nm | 494 nm | 138° C. |
| 83 | 48% | 729.26 | 728.84 | 352 nm | 382 nm | 180° C. |
| 84 | 40% | 733.27 | 732.84 | 314 nm | 483 nm | 207° C. |
| 90 | 35% | 755.31 | 754.92 | 310 nm | 481 nm | 215° C. |
| 104 | 62% | 733.27 | 732.84 | 334 nm | 475 nm | 222° C. |
| 105 | 30% | 733.27 | 732.84 | 350 nm | 487 nm | 213° C. |
| 106 | 38% | 715.28 | 714.85 | 342 nm | 479 nm | 214° C. |
| 107 | 42% | 745.24 | 744.9 | 344 nm | 489 nm | 255° C. |
| 108 | 28% | 716.28 | 715.84 | 334 nm | 510 nm | |
| 109 | 11% | 792.31 | 791.94 | 338 nm | 511 nm | 260° C. |
| 110 | 66% | 653.27 | 652.78 | 344 nm | 489 nm | 255° C. |
| 111 | 46% | 667.28 | 666.81 | 479 nm | 304 nm | 230° C. |
| 112 | 25% | 729.3 | 728.88 | 324 nm | 482 nm | 130° C. |
| 113 | 23% | 714.29 | 713.87 | 345 nm | 404 nm | 219° C. |
| 114 | 55% | 669.21 | 668.81 | 334 nm | 494 nm | 220° C. |
| 115 | 51% | 679.28 | 678.82 | 354 nm | 478 nm | 212° C. |

### Example 1

### Manufacture of OLED Device Using the Organic Electroluminescent Compound According to the Present Invention

An OLED device was manufactured using the electroluminescent material according to the present invention. First, a transparent electrode ITO thin film (15Ω/□) obtained from a glass for OLED (produced by Samsung Corning) was subjected to ultrasonic washing with trichloroethylene, acetone, ethanol and distilled water, sequentially, and stored in isopropanol before use.

Then, an ITO substrate was equipped in a substrate folder of a vacuum vapor deposition apparatus, and N¹,N^{1′}-([1,1′-biphenyl]-4,4′-diyl)bis(N¹-(naphthalen-1-yl)-N⁴,N⁴-diphenylbenzene-1,4-diamine was placed in a cell of the vacuum vapor deposition apparatus, which was then ventilated up to 10⁻⁶ torr of vacuum in the chamber. Then, electric current was applied to the cell to evaporate N¹,N^{1′}-([1,1′-biphenyl]-4,4′-diyl)bis(N¹-(naphthalen-1-yl)-N⁴,N⁴-diphenylbenzene-1,4-diamine, thereby forming a hole injection layer having a thickness of 60 nm on the ITO substrate. Then, N,N¹-di(4-biphenyl)-N,N¹-di(4-biphenyl)-4,4′-diaminobiphenyl was placed in another cell of the vacuum vapor deposition apparatus, and electric current was applied to the cell to evaporate NPB, thereby forming a hole transport layer having a thickness of 20 nm on the hole injection layer.

After forming the hole injection layer and the hole transport layer, an electroluminescent layer was formed thereon as follows. Compound 3 was placed in a cell of a vacuum vapor deposition apparatus as a host, and Compound D1 was placed in another cell as a dopant. The two materials were evaporated at different rates such that an electroluminescent layer having a thickness of 30 nm was vapor-deposited on the hole transport layer at 15 wt %. Subsequently, 2-(4-(9,10-di(naphthalen-2-yl)anthracen-2-yl)phenyl)-1-phenyl-1H-benzo[d]imidazole was placed as an electron transport layer on the electroluminescent layer, and Lithium quinolate was placed in another cell. The two materials were evaporated at the same rate such that an electroluminescent layer having a thickness of 30 nm was vapor-deposited at 50 wt %. Then, after vapor-depositing lithium quinolate (Liq) with a thickness of 2 nm as an electron injection layer, an Al cathode having a thickness of 150 nm was formed using another vacuum vapor deposition apparatus to manufacture an OLED.

Each compound used in the OLED device as an electroluminescent material was purified by vacuum sublimation at 10⁻⁶ torr.

As a result, it was confirmed that current of 5.84 mA/cm² flows and a green light of 2530 cd/m² was emitted.

### Example 2

### Manufacture of OLED Device Using the Organic Electroluminescent Compound According to the Present Invention

An OLED device was manufactured in the same manner as Example 1 except that Compound 6 was used as a host material.

As a result, it was confirmed that current of 12.9 mA/cm² flows and a green light of 5280 cd/m² was emitted.

### Example 3

### Manufacture of OLED Device Using the Organic Electroluminescent Compound According to the Present Invention

An OLED device was manufactured in the same manner as Example 1 except that Compound 9 was used as a host material.

As a result, it was confirmed that current of 3.36 mA/cm² flows and a green light of 1580 cd/m² was emitted.

### Example 4

### Manufacture of OLED Device Using the Organic Electroluminescent Compound According to the Present Invention

An OLED device was manufactured in the same manner as Example 1 except that Compound 61 was used as a host material.

As a result, it was confirmed that current of 12.5 mA/cm² flows and a green light of 4670 cd/m² was emitted.

### Example 5

### Manufacture of OLED Device Using the Organic Electroluminescent Compound According to the Present Invention

An OLED device was manufactured in the same manner as Example 1 except that Compound 74 was used as a host material.

As a result, it was confirmed that current of 4.16 mA/cm² flows and a green to light of 1750 cd/m² was emitted.

### Example 6

### Manufacture of OLED Device Using the Organic Electroluminescent Compound According to the Present Invention

An OLED device was manufactured in the same manner as Example 1 except that Compound 90 was used as a host material. As a result, it was confirmed that current of 17.1 mA/cm² flows and a green light of 6420 cd/m² was emitted.

### Example 7

### Manufacture of OLED Device Using the Organic Electroluminescent Compound According to the Present Invention

An OLED device was manufactured in the same manner as Example 1 except that Compound 104 was used as a host material.

As a result, it was confirmed that current of 2.32 mA/cm² flows and a green light of 940 cd/m² was emitted.

### Example 8

### Manufacture of OLED Device Using the Organic Electroluminescent Compound According to the Present Invention

An OLED device was manufactured in the same manner as Example 1 except that Compound 107 was used as a host material.

As a result, it was confirmed that current of 3.4 mA/cm² flows and a green light of 1490 cd/m² was emitted.

### Example 9

### Manufacture of OLED Device Using the Organic Electroluminescent Compound According to the Present Invention

An OLED device was manufactured in the same manner as Example 1 except that Compound 109 was used as a host material.

As a result, it was confirmed that current of 2.37 mA/cm² flows and a green to light of 890 cd/m² was emitted.

### Example 10

### Manufacture of OLED Device Using the Organic Electroluminescent Compound According to the Present Invention

An OLED device was manufactured in the same manner as Example 1 except that Compound III was used as a host material.

As a result, it was confirmed that current of 9.15 mA/cm² flows and a green light of 3790 cd/m² was emitted.

### Comparative Example 1

### Manufacture of OLED Device Using Conventional Electroluminescent Host Material

An OLED device was manufactured as in Example 1 except that an electroluminescent layer was vapor-deposited using 4,4′-N,N′-dicarbazole-biphenyl as a host material and aluminum(III)bis(2-methyl-8-quinolinato) (4-phenylphenolate)) of a 10 nm thickness was vapor-deposited on the electroluminescent layer as a hole blocking layer.

As a result, it was confirmed that current of 5.7 mA/cm² flows and a green light of 2000 cd/m² was emitted.

The organic electroluminescent compounds according to the present invention have excellent properties compared with the conventional material. In addition, the device using the organic electroluminescent compound according to the present invention as host material has an improved electroluminescent efficiency and consumes less power by improving power efficiency according to decrease of driving voltage.

1. An organic electroluminescent compound represented by Chemical Formula 1: 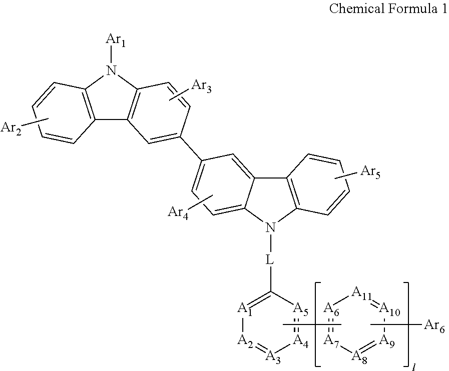
wherein
the I represents an integer of 0 to 2;
the L represents (C6-C30)arylene or (C3-C30)heteroarylene; the A₁ to A₁₁ independently represent CR7 or N; the R7 and Ar₁ to Ar₆ independently represent any one selected from the group consisting of hydrogen, deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl and tri(C6-C30)arylsilyl; each of alkyl, cycloalkyl, heterocycloalkyl, alkenyl, alkynyl, aryl, heteroaryl, arylene, and heteroarylene of the R7, and Ar₁ to Ar₆ is further substituted with one or more selected from the group consisting of deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl, (C1-C30)alkyldi(C6-C30)arylsilyl and tri(C6-C30)arylsilyl; carbon atoms of the A₁ to A₁₁ and carbon atoms of Ar₆ are linked through a chemical bond, or independently linked via any one selected from the group consisting of —CR₈R₉—, —O—, —NR₁₀— and —S— to form a fused ring; and definition on the R₈, R₉, R₁₀ and substituents thereof are the same as that of the R₇.

2. The organic electroluminescent compound of claim 1, which is represented by Chemical Formula 2: 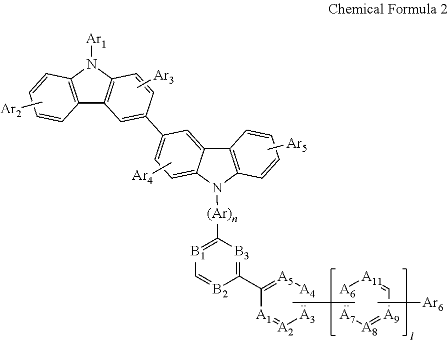
wherein
the I represents an integer of 1 to 2; the Ar represents (C6-C30)arylene, n represents an integer of 1 to 2; the A₁ to A₁₁ independently represent CR7 or N; the R7 and Ar₁ to Ar₆ independently represent any one selected from the group consisting of hydrogen, deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl and tri(C6-C30)arylsilyl; the B₁, B₂ and B₃ independently represent CH or N, but they do not represent CH at the same time; each of alkyl, cycloalkyl, heterocycloalkyl, alkenyl, alkynyl, aryl and heteroaryl of the R7, Ar₁ to Ar₆ is further substituted with one or more selected from the group consisting of deuterium, halogen, cyano, nitro, hydroxyl, (C1-C30)alkyl, halo(C1-C30)alkyl, (C3-C30)cycloalkyl, 5- to 7-membered heterocycloalkyl, (C2-C30)alkenyl, (C2-C30)alkynyl, (C6-C30)aryl, (C1-C30)alkoxy, (C6-C30)aryloxy, (C3-C30)heteroaryl, (C6-C30)ar(C1-C30)alkyl, (C6-C30)arylthio, mono or di(C1-C30)alkylamino, mono or di(C6-C30)arylamino, tri(C1-C30)alkylsilyl, di(C1-C30)alkyl(C6-C30)arylsilyl, (C1-C30)alkyldi(C6-C30)arylsilyl and tri(C6-C30)arylsilyl; carbon atoms of the A₁ to A₁₁ and carbon atoms of Ar₆ are linked through a chemical bond, or independently linked via any one selected from the group consisting of —CR₈R₉—, —O—, —NR₁₀— and —S— to form a fused ring; and definition on the R₈, R₉, R₁₀ and substituents thereof is the same as that of the R₇.

3. The organic electroluminescent compound of claim 1, which is represented by Chemical Formula 3. 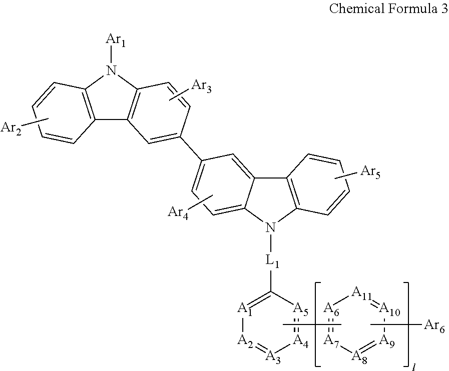
wherein
the L₁ represents (C3-C30)heteroarylene; definition on Ar₁ to Ar₆ and substituents of Ar₁ to Ar₆ is the same as that of Ar₁ to Ar₆ in Chemical Formula 1, and definition on A₁ to A₁₁ is the same as that of A₁ to A₁₁ in Chemical Formula 1; and the I is an integer of 1 to 2.

4. The organic electroluminescent compound of claim 1, which is to represented by Chemical Formula 4. 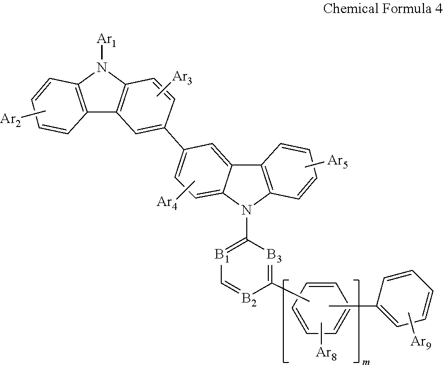
wherein
definition on Ar₁ to Ar₅, Ar₅ to Ar₉ and substituents thereof is the same as that of Ar₁ to Ar₆ in Chemical Formula 1; and the m represents an integer of 1 to 2, and the B₁, B₂ and B₃ independently represent CH or N, but they are not CH at the same time.

5. The organic electroluminescent compound of claim 1, which is represented by Chemical Formula 5. 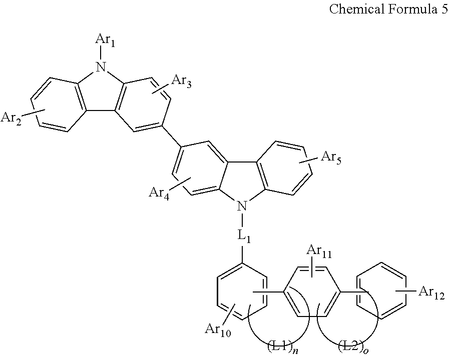
wherein
L₁ represents (C3-C30)heteroarylene; definition on Ar₁ to Ar₅, Ar₁₀ to Ar₁₂ and substituents thereof is the same as that of Ar₁ to Ar₆ in Chemical Formula 1;
the L1 to L2 independently represent any one selected from the group consisting of —CR₈R₉—, —O—, —NR₁₀— and —S—; definition on the R₈, R₉, R₁₀ and substituents thereof is the same as that of R₇ in Chemical Formula 1; and the n and o independently represent an integer of 0 to 1, and n+o=1.

6. The organic electroluminescent compound of claim 1, which is selected from following compounds:

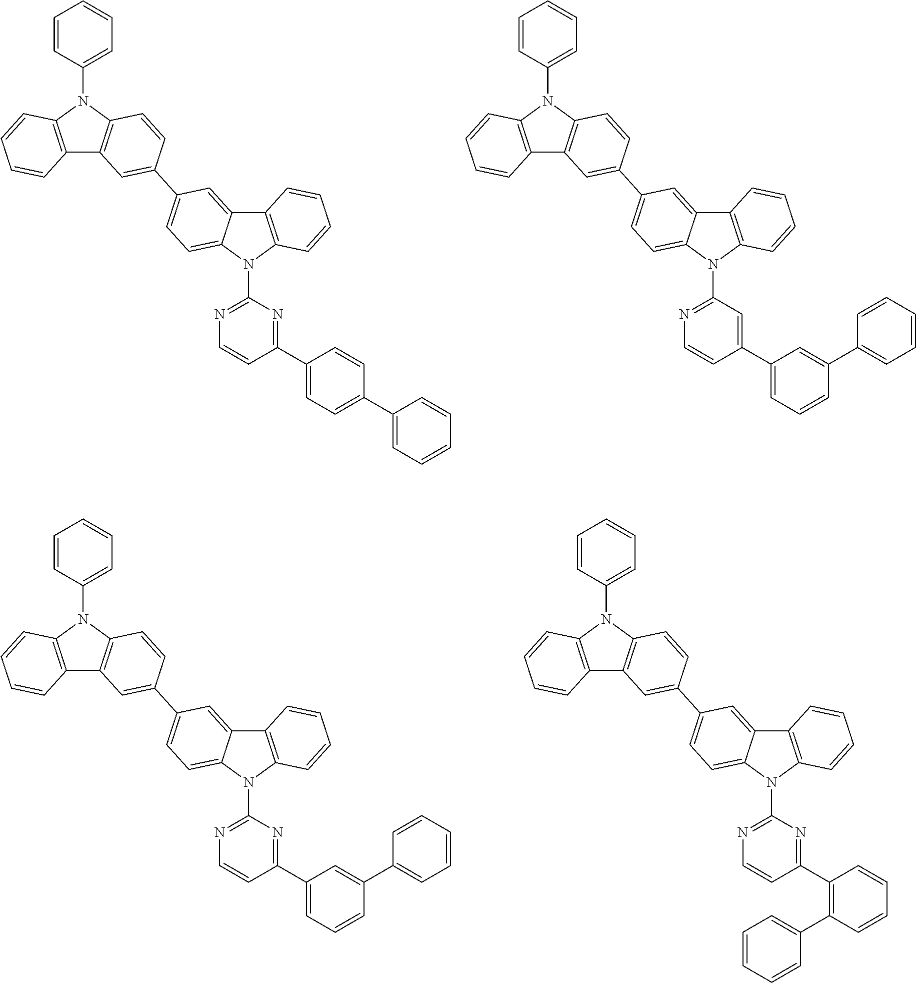 [SMILES: c1ccc(-c2ccc(-c3ccnc(-n4c5ccccc5c5cc(-c6ccc7c(c6)c6ccccc6n7-c6ccccc6)ccc54)n3)cc2)cc1 ; c1ccc(-c2cccc(-c3ccnc(-n4c5ccccc5c5cc(-c6ccc7c(c6)c6ccccc6n7-c6ccccc6)ccc54)c3)c2)cc1 ; c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccccc2-c2ccnc(-n3c4ccccc4c4cc(-c5ccc6c(c5)c5ccccc5n6-c5ccccc5)ccc43)n2)cc1]

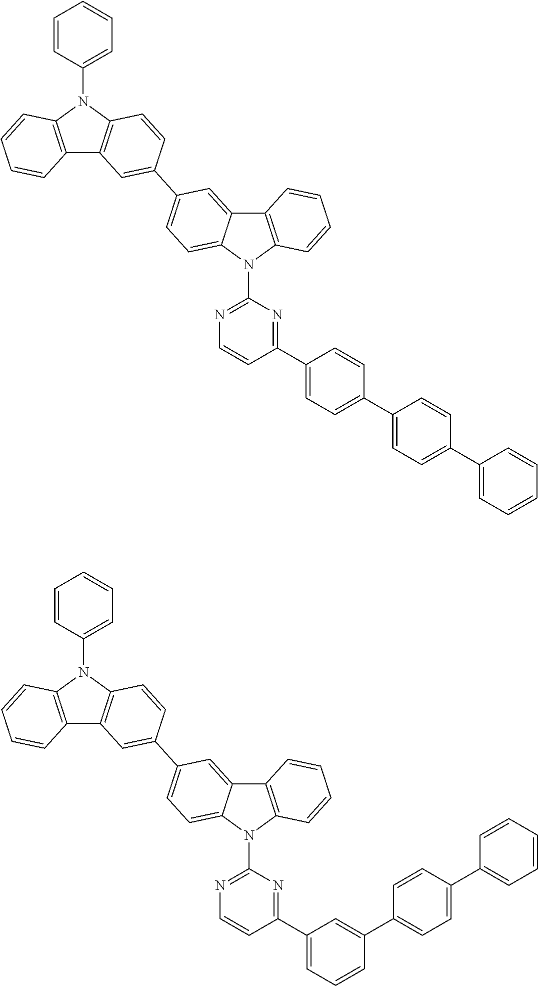 [SMILES: c1ccc(-c2ccc(-c3ccc(-c4ccnc(-n5c6ccccc6c6cc(-c7ccc8c(c7)c7ccccc7n8-c7ccccc7)ccc65)n4)cc3)cc2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

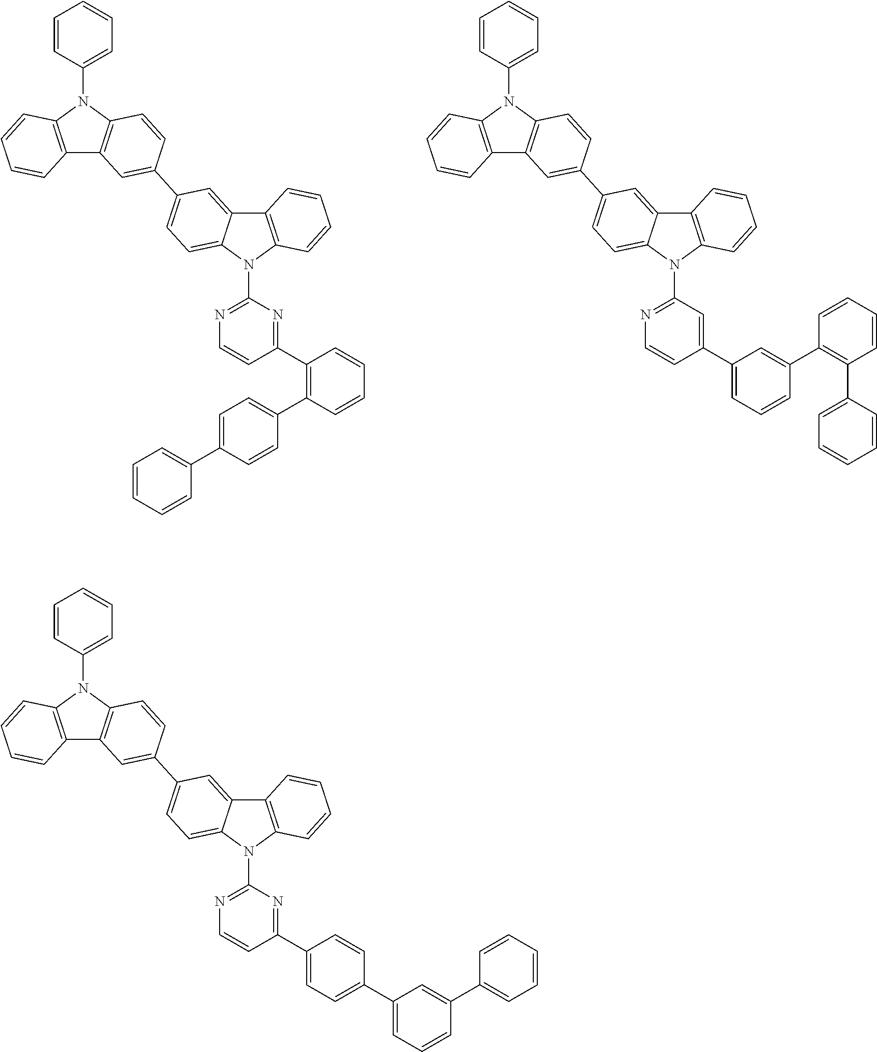 [SMILES: c1ccc(-c2ccc(-c3ccccc3-c3ccnc(-n4c5ccccc5c5cc(-c6ccc7c(c6)c6ccccc6n7-c6ccccc6)ccc54)n3)cc2)cc1 ; c1ccc(-c2ccccc2-c2cccc(-c3ccnc(-n4c5ccccc5c5cc(-c6ccc7c(c6)c6ccccc6n7-c6ccccc6)ccc54)c3)c2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1]

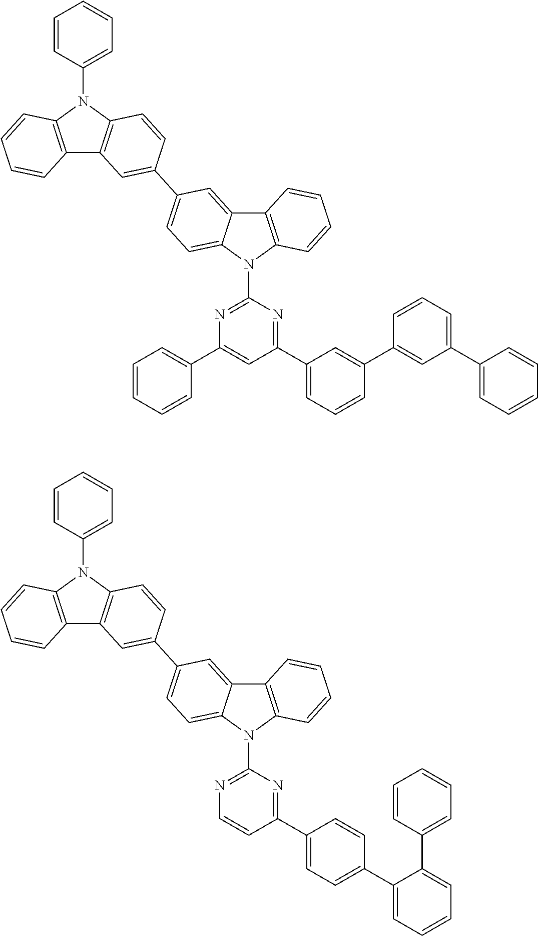 [SMILES: c1ccc(-c2cccc(-c3cccc(-c4cc(-c5ccccc5)nc(-n5c6ccccc6c6cc(-c7ccc8c(c7)c7ccccc7n8-c7ccccc7)ccc65)n4)c3)c2)cc1 ; c1ccc(-c2ccccc2-c2ccc(-c3ccnc(-n4c5ccccc5c5cc(-c6ccc7c(c6)c6ccccc6n7-c6ccccc6)ccc54)n3)cc2)cc1]

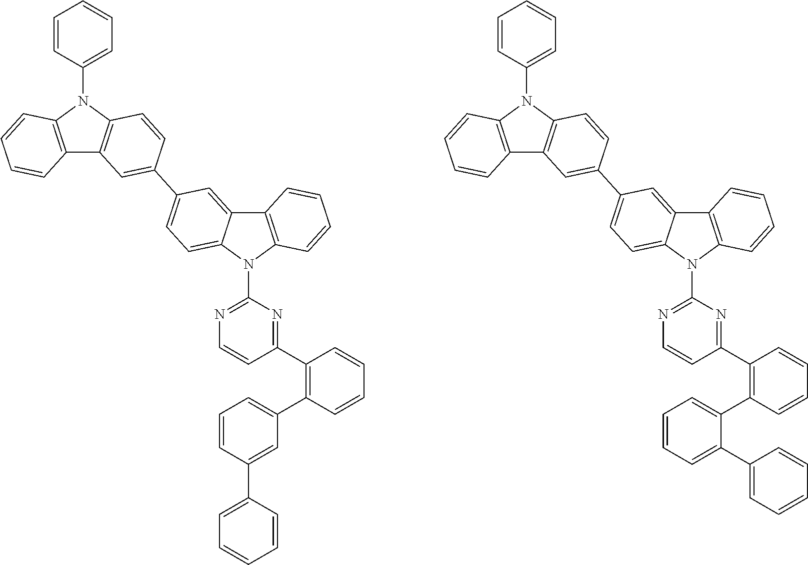 [SMILES: c1ccc(-c2cccc(-c3ccccc3-c3ccnc(-n4c5ccccc5c5cc(-c6ccc7c(c6)c6ccccc6n7-c6ccccc6)ccc54)n3)c2)cc1 ; c1ccc(-c2ccccc2-c2ccccc2-c2ccnc(-n3c4ccccc4c4cc(-c5ccc6c(c5)c5ccccc5n6-c5ccccc5)ccc43)n2)cc1]

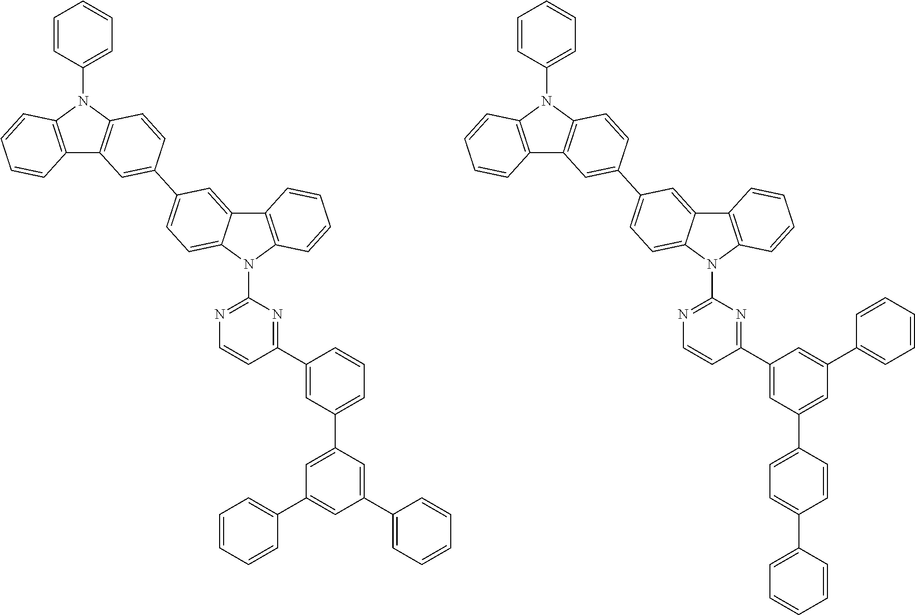 [SMILES: c1ccc(-c2cc(-c3ccccc3)cc(-c3cccc(-c4ccnc(-n5c6ccccc6c6cc(-c7ccc8c(c7)c7ccccc7n8-c7ccccc7)ccc65)n4)c3)c2)cc1 ; c1ccc(-c2ccc(-c3cc(-c4ccccc4)cc(-c4ccnc(-n5c6ccccc6c6cc(-c7ccc8c(c7)c7ccccc7n8-c7ccccc7)ccc65)n4)c3)cc2)cc1]

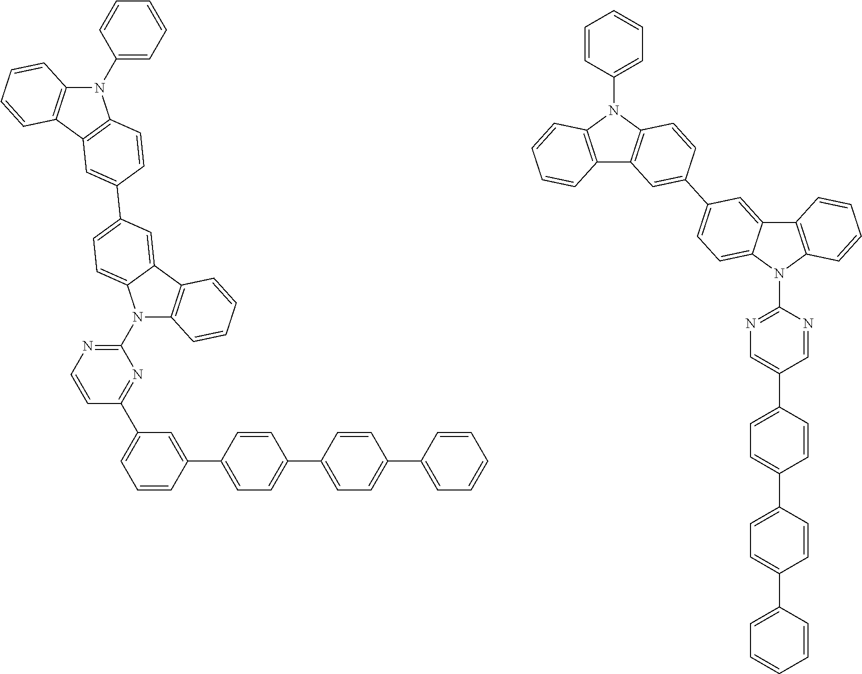 [SMILES: c1ccc(-c2ccc(-c3ccc(-c4cccc(-c5ccnc(-n6c7ccccc7c7cc(-c8ccc9c(c8)c8ccccc8n9-c8ccccc8)ccc76)n5)c4)cc3)cc2)cc1 ; c1ccc(-c2ccc(-c3ccc(-c4cnc(-n5c6ccccc6c6cc(-c7ccc8c(c7)c7ccccc7n8-c7ccccc7)ccc65)nc4)cc3)cc2)cc1]

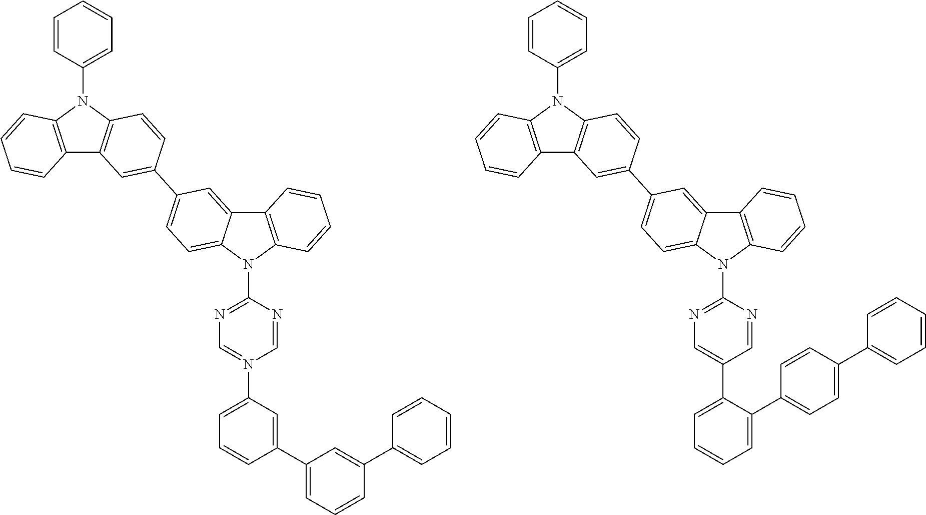

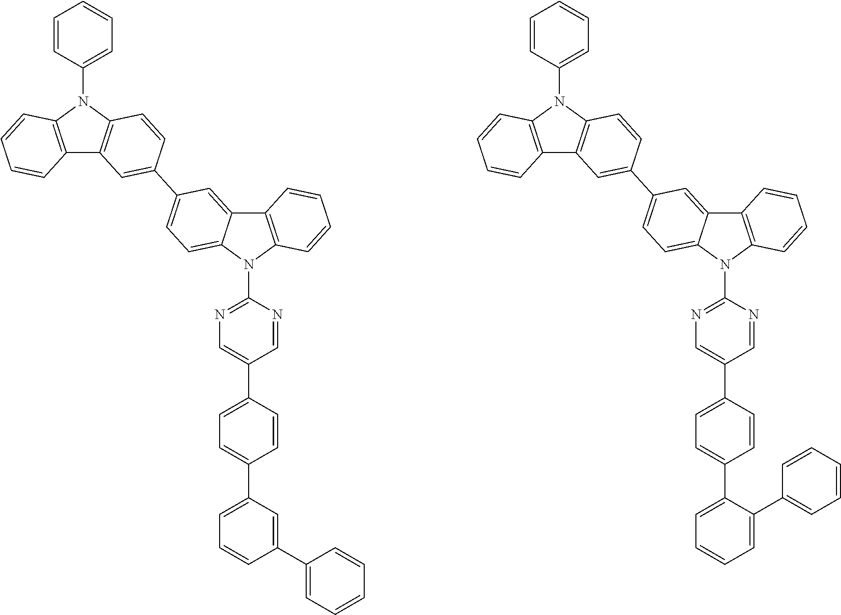 [SMILES: c1ccc(-c2cccc(-c3ccc(-c4cnc(-n5c6ccccc6c6cc(-c7ccc8c(c7)c7ccccc7n8-c7ccccc7)ccc65)nc4)cc3)c2)cc1 ; c1ccc(-c2ccccc2-c2ccc(-c3cnc(-n4c5ccccc5c5cc(-c6ccc7c(c6)c6ccccc6n7-c6ccccc6)ccc54)nc3)cc2)cc1]

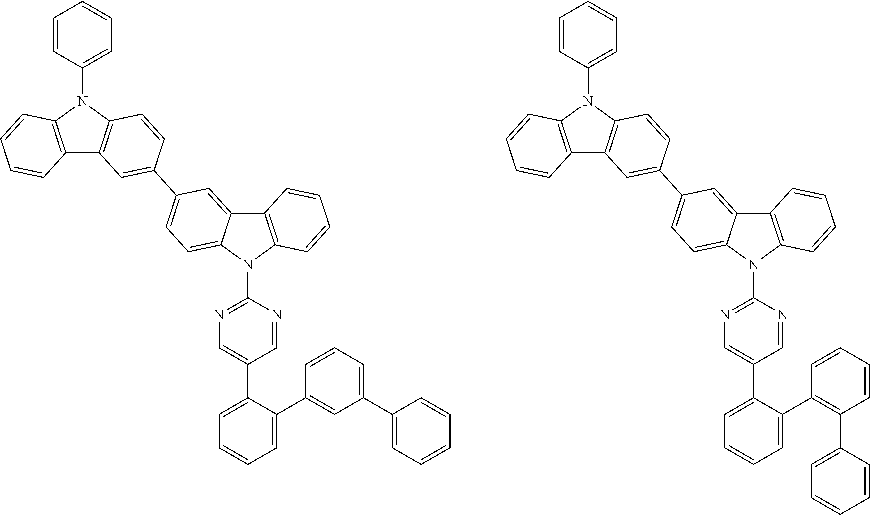 [SMILES: c1ccc(-c2cccc(-c3ccccc3-c3cnc(-n4c5ccccc5c5cc(-c6ccc7c(c6)c6ccccc6n7-c6ccccc6)ccc54)nc3)c2)cc1 ; c1ccc(-c2ccccc2-c2ccccc2-c2cnc(-n3c4ccccc4c4cc(-c5ccc6c(c5)c5ccccc5n6-c5ccccc5)ccc43)nc2)cc1]

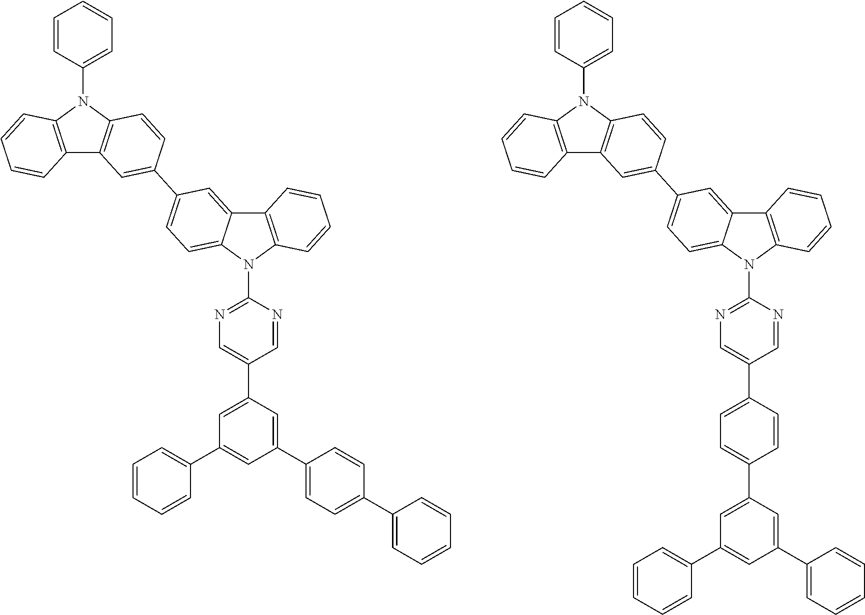 [SMILES: c1ccc(-c2ccc(-c3cc(-c4ccccc4)cc(-c4cnc(-n5c6ccccc6c6cc(-c7ccc8c(c7)c7ccccc7n8-c7ccccc7)ccc65)nc4)c3)cc2)cc1 ; c1ccc(-c2cc(-c3ccccc3)cc(-c3ccc(-c4cnc(-n5c6ccccc6c6cc(-c7ccc8c(c7)c7ccccc7n8-c7ccccc7)ccc65)nc4)cc3)c2)cc1]

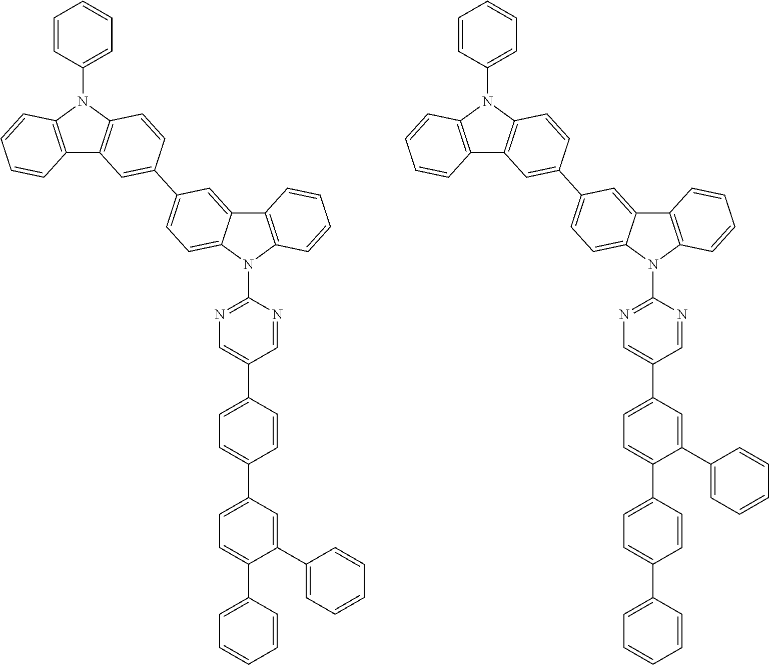 [SMILES: c1ccc(-c2ccc(-c3ccc(-c4cnc(-n5c6ccccc6c6cc(-c7ccc8c(c7)c7ccccc7n8-c7ccccc7)ccc65)nc4)cc3)cc2-c2ccccc2)cc1 ; c1ccc(-c2ccc(-c3ccc(-c4cnc(-n5c6ccccc6c6cc(-c7ccc8c(c7)c7ccccc7n8-c7ccccc7)ccc65)nc4)cc3-c3ccccc3)cc2)cc1]

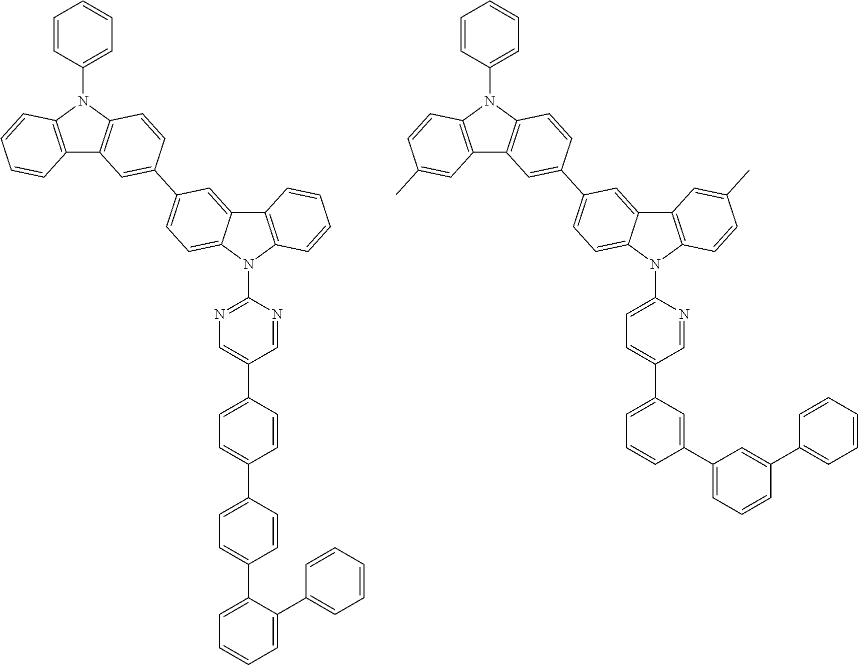 [SMILES: c1ccc(-c2ccccc2-c2ccc(-c3ccc(-c4cnc(-n5c6ccccc6c6cc(-c7ccc8c(c7)c7ccccc7n8-c7ccccc7)ccc65)nc4)cc3)cc2)cc1 ; Cc1ccc2c(c1)c1cc(-c3ccc4c(c3)c3cc(C)ccc3n4-c3ccc(-c4cccc(-c5cccc(-c6ccccc6)c5)c4)cn3)ccc1n2-c1ccccc1]

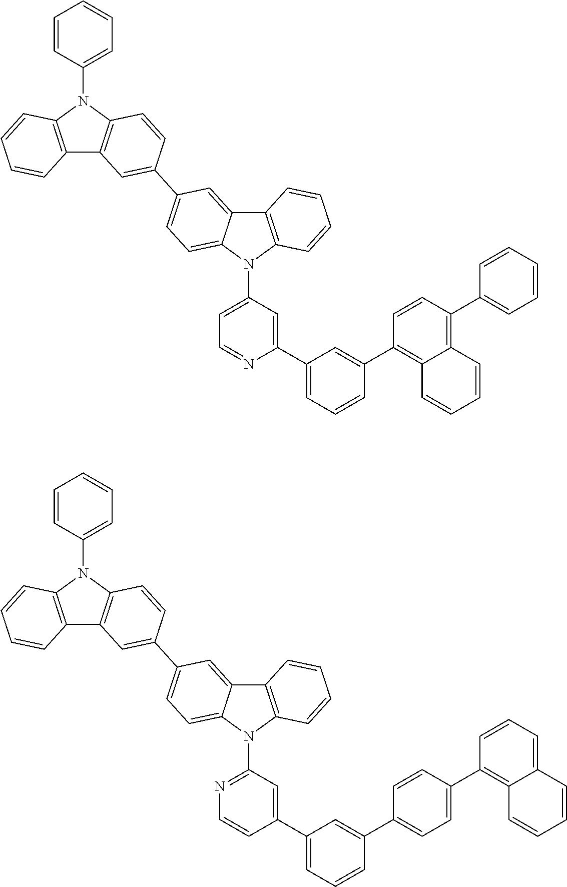 [SMILES: c1ccc(-c2ccc(-c3cccc(-c4cc(-n5c6ccccc6c6cc(-c7ccc8c(c7)c7ccccc7n8-c7ccccc7)ccc65)ccn4)c3)c3ccccc23)cc1 ; c1ccc(-n2c3ccccc3c3cc(-c4ccc5c(c4)c4ccccc4n5-c4cc(-c5cccc(-c6ccc(-c7cccc8ccccc78)cc6)c5)ccn4)ccc32)cc1]

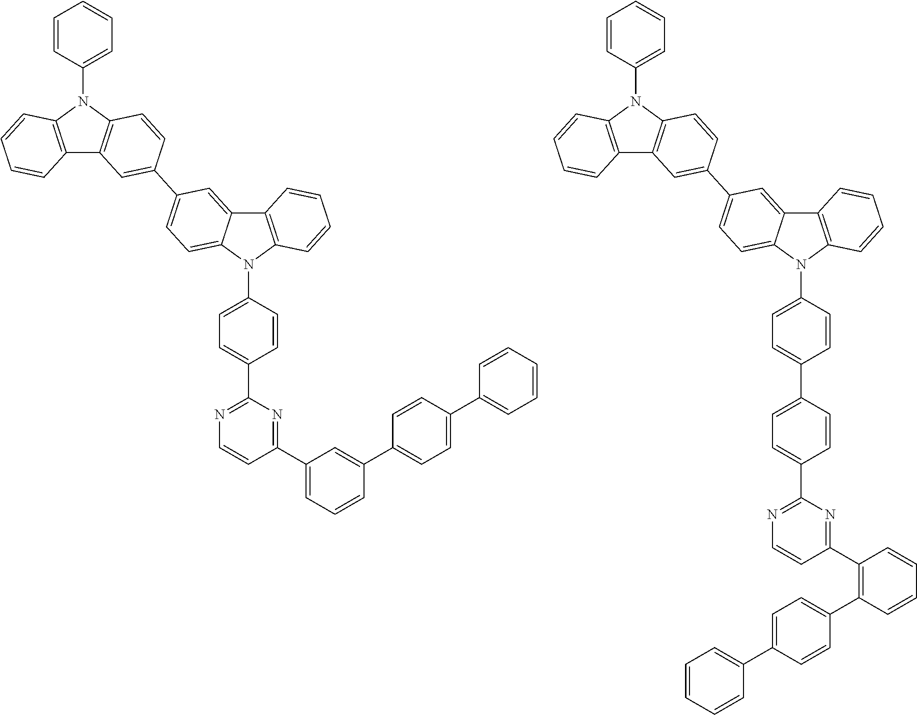 [SMILES: c1ccc(-c2ccc(-c3cccc(-c4ccnc(-c5ccc(-n6c7ccccc7c7cc(-c8ccc9c(c8)c8ccccc8n9-c8ccccc8)ccc76)cc5)n4)c3)cc2)cc1 ; c1ccc(-c2ccc(-c3ccccc3-c3ccnc(-c4ccc(-c5ccc(-n6c7ccccc7c7cc(-c8ccc9c(c8)c8ccccc8n9-c8ccccc8)ccc76)cc5)cc4)n3)cc2)cc1]

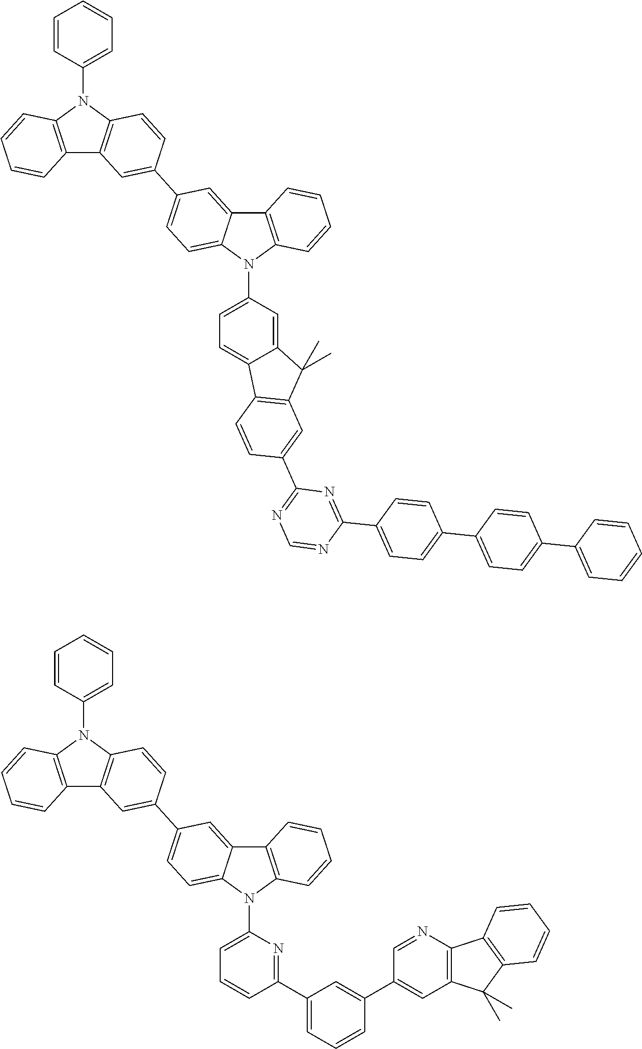

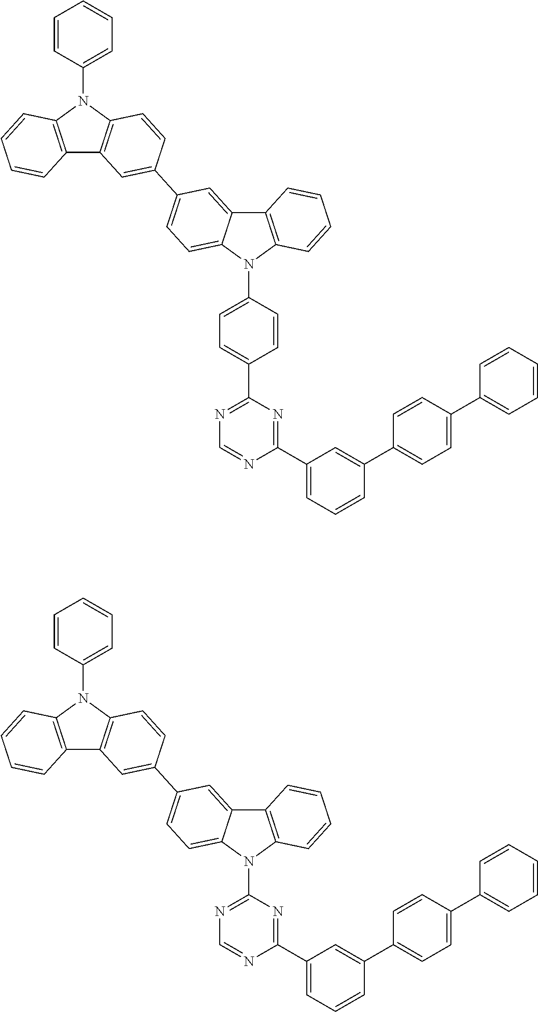 [SMILES: c1ccc(-c2ccc(-c3cccc(-c4ncnc(-c5ccc(-n6c7ccccc7c7cc(-c8ccc9c(c8)c8ccccc8n9-c8ccccc8)ccc76)cc5)n4)c3)cc2)cc1 ; c1ccc(-c2ccc(-c3cccc(-c4ncnc(-n5c6ccccc6c6cc(-c7ccc8c(c7)c7ccccc7n8-c7ccccc7)ccc65)n4)c3)cc2)cc1]

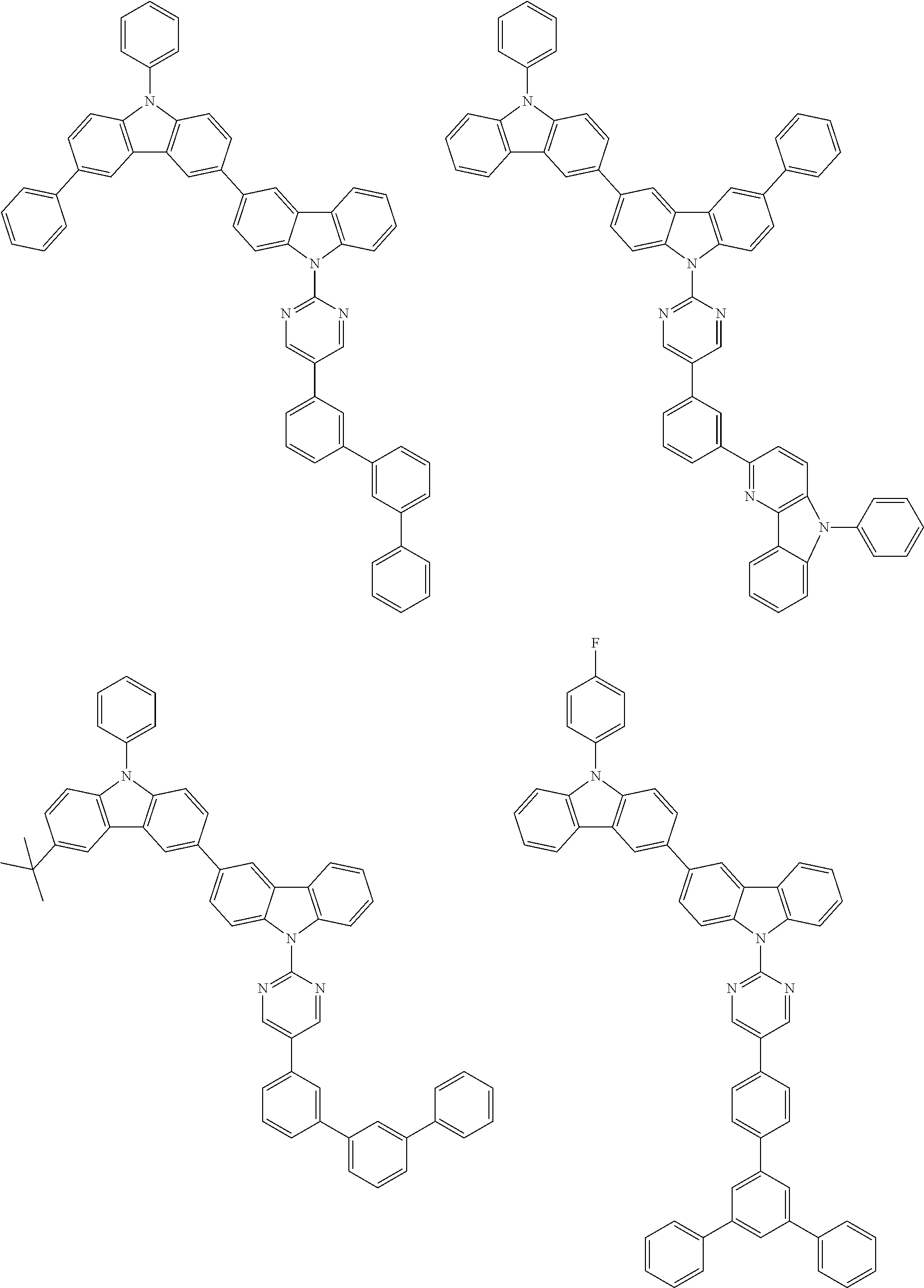 [SMILES: c1ccc(-c2cccc(-c3cccc(-c4cnc(-n5c6ccccc6c6cc(-c7ccc8c(c7)c7cc(-c9ccccc9)ccc7n8-c7ccccc7)ccc65)nc4)c3)c2)cc1 ; c1ccc(-c2ccc3c(c2)c2cc(-c4ccc5c(c4)c4ccccc4n5-c4ccccc4)ccc2n3-c2ncc(-c3cccc(-c4ccc5c(n4)c4ccccc4n5-c4ccccc4)c3)cn2)cc1 ; CC(C)(C)c1ccc2c(c1)c1cc(-c3ccc4c(c3)c3ccccc3n4-c3ncc(-c4cccc(-c5cccc(-c6ccccc6)c5)c4)cn3)ccc1n2-c1ccccc1 ; Fc1ccc(-n2c3ccccc3c3cc(-c4ccc5c(c4)c4ccccc4n5-c4ncc(-c5ccc(-c6cc(-c7ccccc7)cc(-c7ccccc7)c6)cc5)cn4)ccc32)cc1]

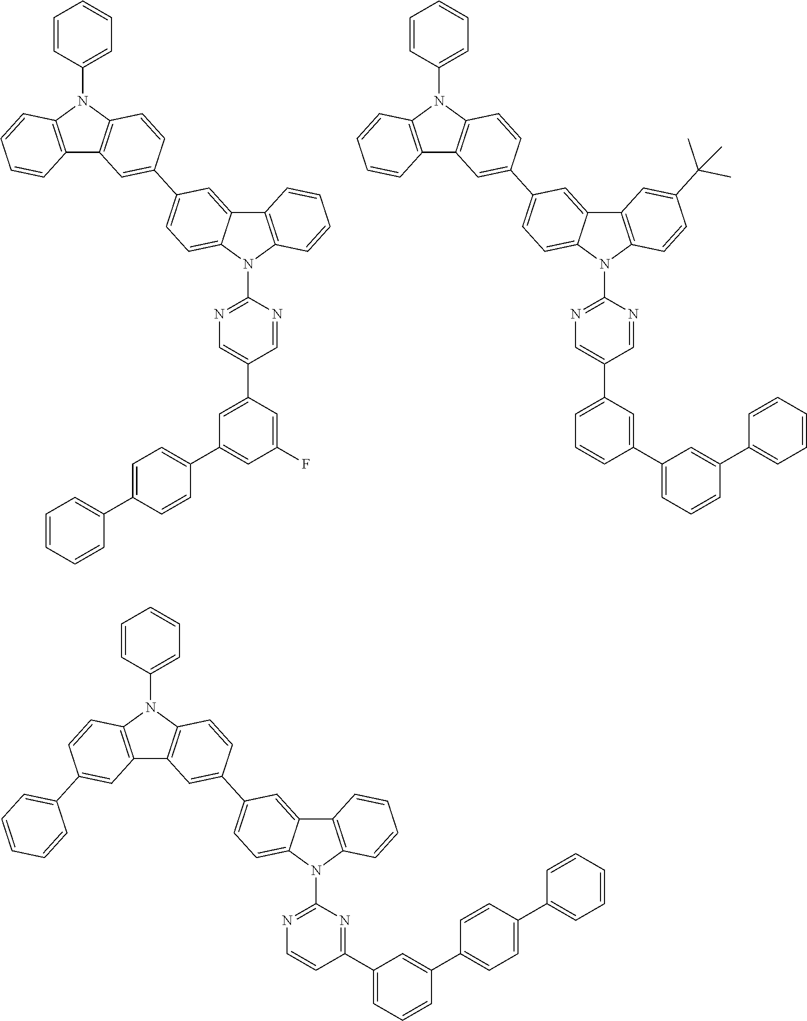 [SMILES: Fc1cc(-c2ccc(-c3ccccc3)cc2)cc(-c2cnc(-n3c4ccccc4c4cc(-c5ccc6c(c5)c5ccccc5n6-c5ccccc5)ccc43)nc2)c1 ; CC(C)(C)c1ccc2c(c1)c1cc(-c3ccc4c(c3)c3ccccc3n4-c3ccccc3)ccc1n2-c1ncc(-c2cccc(-c3cccc(-c4ccccc4)c3)c2)cn1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

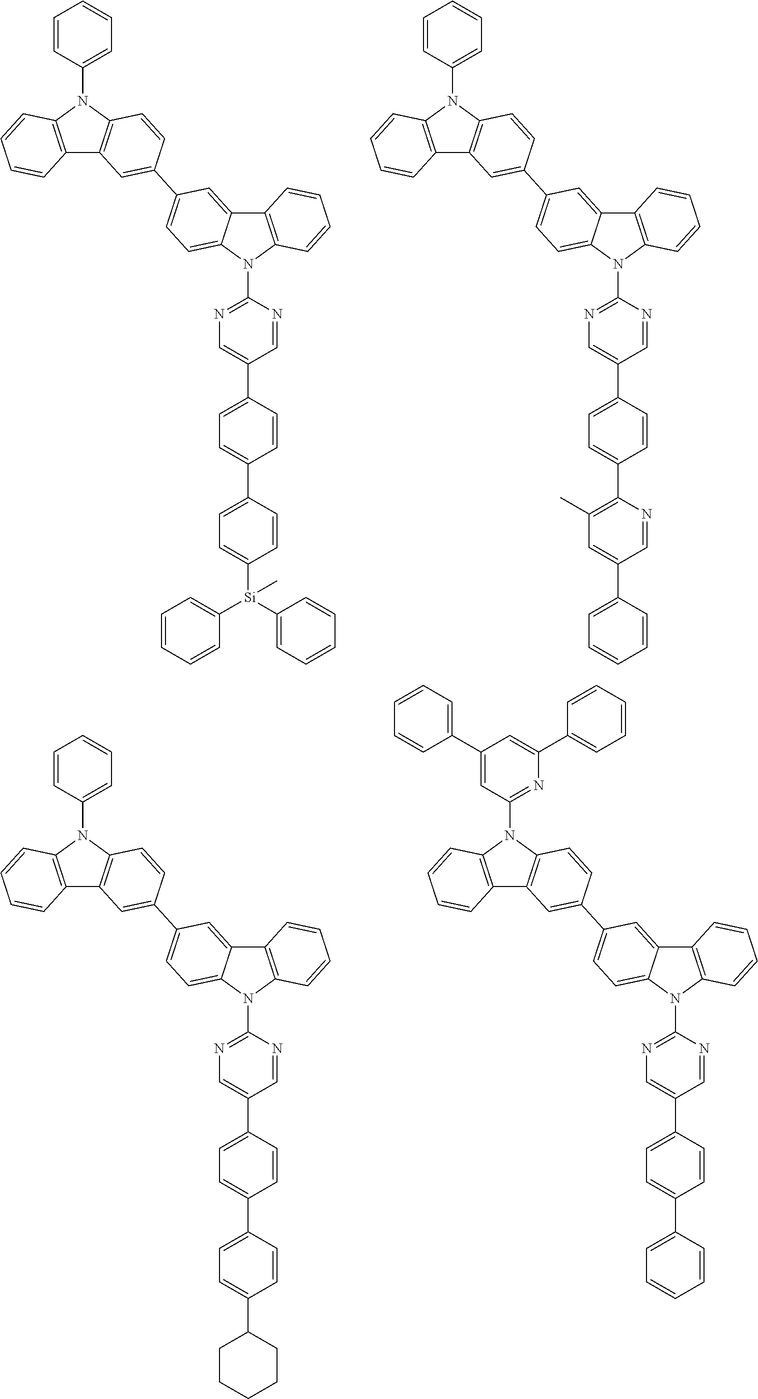

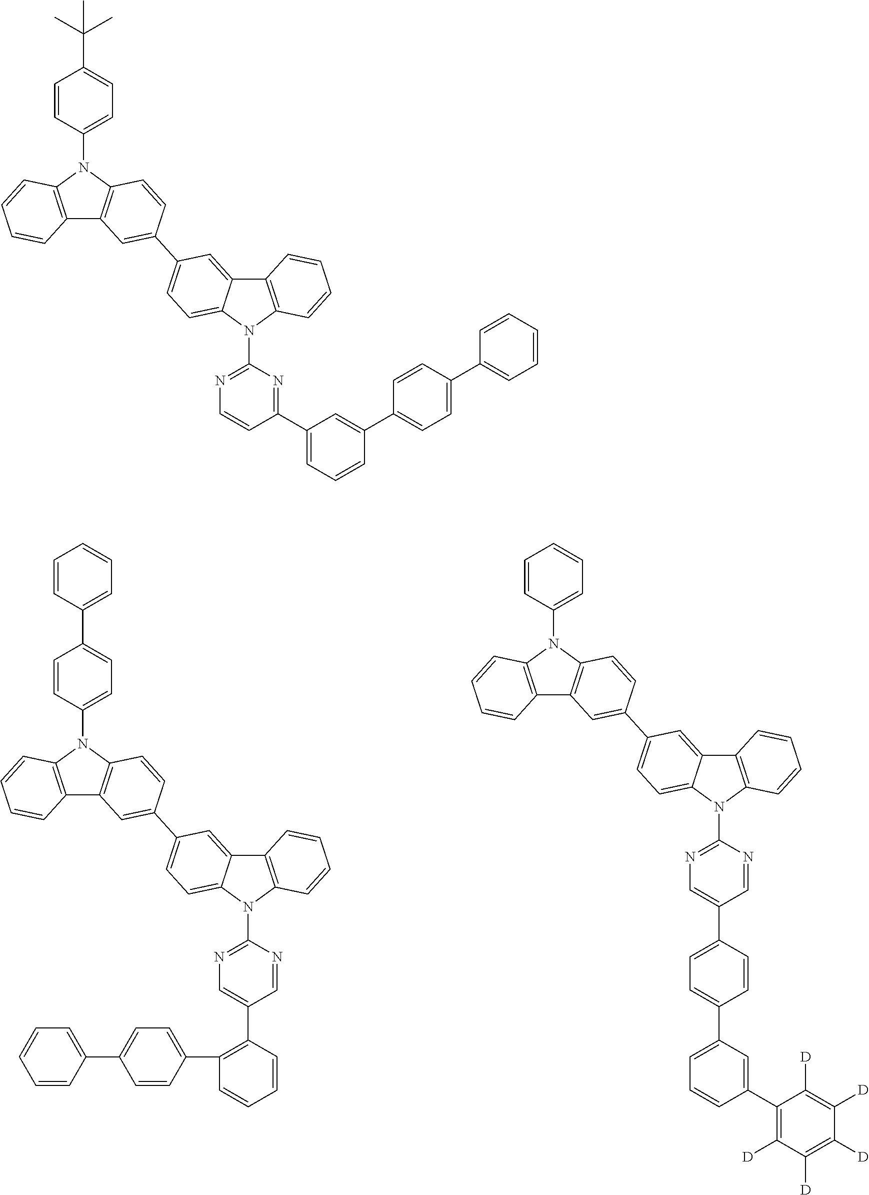 [SMILES: CC(C)(C)c1ccc(-n2c3ccccc3c3cc(-c4ccc5c(c4)c4ccccc4n5-c4nccc(-c5cccc(-c6ccc(-c7ccccc7)cc6)c5)n4)ccc32)cc1 ; c1ccc(-c2ccc(-c3ccccc3-c3cnc(-n4c5ccccc5c5cc(-c6ccc7c(c6)c6ccccc6n7-c6ccc(-c7ccccc7)cc6)ccc54)nc3)cc2)cc1 ; [2H]c1c([2H])c([2H])c(-c2cccc(-c3ccc(-c4cnc(-n5c6ccccc6c6cc(-c7ccc8c(c7)c7ccccc7n8-c7ccccc7)ccc65)nc4)cc3)c2)c([2H])c1[2H]]

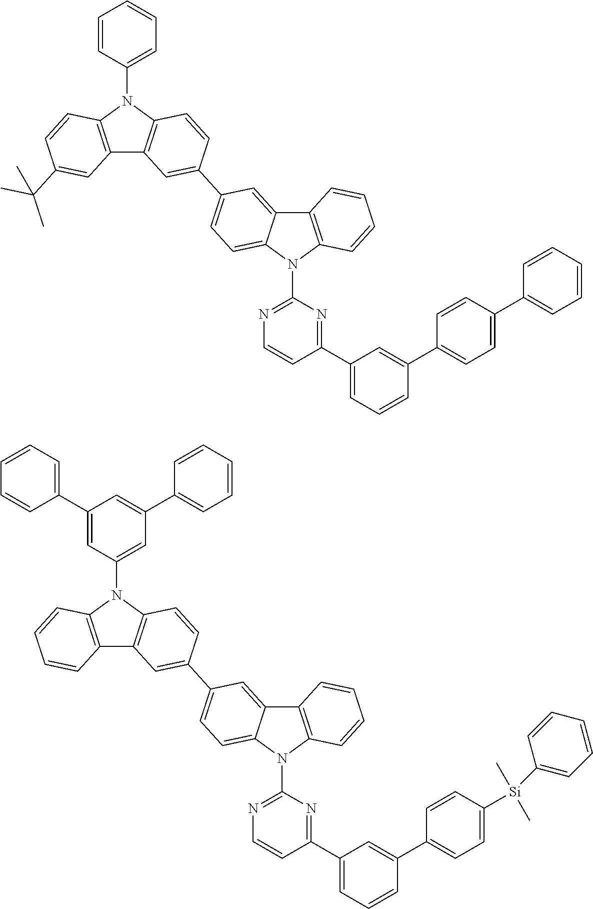 [SMILES: CC(C)(C)c1ccc2c(c1)c1cc(-c3ccc4c(c3)c3ccccc3n4-c3nccc(-c4cccc(-c5ccc(-c6ccccc6)cc5)c4)n3)ccc1n2-c1ccccc1 ; C[Si](C)(c1ccccc1)c1ccc(-c2cccc(-c3ccnc(-n4c5ccccc5c5cc(-c6ccc7c(c6)c6ccccc6n7-c6cc(-c7ccccc7)cc(-c7ccccc7)c6)ccc54)n3)c2)cc1]

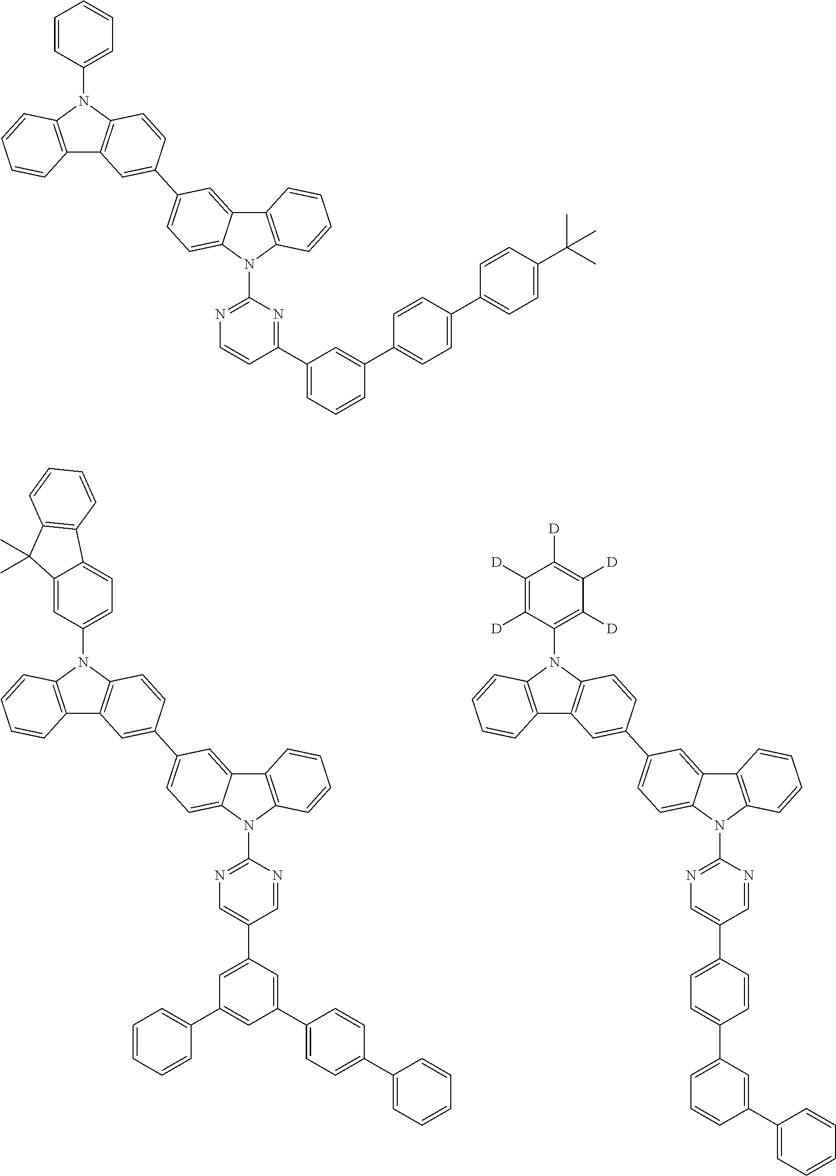

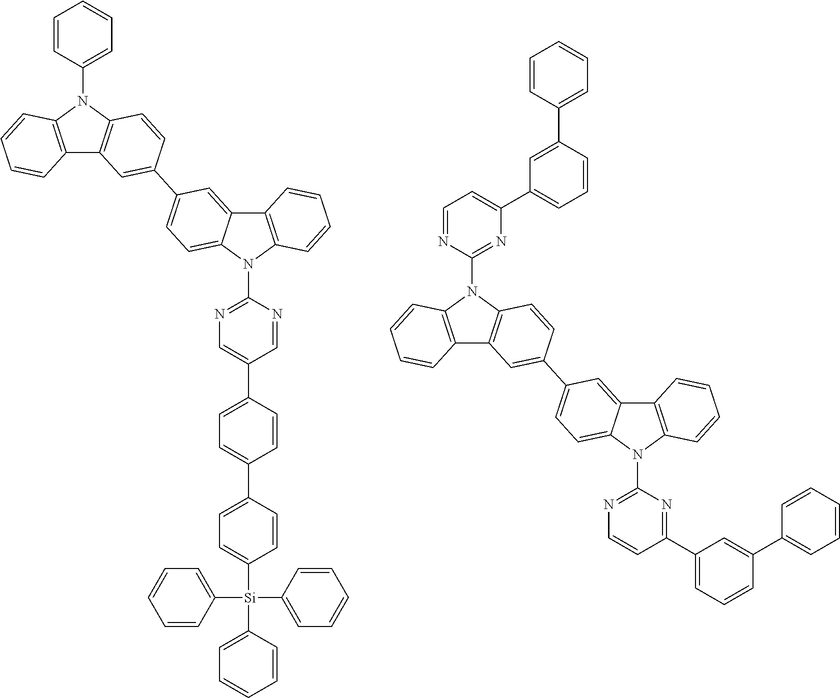 [SMILES: c1ccc(-n2c3ccccc3c3cc(-c4ccc5c(c4)c4ccccc4n5-c4ncc(-c5ccc(-c6ccc([Si](c7ccccc7)(c7ccccc7)c7ccccc7)cc6)cc5)cn4)ccc32)cc1 ; c1ccc(-c2cccc(-c3ccnc(-n4c5ccccc5c5cc(-c6ccc7c(c6)c6ccccc6n7-c6nccc(-c7cccc(-c8ccccc8)c7)n6)ccc54)n3)c2)cc1]

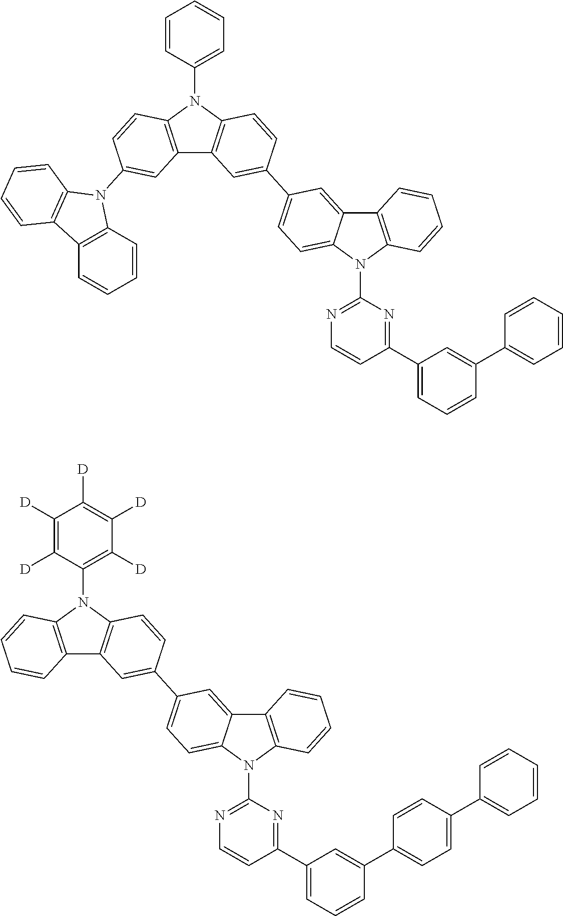 [SMILES: c1ccc(-c2cccc(-c3ccnc(-n4c5ccccc5c5cc(-c6ccc7c(c6)c6cc(-n8c9ccccc9c9ccccc98)ccc6n7-c6ccccc6)ccc54)n3)c2)cc1 ; [2H]c1c([2H])c([2H])c(-n2c3ccccc3c3cc(-c4ccc5c(c4)c4ccccc4n5-c4nccc(-c5cccc(-c6ccc(-c7ccccc7)cc6)c5)n4)ccc32)c([2H])c1[2H]]

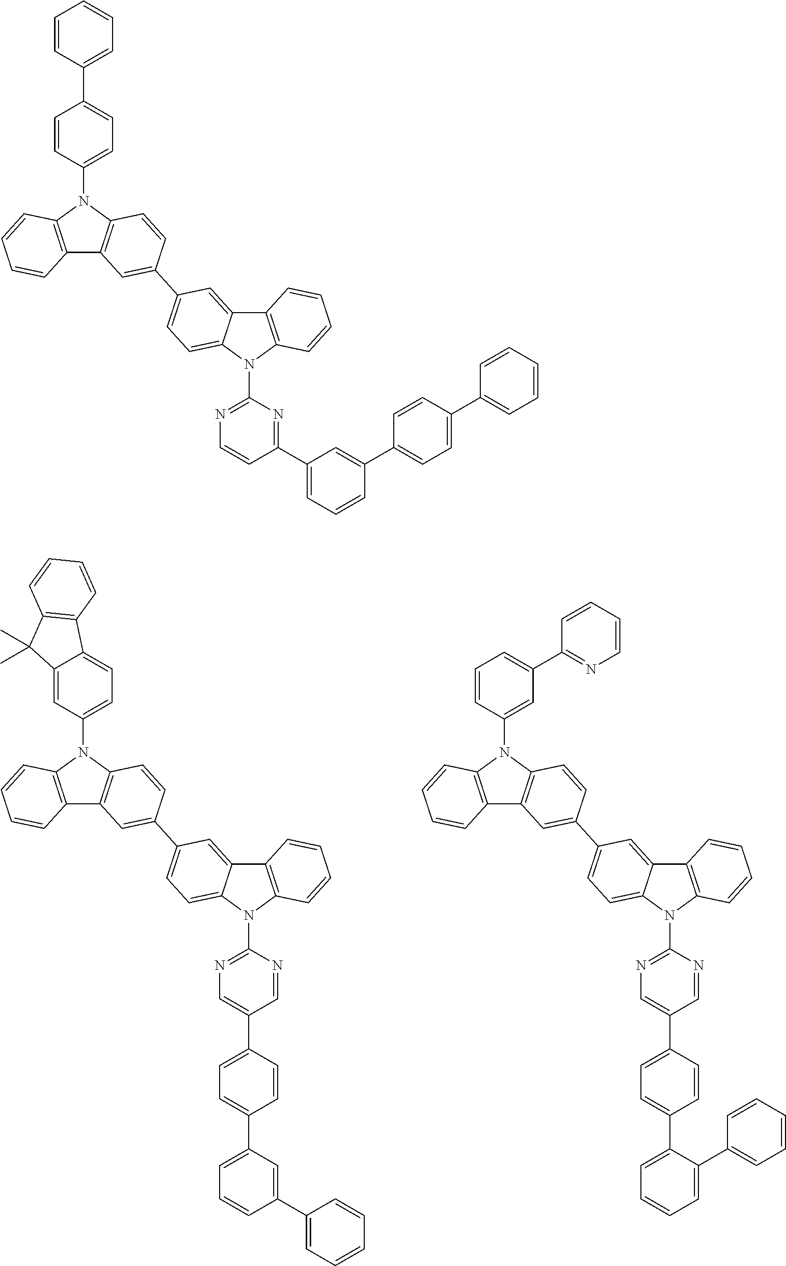 [SMILES: c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1 ; CC1(C)c2ccccc2-c2ccc(-n3c4ccccc4c4cc(-c5ccc6c(c5)c5ccccc5n6-c5ncc(-c6ccc(-c7cccc(-c8ccccc8)c7)cc6)cn5)ccc43)cc21 ; c1ccc(-c2ccccc2-c2ccc(-c3cnc(-n4c5ccccc5c5cc(-c6ccc7c(c6)c6ccccc6n7-c6cccc(-c7ccccn7)c6)ccc54)nc3)cc2)cc1]

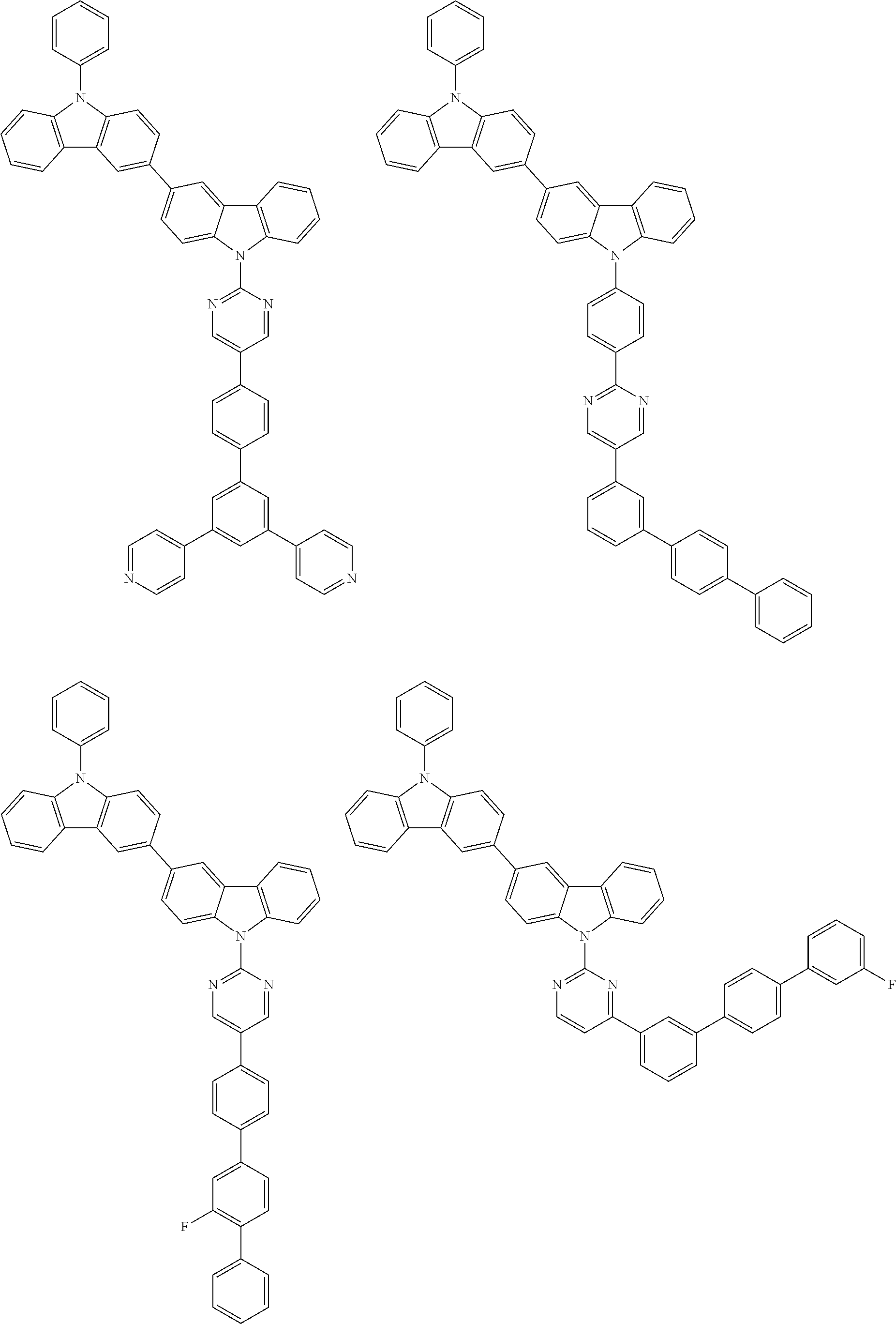 [SMILES: c1ccc(-n2c3ccccc3c3cc(-c4ccc5c(c4)c4ccccc4n5-c4ncc(-c5ccc(-c6cc(-c7ccncc7)cc(-c7ccncc7)c6)cc5)cn4)ccc32)cc1 ; c1ccc(-c2ccc(-c3cccc(-c4cnc(-c5ccc(-n6c7ccccc7c7cc(-c8ccc9c(c8)c8ccccc8n9-c8ccccc8)ccc76)cc5)nc4)c3)cc2)cc1 ; Fc1cc(-c2ccc(-c3cnc(-n4c5ccccc5c5cc(-c6ccc7c(c6)c6ccccc6n7-c6ccccc6)ccc54)nc3)cc2)ccc1-c1ccccc1 ; Fc1cccc(-c2ccc(-c3cccc(-c4ccnc(-n5c6ccccc6c6cc(-c7ccc8c(c7)c7ccccc7n8-c7ccccc7)ccc65)n4)c3)cc2)c1]

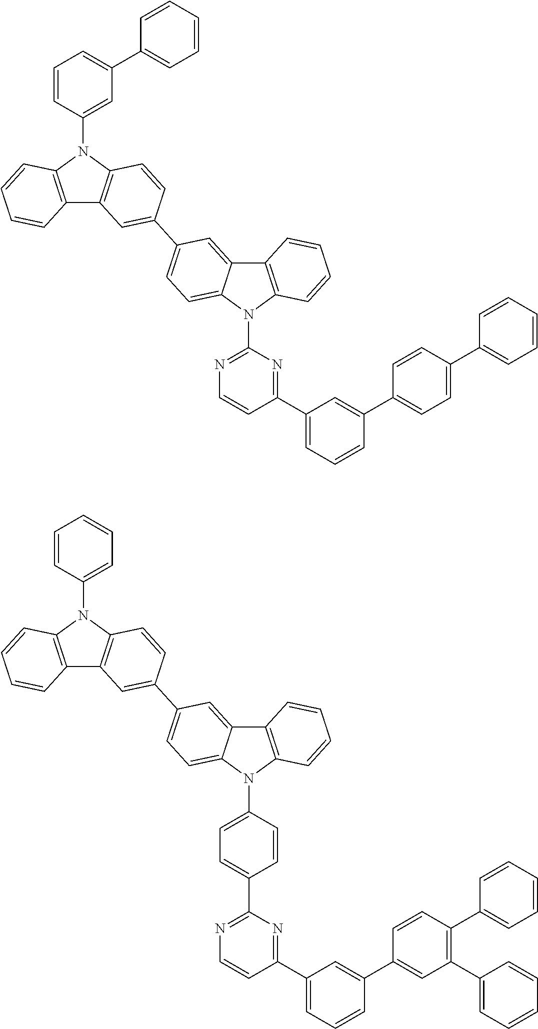 [SMILES: c1ccc(-c2ccc(-c3cccc(-c4ccnc(-n5c6ccccc6c6cc(-c7ccc8c(c7)c7ccccc7n8-c7cccc(-c8ccccc8)c7)ccc65)n4)c3)cc2)cc1 ; c1ccc(-c2ccc(-c3cccc(-c4ccnc(-c5ccc(-n6c7ccccc7c7cc(-c8ccc9c(c8)c8ccccc8n9-c8ccccc8)ccc76)cc5)n4)c3)cc2-c2ccccc2)cc1]

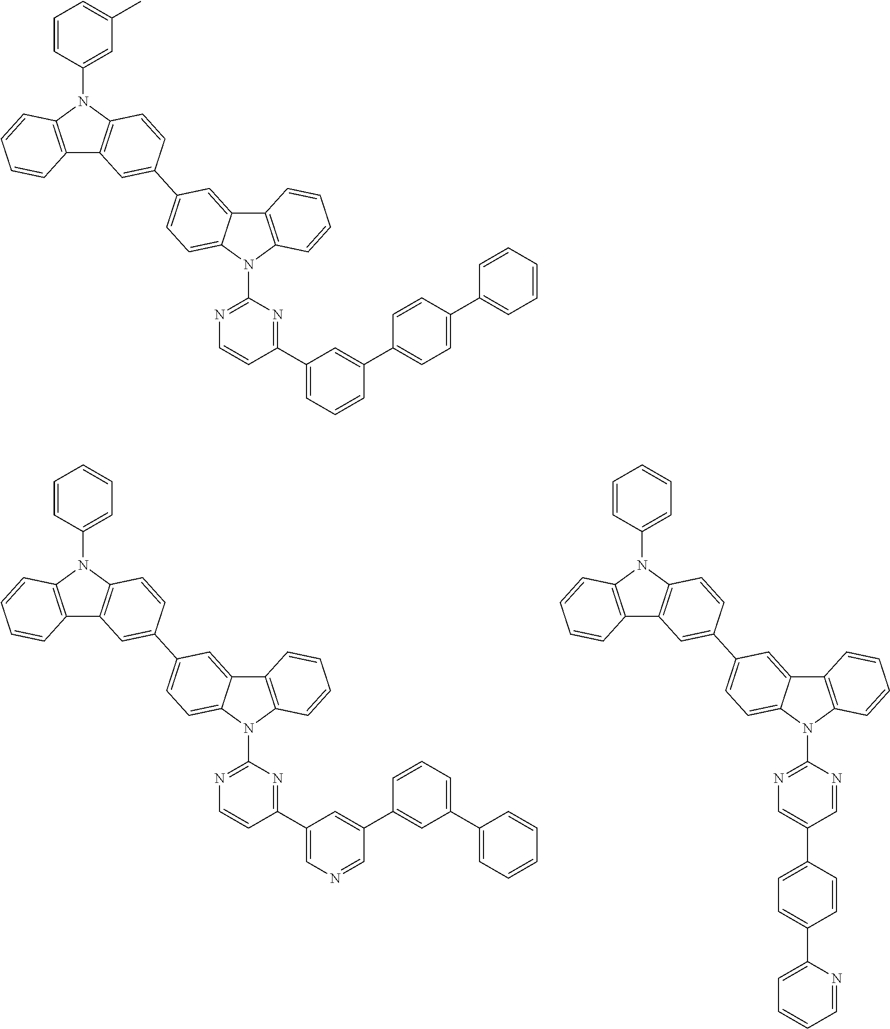 [SMILES: Cc1cccc(-n2c3ccccc3c3cc(-c4ccc5c(c4)c4ccccc4n5-c4nccc(-c5cccc(-c6ccc(-c7ccccc7)cc6)c5)n4)ccc32)c1 ; c1ccc(-c2cccc(-c3cncc(-c4ccnc(-n5c6ccccc6c6cc(-c7ccc8c(c7)c7ccccc7n8-c7ccccc7)ccc65)n4)c3)c2)cc1 ; c1ccc(-n2c3ccccc3c3cc(-c4ccc5c(c4)c4ccccc4n5-c4ncc(-c5ccc(-c6ccccn6)cc5)cn4)ccc32)cc1]

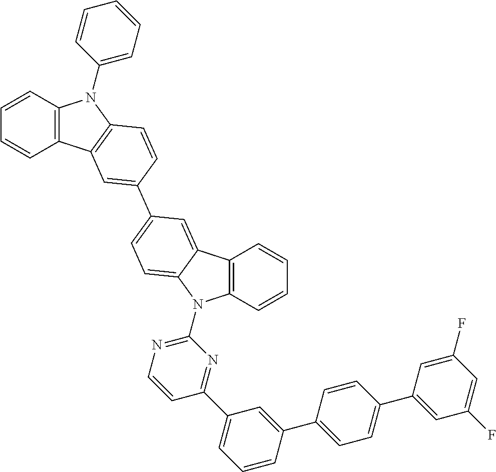 [SMILES: Fc1cc(F)cc(-c2ccc(-c3cccc(-c4ccnc(-n5c6ccccc6c6cc(-c7ccc8c(c7)c7ccccc7n8-c7ccccc7)ccc65)n4)c3)cc2)c1]

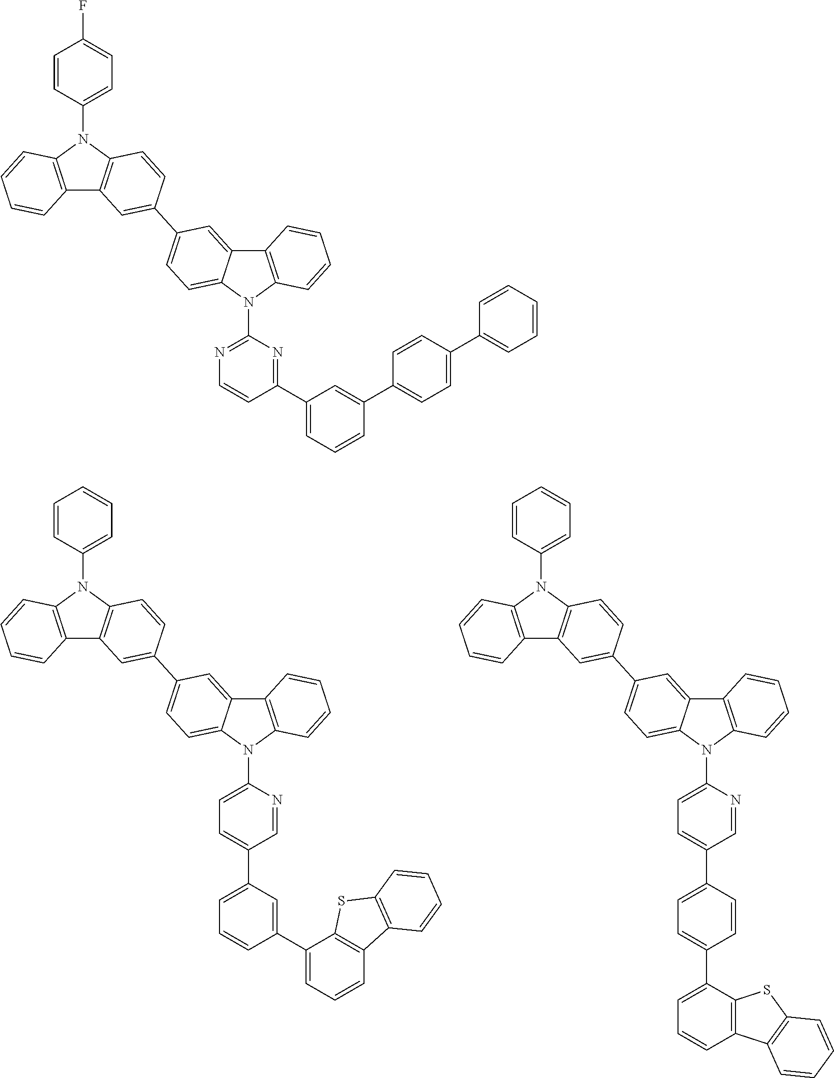 [SMILES: Fc1ccc(-n2c3ccccc3c3cc(-c4ccc5c(c4)c4ccccc4n5-c4nccc(-c5cccc(-c6ccc(-c7ccccc7)cc6)c5)n4)ccc32)cc1 ; c1ccc(-n2c3ccccc3c3cc(-c4ccc5c(c4)c4ccccc4n5-c4ccc(-c5cccc(-c6cccc7c6sc6ccccc67)c5)cn4)ccc32)cc1 ; c1ccc(-n2c3ccccc3c3cc(-c4ccc5c(c4)c4ccccc4n5-c4ccc(-c5ccc(-c6cccc7c6sc6ccccc67)cc5)cn4)ccc32)cc1]

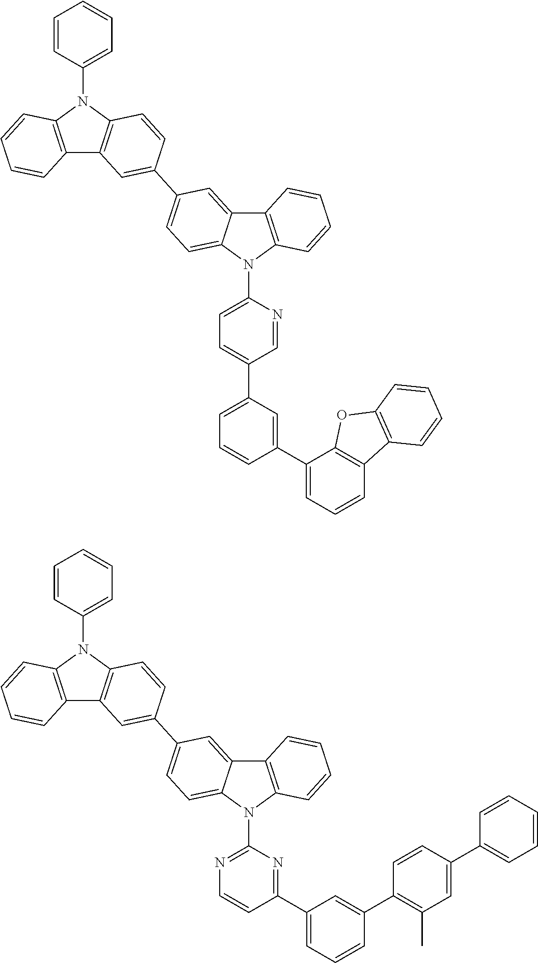 [SMILES: c1ccc(-n2c3ccccc3c3cc(-c4ccc5c(c4)c4ccccc4n5-c4ccc(-c5cccc(-c6cccc7c6oc6ccccc67)c5)cn4)ccc32)cc1 ; Cc1cc(-c2ccccc2)ccc1-c1cccc(-c2ccnc(-n3c4ccccc4c4cc(-c5ccc6c(c5)c5ccccc5n6-c5ccccc5)ccc43)n2)c1]

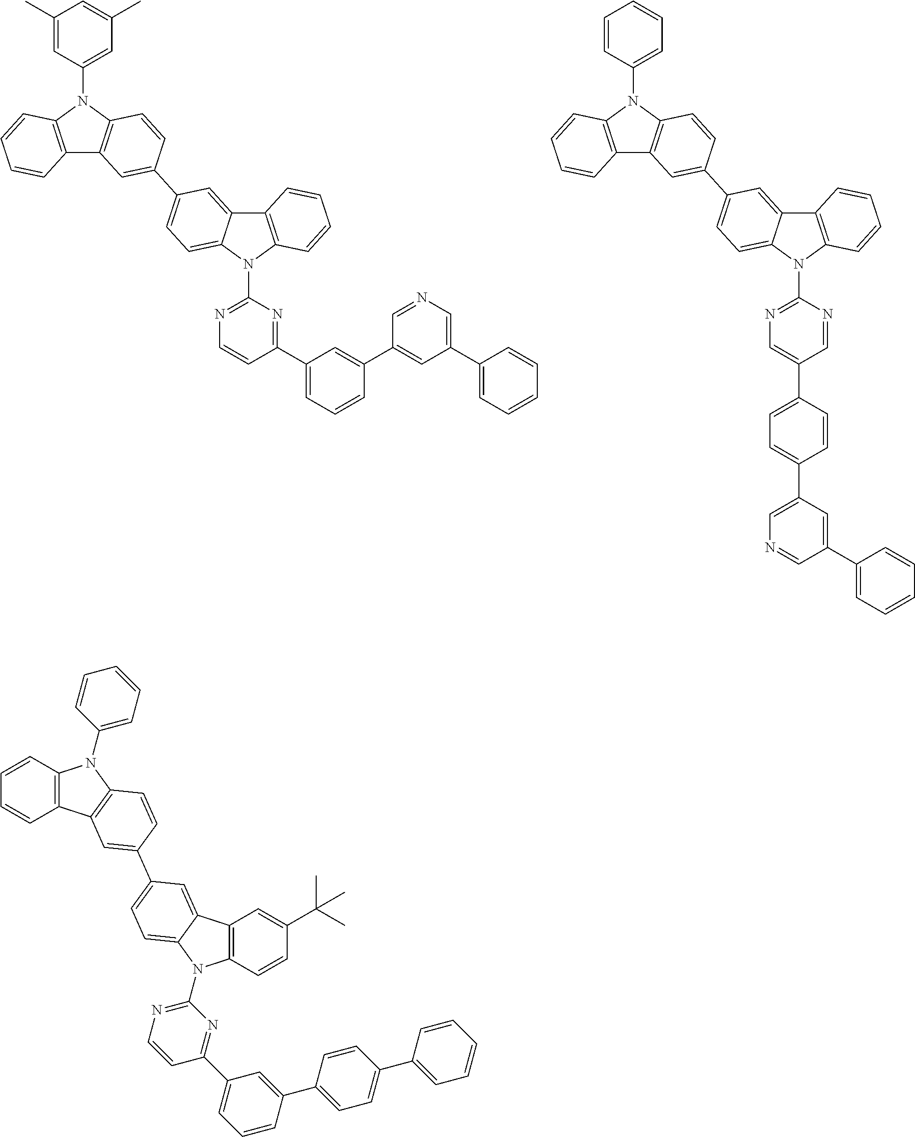 [SMILES: Cc1cc(C)cc(-n2c3ccccc3c3cc(-c4ccc5c(c4)c4ccccc4n5-c4nccc(-c5cccc(-c6cncc(-c7ccccc7)c6)c5)n4)ccc32)c1 ; c1ccc(-c2cncc(-c3ccc(-c4cnc(-n5c6ccccc6c6cc(-c7ccc8c(c7)c7ccccc7n8-c7ccccc7)ccc65)nc4)cc3)c2)cc1 ; CC(C)(C)c1ccc2c(c1)c1cc(-c3ccc4c(c3)c3ccccc3n4-c3ccccc3)ccc1n2-c1nccc(-c2cccc(-c3ccc(-c4ccccc4)cc3)c2)n1]

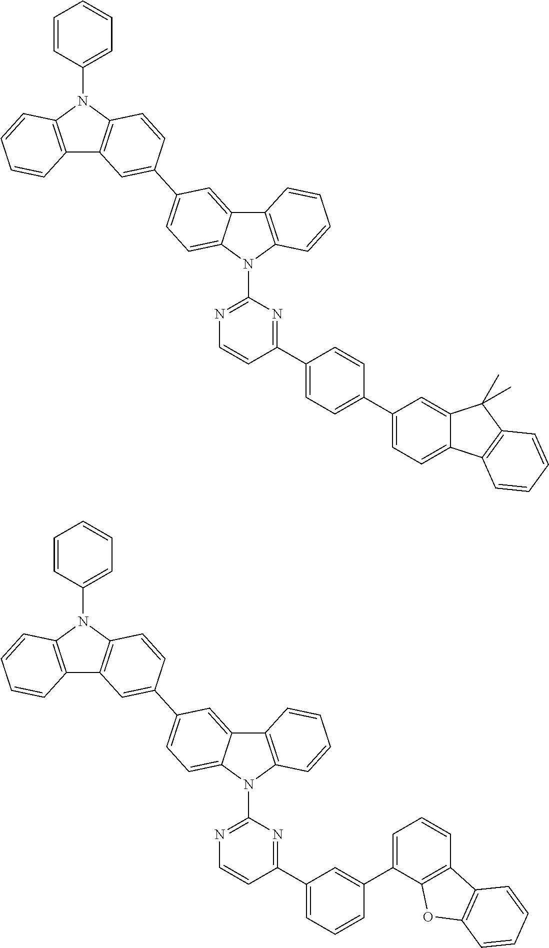 [SMILES: CC1(C)c2ccccc2-c2ccc(-c3ccc(-c4ccnc(-n5c6ccccc6c6cc(-c7ccc8c(c7)c7ccccc7n8-c7ccccc7)ccc65)n4)cc3)cc21 ; c1ccc(-n2c3ccccc3c3cc(-c4ccc5c(c4)c4ccccc4n5-c4nccc(-c5cccc(-c6cccc7c6oc6ccccc67)c5)n4)ccc32)cc1]

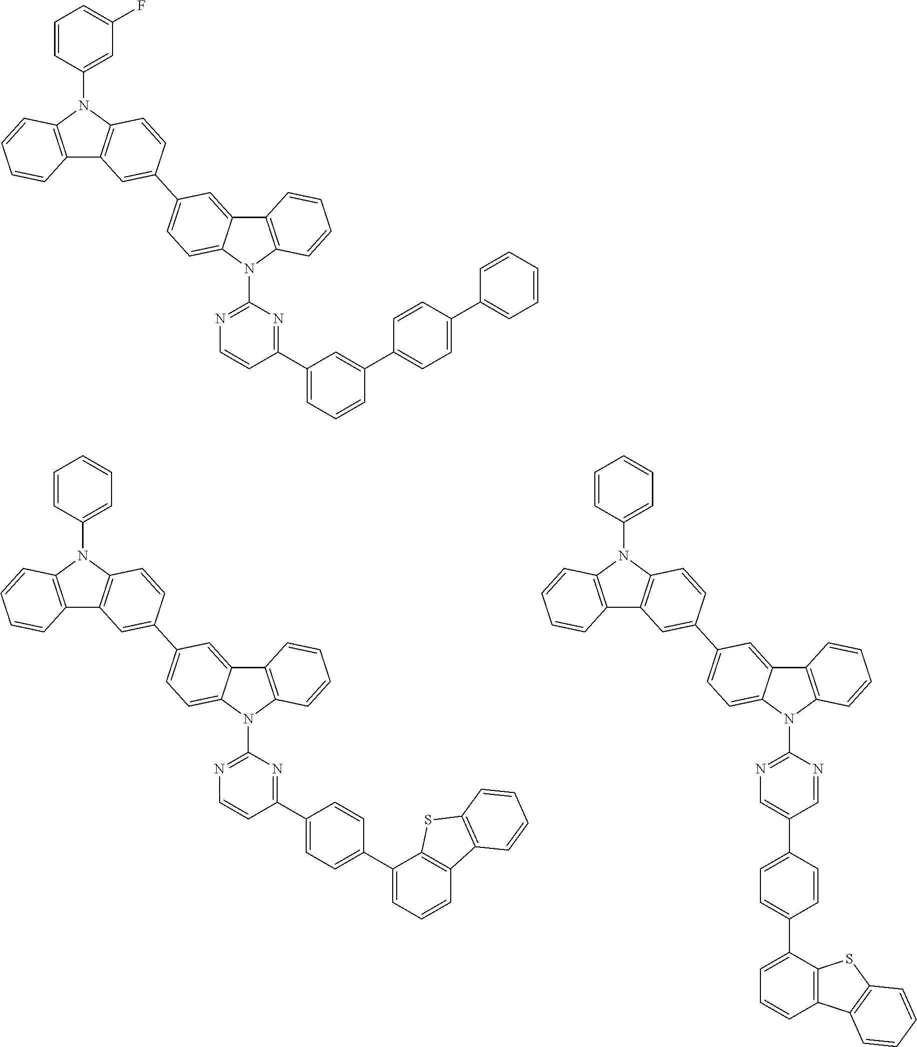 [SMILES: Fc1cccc(-n2c3ccccc3c3cc(-c4ccc5c(c4)c4ccccc4n5-c4nccc(-c5cccc(-c6ccc(-c7ccccc7)cc6)c5)n4)ccc32)c1 ; c1ccc(-n2c3ccccc3c3cc(-c4ccc5c(c4)c4ccccc4n5-c4nccc(-c5ccc(-c6cccc7c6sc6ccccc67)cc5)n4)ccc32)cc1 ; c1ccc(-n2c3ccccc3c3cc(-c4ccc5c(c4)c4ccccc4n5-c4ncc(-c5ccc(-c6cccc7c6sc6ccccc67)cc5)cn4)ccc32)cc1]

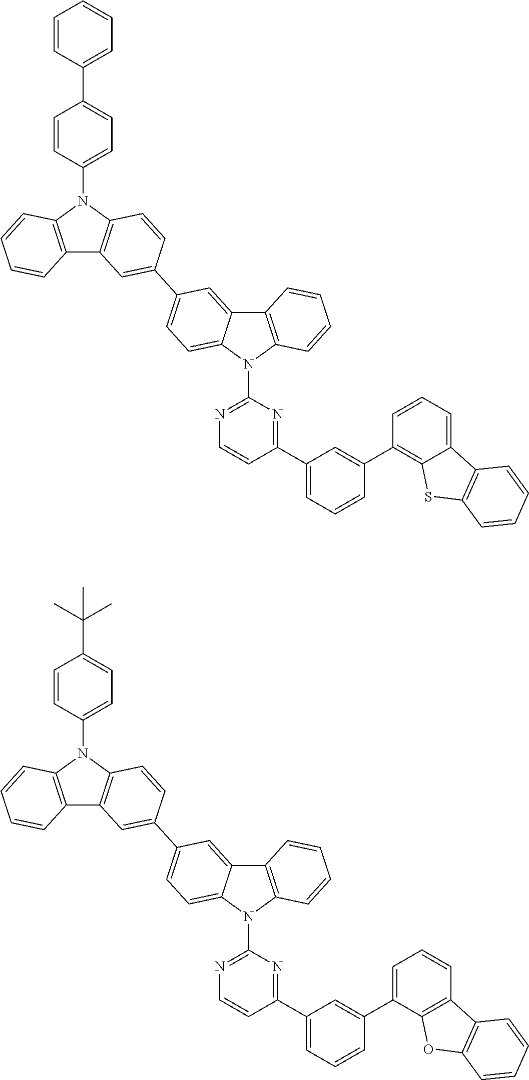 [SMILES: c1ccc(-c2ccc(-n3c4ccccc4c4cc(-c5ccc6c(c5)c5ccccc5n6-c5nccc(-c6cccc(-c7cccc8c7sc7ccccc78)c6)n5)ccc43)cc2)cc1 ; CC(C)(C)c1ccc(-n2c3ccccc3c3cc(-c4ccc5c(c4)c4ccccc4n5-c4nccc(-c5cccc(-c6cccc7c6oc6ccccc67)c5)n4)ccc32)cc1]

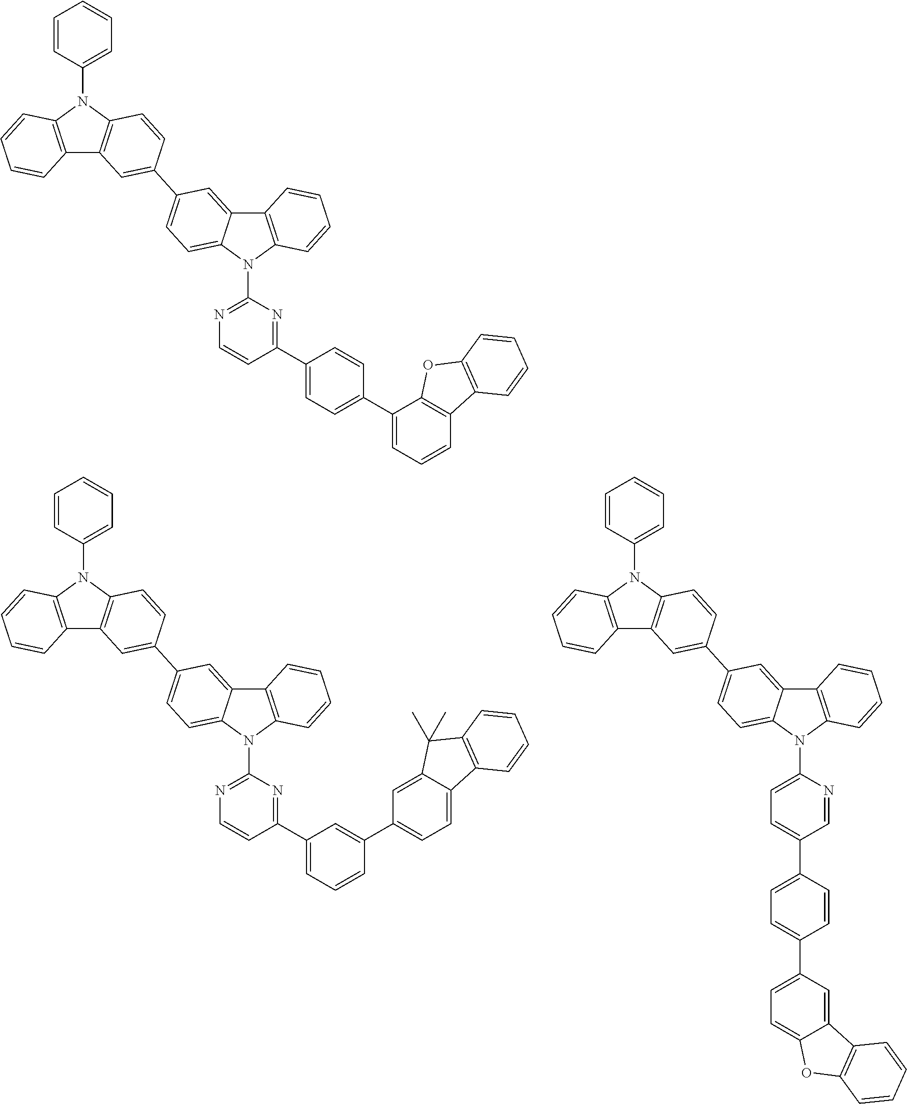 [SMILES: c1ccc(-n2c3ccccc3c3cc(-c4ccc5c(c4)c4ccccc4n5-c4nccc(-c5ccc(-c6cccc7c6oc6ccccc67)cc5)n4)ccc32)cc1 ; CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21 ; c1ccc(-n2c3ccccc3c3cc(-c4ccc5c(c4)c4ccccc4n5-c4ccc(-c5ccc(-c6ccc7oc8ccccc8c7c6)cc5)cn4)ccc32)cc1]

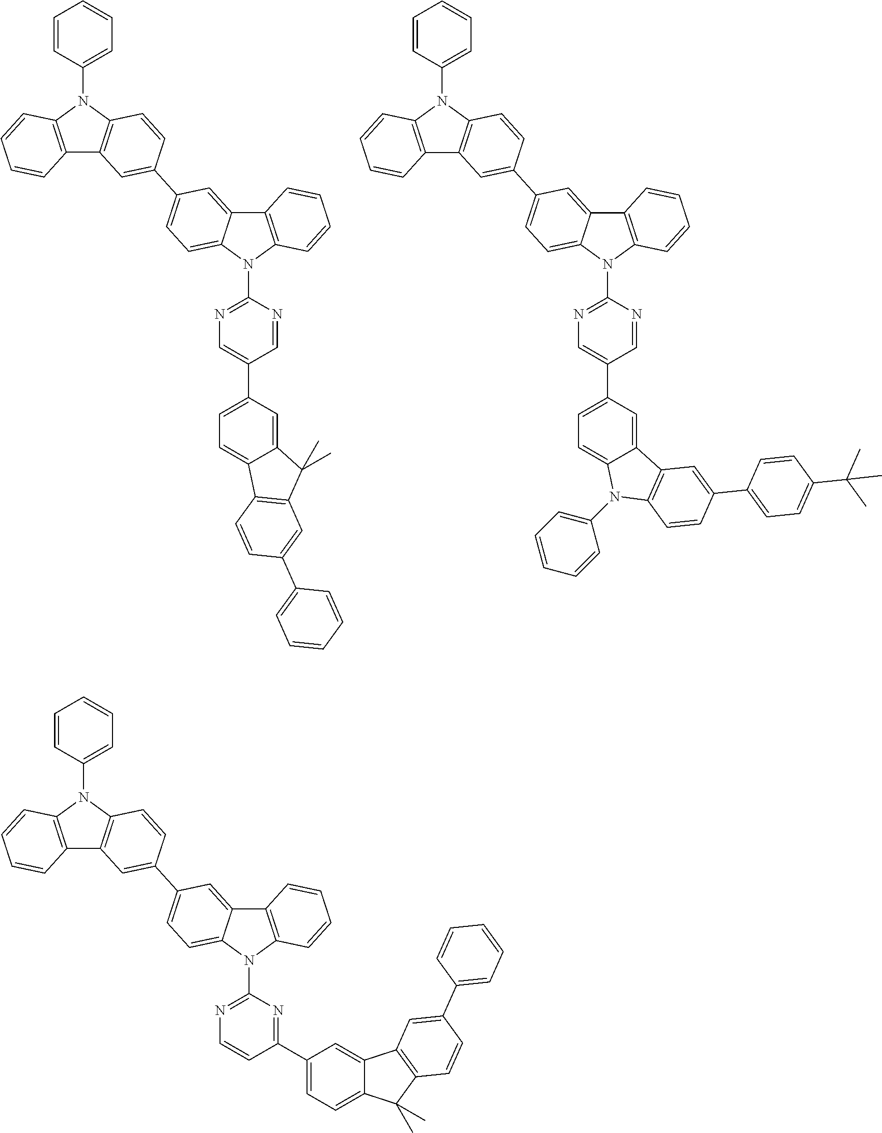 [SMILES: CC1(C)c2cc(-c3ccccc3)ccc2-c2ccc(-c3cnc(-n4c5ccccc5c5cc(-c6ccc7c(c6)c6ccccc6n7-c6ccccc6)ccc54)nc3)cc21 ; CC(C)(C)c1ccc(-c2ccc3c(c2)c2cc(-c4cnc(-n5c6ccccc6c6cc(-c7ccc8c(c7)c7ccccc7n8-c7ccccc7)ccc65)nc4)ccc2n3-c2ccccc2)cc1 ; CC1(C)c2ccc(-c3ccccc3)cc2-c2cc(-c3ccnc(-n4c5ccccc5c5cc(-c6ccc7c(c6)c6ccccc6n7-c6ccccc6)ccc54)n3)ccc21]

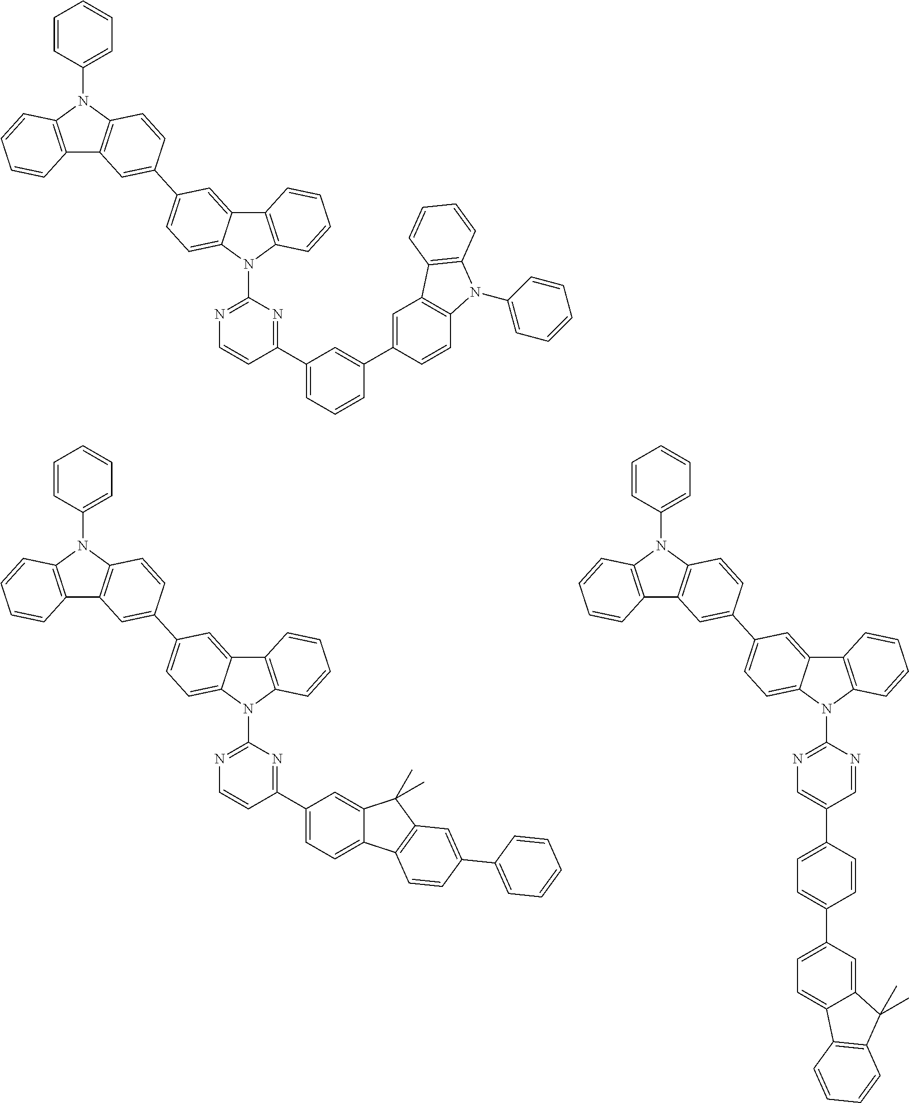 [SMILES: c1ccc(-n2c3ccccc3c3cc(-c4cccc(-c5ccnc(-n6c7ccccc7c7cc(-c8ccc9c(c8)c8ccccc8n9-c8ccccc8)ccc76)n5)c4)ccc32)cc1 ; CC1(C)c2cc(-c3ccccc3)ccc2-c2ccc(-c3ccnc(-n4c5ccccc5c5cc(-c6ccc7c(c6)c6ccccc6n7-c6ccccc6)ccc54)n3)cc21 ; CC1(C)c2ccccc2-c2ccc(-c3ccc(-c4cnc(-n5c6ccccc6c6cc(-c7ccc8c(c7)c7ccccc7n8-c7ccccc7)ccc65)nc4)cc3)cc21]

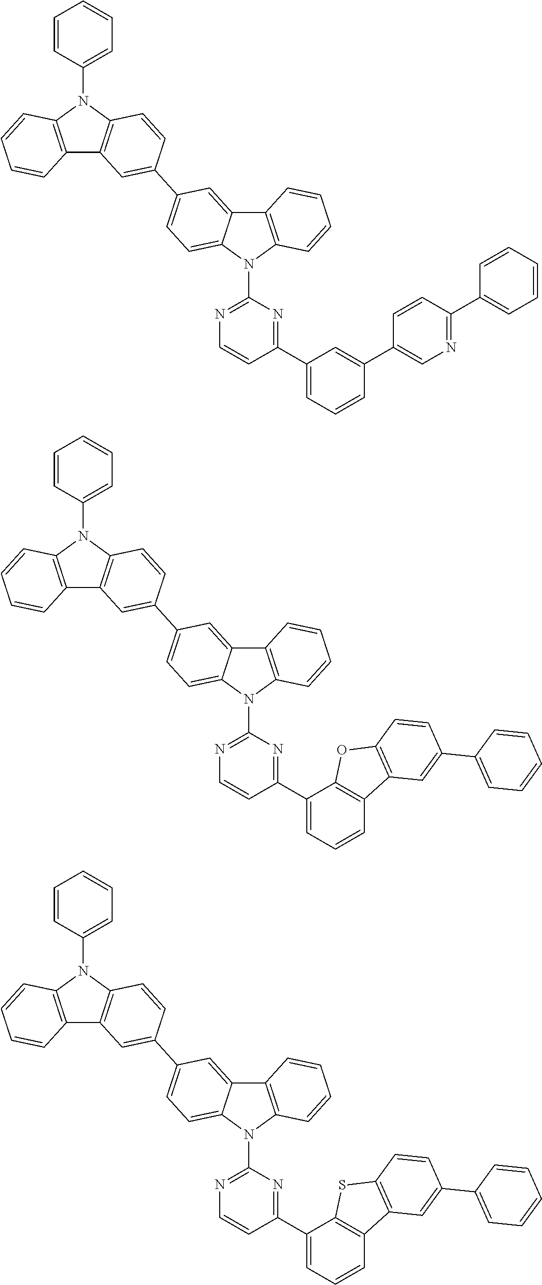 [SMILES: c1ccc(-c2ccc(-c3cccc(-c4ccnc(-n5c6ccccc6c6cc(-c7ccc8c(c7)c7ccccc7n8-c7ccccc7)ccc65)n4)c3)cn2)cc1 ; c1ccc(-c2ccc3oc4c(-c5ccnc(-n6c7ccccc7c7cc(-c8ccc9c(c8)c8ccccc8n9-c8ccccc8)ccc76)n5)cccc4c3c2)cc1 ; c1ccc(-c2ccc3sc4c(-c5ccnc(-n6c7ccccc7c7cc(-c8ccc9c(c8)c8ccccc8n9-c8ccccc8)ccc76)n5)cccc4c3c2)cc1]

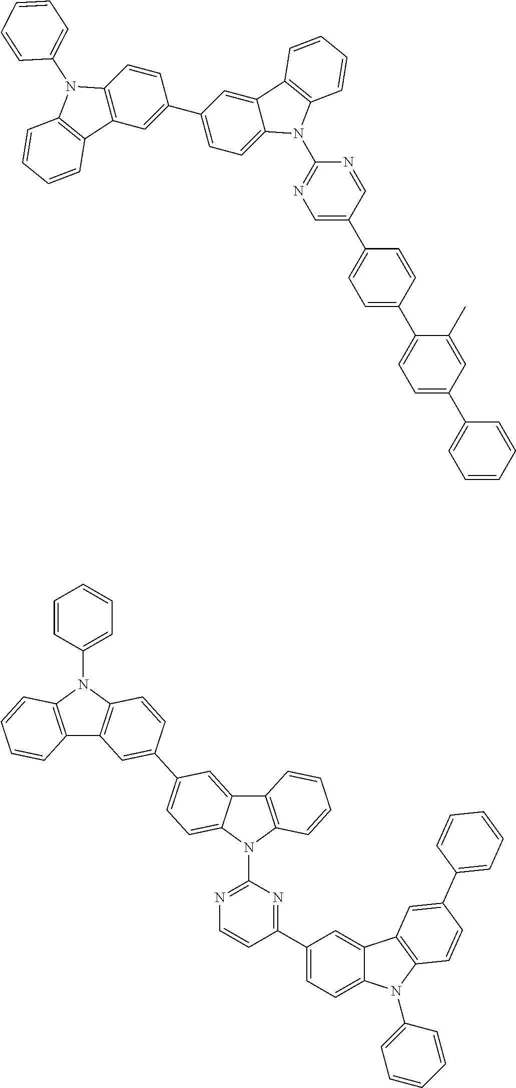 [SMILES: Cc1cc(-c2ccccc2)ccc1-c1ccc(-c2cnc(-n3c4ccccc4c4cc(-c5ccc6c(c5)c5ccccc5n6-c5ccccc5)ccc43)nc2)cc1 ; c1ccc(-c2ccc3c(c2)c2cc(-c4ccnc(-n5c6ccccc6c6cc(-c7ccc8c(c7)c7ccccc7n8-c7ccccc7)ccc65)n4)ccc2n3-c2ccccc2)cc1]

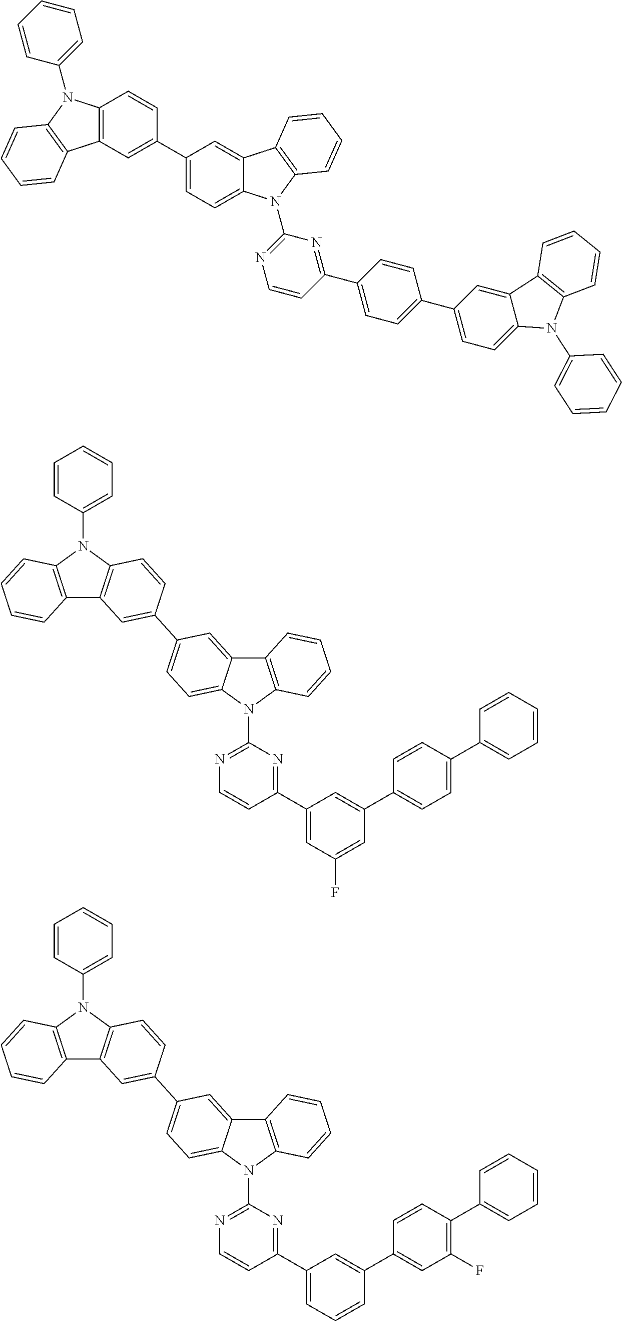 [SMILES: c1ccc(-n2c3ccccc3c3cc(-c4ccc(-c5ccnc(-n6c7ccccc7c7cc(-c8ccc9c(c8)c8ccccc8n9-c8ccccc8)ccc76)n5)cc4)ccc32)cc1 ; Fc1cc(-c2ccc(-c3ccccc3)cc2)cc(-c2ccnc(-n3c4ccccc4c4cc(-c5ccc6c(c5)c5ccccc5n6-c5ccccc5)ccc43)n2)c1 ; Fc1cc(-c2cccc(-c3ccnc(-n4c5ccccc5c5cc(-c6ccc7c(c6)c6ccccc6n7-c6ccccc6)ccc54)n3)c2)ccc1-c1ccccc1]

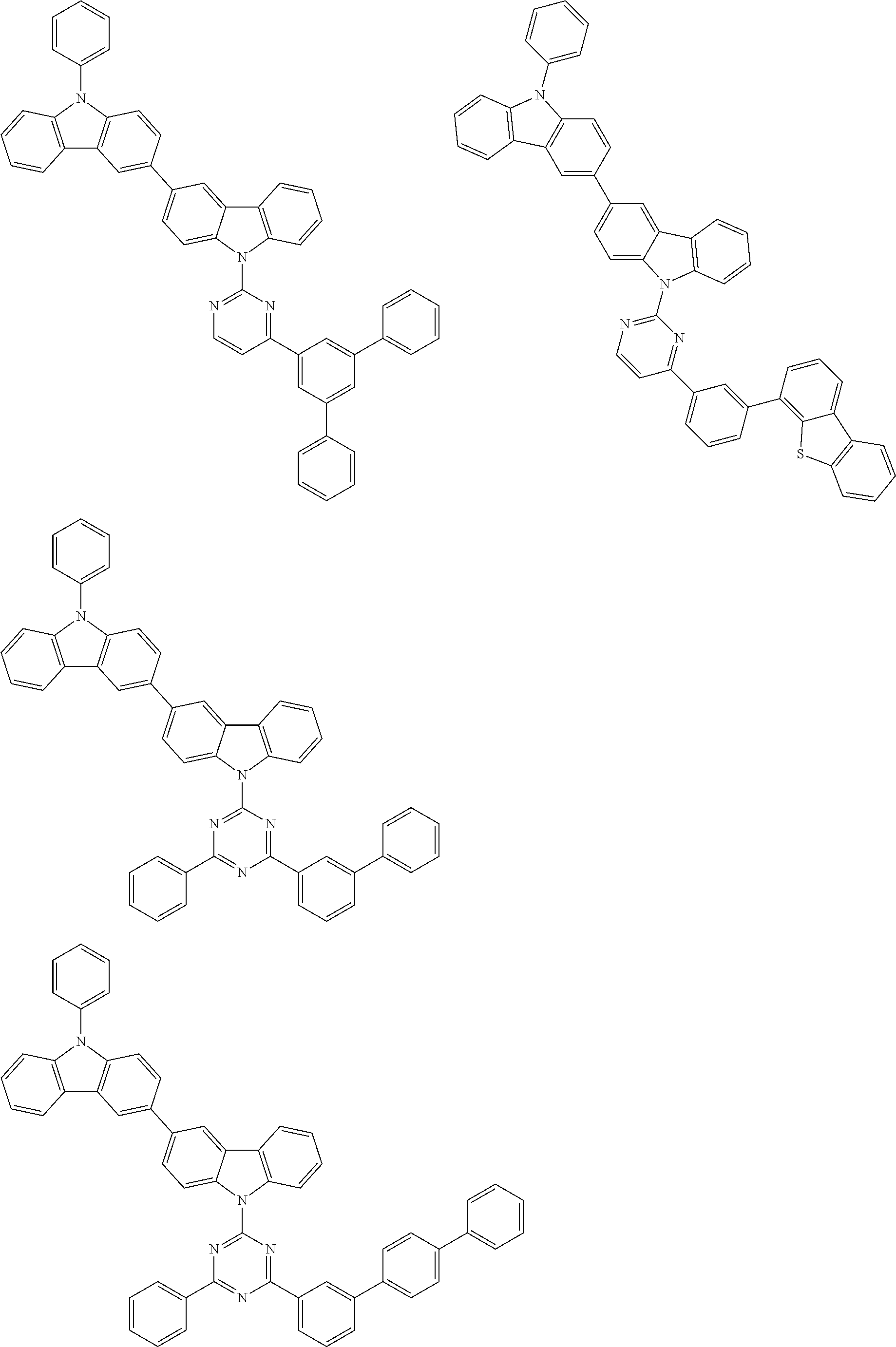 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-n2c3ccccc3c3cc(-c4ccc5c(c4)c4ccccc4n5-c4nccc(-c5cccc(-c6cccc7c6sc6ccccc67)c5)n4)ccc32)cc1 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1]

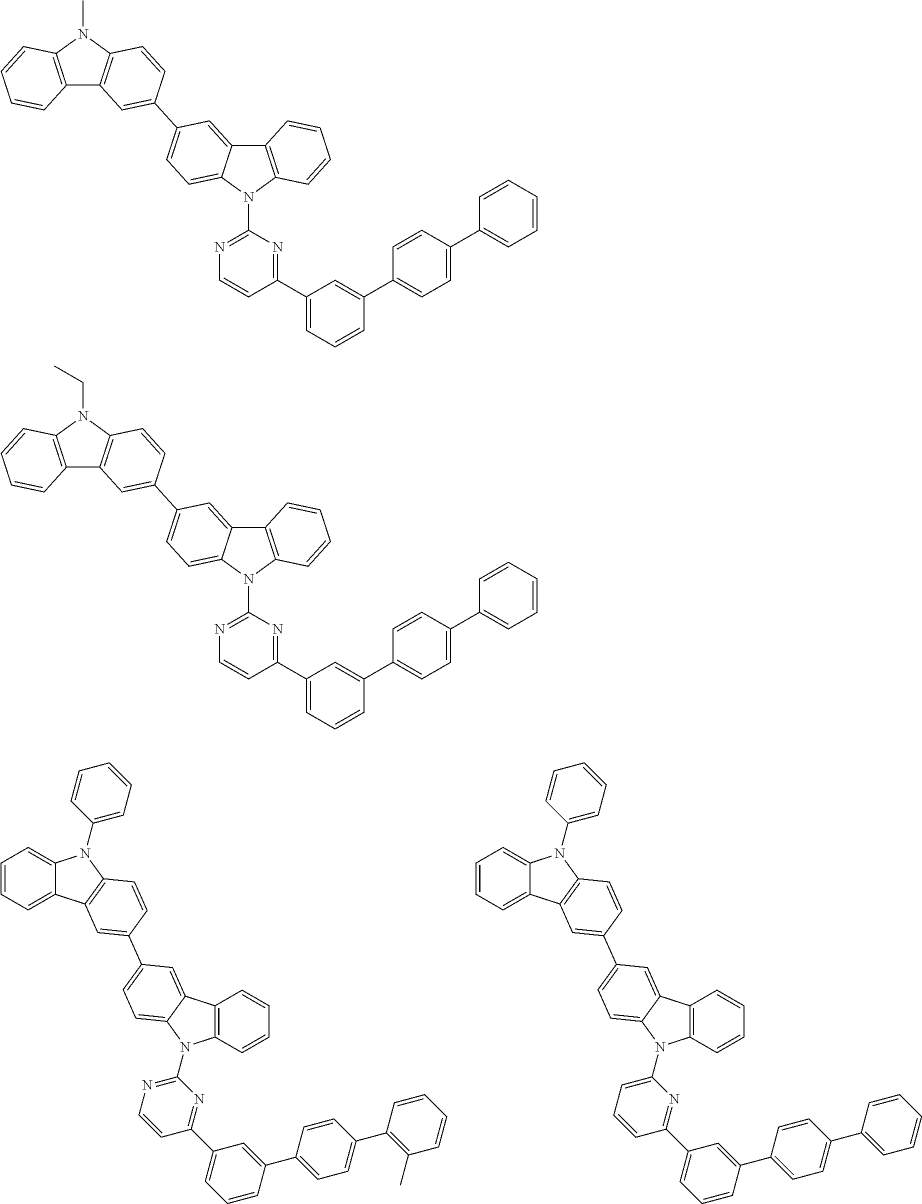 [SMILES: Cn1c2ccccc2c2cc(-c3ccc4c(c3)c3ccccc3n4-c3nccc(-c4cccc(-c5ccc(-c6ccccc6)cc5)c4)n3)ccc21 ; CCn1c2ccccc2c2cc(-c3ccc4c(c3)c3ccccc3n4-c3nccc(-c4cccc(-c5ccc(-c6ccccc6)cc5)c4)n3)ccc21 ; Cc1ccccc1-c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4cccc(-n5c6ccccc6c6cc(-c7ccc8c(c7)c7ccccc7n8-c7ccccc7)ccc65)n4)c3)cc2)cc1]

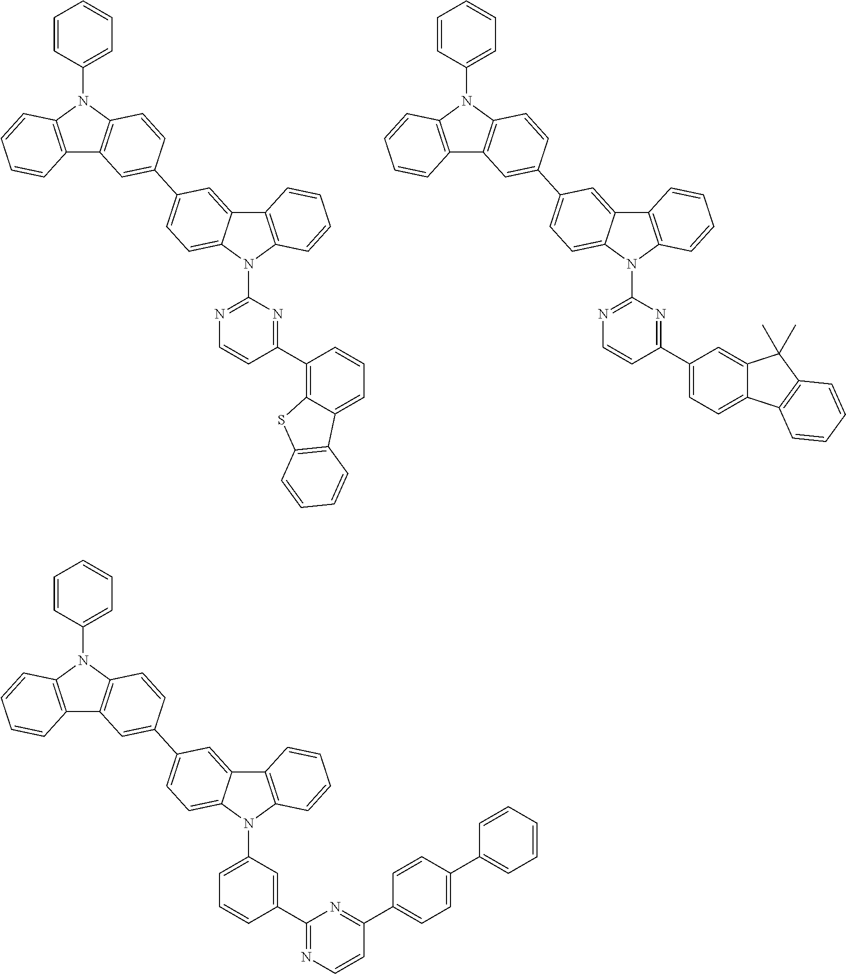 [SMILES: c1ccc(-n2c3ccccc3c3cc(-c4ccc5c(c4)c4ccccc4n5-c4nccc(-c5cccc6c5sc5ccccc56)n4)ccc32)cc1 ; CC1(C)c2ccccc2-c2ccc(-c3ccnc(-n4c5ccccc5c5cc(-c6ccc7c(c6)c6ccccc6n7-c6ccccc6)ccc54)n3)cc21 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1]

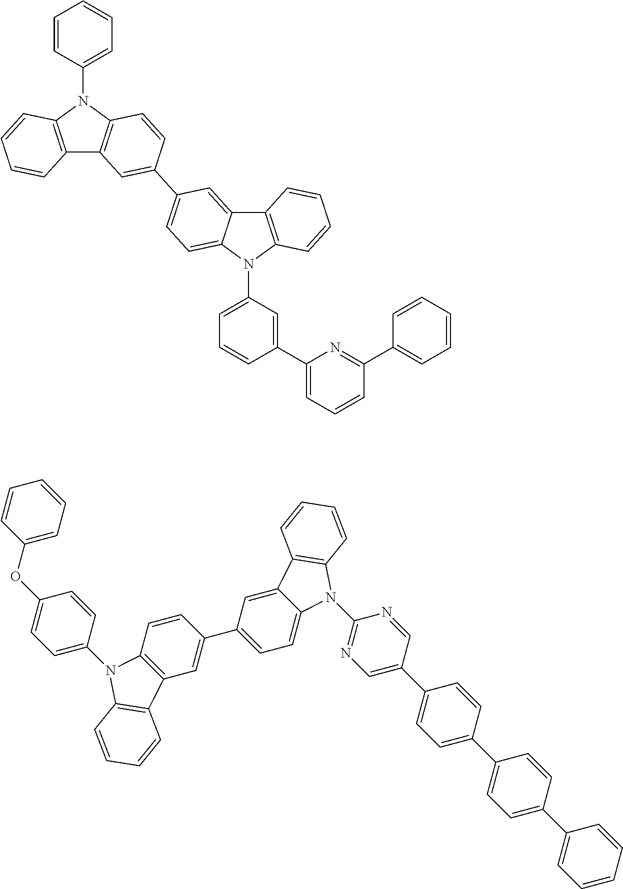 [SMILES: c1ccc(-c2cccc(-c3cccc(-n4c5ccccc5c5cc(-c6ccc7c(c6)c6ccccc6n7-c6ccccc6)ccc54)c3)n2)cc1 ; c1ccc(Oc2ccc(-n3c4ccccc4c4cc(-c5ccc6c(c5)c5ccccc5n6-c5ncc(-c6ccc(-c7ccc(-c8ccccc8)cc7)cc6)cn5)ccc43)cc2)cc1]

7. An organic electroluminescent device comprising the organic electroluminescent compound according to any one selected from claims 1 to 6.

8. The organic electroluminescent device of claim 7, which comprises a first electrode; a second electrode; and one or more organic layers interposed between the first electrode and the second electrode, wherein the organic layer comprises one or more organic electroluminescent compounds and one or more phosphorescent dopants.

9. The organic electroluminescent device according to claim 8, wherein the organic layer further comprises one or more amine compound(s) (A) selected from the group consisting of arylamine compounds and styrylarylamine compounds; one or more metal(s) selected from the group consisting of organic metals of Group 1, Group 2, 4th period and 5th period transition metals, lanthanide metals and d-transition elements or complex compound(s)(B) comprising the metal; or one or more selected from (A) and (B).

10. The organic electroluminescent device of claim 8, which is a white light-emitting organic electroluminescent device wherein the organic layer comprises an electroluminescent layer and a charge generating layer, or further comprises one or more organic electroluminescent layers emitting blue, red or green light.
